(19) United States
(12) Patent Application Publication
(10) Pub. No.: US 2021/0021230 A1
(43) Pub. Date: Jan. 21, 2021

(54) PHOTOVOLTAIC MICROCELL ARRAY WITH MULTI-STAGE CONCENTRATING OPTICS

(71) Applicant: TERRA FIRMA INNOVATIONS INC., Sutton (CA)

(72) Inventor: Richard NORMAN, Sutton (CA)

(21) Appl. No.: 16/982,285

(22) PCT Filed: Mar. 18, 2019
(86) PCT No.: PCT/CA2019/050329

§ 371 Date: Sep. 18, 2020

Related U.S. Application Data
(60) Provisional application No. 62/644,774, filed on Mar. 19, 2018.

(51) Int. Cl. H02S 40/22; G02B 19/00; G02B 26/08; F21V 7/00; F21V 5/00

(52) U.S. Cl. CPC H02S 40/22; G02B 19/0042; F21Y 2115/10; F21V 7/0033; F21V 5/007; G02B 26/0816

(57) ABSTRACT

The present invention is primarily directed to reducing the cost of photovoltaic systems in general, and high-concentration photovoltaic systems in particular, through reducing the cost of concentrating light to the high-concentration needed to make ultra-efficient cells affordable, reducing the cost of interconnecting and cooling the photovoltaic cells, and increasing the optical and electrical efficiency of the photovoltaic system as a whole.

### CROSS-REFERENCE TO RELATED APPLICATIONS

This application claims priority from U.S. Provisional Patent Application 62/644,774 filed Mar. 19, 2018, the specification of which is incorporated herein by reference.

### TECHNICAL FIELD

This invention relates to the field of converting solar energy to electrical energy, and more specifically to low cost, high-efficiency, high-concentration photovoltaic systems.

### SUMMARY OF THE PRIOR ART

Photovoltaic (PV) panels, in which semiconductor materials transfer energy from photons of sunlight to electrons that can then drive electrical circuitry, are well known in the art of electrical power generation; these now produce electricity cost-effectively when the sun is shining, but much lower PV system cost is needed to cover the round-trip inefficiency and cost of storage, whether pumped-storage hydroelectricity, batteries, PV sun-to-fuels, or other means.

Most PV systems intercept sunlight by largely covering their entire light-gathering area low-cost-per-area semiconductor; and increases in their semiconductor conversion efficiencies and decreases in their semiconductor cost per area have led the dramatic improvements in cost per Watt. But low-cost single-junction semiconductors are approaching their theoretical efficiency limits, and even if the semiconductor itself were free, these flat panel PV systems would not be low enough cost to fully displace fossil fuels. There is thus a need for a more cost-effective way to convert sunlight to electricity.

Multi-junction cells, or tandem cells, have multiple layers of semiconductors, with each layer optimized to convert different wavelengths of light; these tandem cells offer roughly twice the efficiency of single-layer semiconductors, but cost roughly 1000 times more per area. High-concentration photovoltaics, or HCPV, uses mirrors, lenses and/or other optical elements to concentrate light roughly 1000× onto such cells (where X is used herein to mean a geometric concentration); roughly 2000× the power per area makes the 1000× cell cost per area highly affordable. However, the rest of the system has been too expensive: the intense concentration has required expensive heat-conducting substrates to conduct heat from the cells, the bulky sealed boxes that protect the optics and the cells are expensive, and the complex concentrating optics themselves have added significantly to the system cost.

HCPV system thickness scales inversely with cells size, so small cells can reduce many of the system costs, and microcells (cells less than 1 mm²) have become a major research area. Microcells allow HCPV systems to be as thin as traditional flat panels, in some cases even eliminating air-gaps in the optical path to improve optical efficiency; microcells have lower resistive losses than large cells, improving conversion efficiency; and microcells shed heat well, improving cooling efficiency. However, the smaller the cells, the more cells there are to handle, and if each cell has its own receiver, the more receivers there are to handle as well, and placing vast numbers of cells or receivers over a large light-gathering area itself becomes expensive. There is thus a need for a way to obtain the efficiency advantages of microcells without the costs.

The present invention is directed to reducing the cost of using micro-cells, and includes multiple innovations that interact synergistically to greatly reduce that cost. Specific embodiments with combinations of innovations are described in detail, and it should be understood that the use of specifics is for the sake of clarity rather than for limitation. For example, while other types of cells that perform well at high concentration would also be suitable, tandem cells are discussed in preferred embodiments because they currently have the highest efficiency and are commercially available at reasonable cost, and they exemplify the characteristic of suitable cells.

As seen in Prior Art FIG. 1A, most HCPV systems comprise large hollow boxes 161 with two-dimensional arrays of mid-sized refractive optical elements for primary concentration, with each primary optical element concentrating light for a single tandem cell. The array 110 of primary concentrators spans the light-gathering area; the outer surface is typically smooth glass with the inside surface patterned in over-molded silicone into an array of Fresnel lenses 11, each of which concentrates light in two dimensions onto a secondary optical element 12 that focuses light onto a tandem cell. The cell comprises part of a receiver 14, which is shown in greater detail in FIG. 1B (as used herein, a receiver refers to an entity comprising a mechanically contiguous substrate and comprising one or PV cells, with all of its PV cells electrically in parallel). At the egress of the secondary optical element is a tandem cell 1B5 that is on an electrically conductive copper layer 1B411 that is on a thermally-conductive-but-electrically-isolating aluminum nitride layer 1B4121; a second copper layer 1B411′ is added to balance thermal expansion stress. The receivers are distributed below the whole light-gathering area (which when used without qualification herein refers to the primary light-gathering area of the PV system), connected in series by wires 1B43; to connect the receivers in series, a receiver has two connector cages 1B462 that receive the ends of the wires 1B43, and diode 1B42 will electrically bypass the receiver if the cell is defective or under-illuminated compared to cells on other receivers in the series. The cell's bottom (+) and top (−) contacts are both connected to the same conductive copper layer 1B411, requiring complex patterning of that layer to divide it into two disjoint regions, 1B4111 (+) and 1B4112 (−); the copper layer is bonded to thick isolating substrate 1B4121 as a sheet and is then lithographically patterned (masked and etched) into the two regions. A cell has multiple bond wires 1B53 connecting its bus bars 1B52 to the conductor 1B4112.

Such modules are generally installed on a two-axis tracker to track the sun. Two-axis trackers are well known in the prior art; in addition to the most common pedestal altitude/azimuth tracker 1C0, as shown in FIG. 1C (image from SAT CONTROL's web site), there are carousel altitude/azimuth trackers, polar daily/seasonal trackers, tilt-and-roll trackers, X/Y trackers, and a variety of other designs. Most two-axis trackers have straight steel rails like rail 1C01 to which modules are bolted so that when the tracker tracks the sun, the modules track with it.

Another large-box HCPV variant uses reflective optics, but the principles are similar. A cover-glass, again with a smooth outer surface, admits light onto a two-dimensional arrays of mid-sized reflective optical elements used for primary concentration. Each such mirror concentrates light onto a secondary optical element that reflects onto a single cell, typically through an intervening tertiary optical element (this functions similarly to secondary optical element 12 above, but is optimized for the narrower angle of light from the secondary optical element). The cell and the rest of the receiver are in general the same as those in FIG. 1A and FIG. 1B.

These refractive and reflective HCPV architectures have similar high costs from large sealed steel boxes adding to the expense of two-dimensionally-patterned optics the size of the light-gathering area and receivers substrates based on lithographic patterning of an expensive copper-on-thermally-conductive-insulator substrate, and both architectures have therefore been adapted to take advantage of microcells. If the dimensions of the primary optical element 11 are reduced by a scaling factor S, the depth of the box 161 is reduced by the same factor S, and the dimensions of each cell 1B5 are also reduced by a factor of S. With enough reduction, the depth of the box becomes small enough that the whole system becomes as thin as a flat panel; the shorter sides allow replacing the steel box with a stamped metal pan, and small cells spread heat better, allowing thinner metal.

At a small enough scale, the entire optical complex can be molded as a single sheet of glass or plastic because the light path from cover-glass to cell becomes short enough that absorption in low-cost glass becomes acceptable. With current glass this occurs at a cell size of roughly 1 mm²; since such cells have an area of one millionth of a square meter, cells that size or smaller are referred to as microcells. For refractive optics, the lens pattern must now be on the front of the cover-glass (since the inside is solid), but the small lens size allows standard lenses rather than the more complex Fresnel lenses to be used, which raises optical efficiency. As exemplified by Hayashi, et al. in “High-efficiency thin and compact concentrator photovoltaics with micro-solar cells directly attached to a lens array” (hereinafter referred to as Hayashi1), the light-gathering area is spanned by a lens sheet, which has a sea of small lenses. Each lens focuses onto a single cell without any intervening air gap, eliminating sharp refractive index changes that would reflect energy and reduce efficiency. Miniaturizing the cells and optics until the optics become a solid sheet can also be applied to reflective optics with similar results, as exemplified by Elrod in “III-V Solar Concentrators: Driving Down the Cost to Below $1.00/Watt”.

However, while the optics are simpler and the box is less expensive, and the microcells are efficient and shed heat well, there are now vast numbers of tiny receivers to place and to interconnect, and the complex optics, sealed box, and receiver placement all span the entire light-gathering area, again creating a high-cost system. Indeed, Hayashi's later work, as exemplified by “Thin concentrator photovoltaic module with micro-solar cells which are mounted by self-align method using surface tension of melted solder” (hereinafter Hayashi2), gives up the solid-optics approach in preference for an intermediate-thickness approach for an approach more like that of Furman et al. in “A High Concentration Photovoltaic module Utilizing Micro-Transfer Printing and Surface-Mount Technology”, in which the primary concentration is by a sheet of lenses separated by an air gap from secondary optics that feed the cells, with a one-to-one correspondence between primary and secondary concentrators and cells. There is thus a need to keep the scaling advantages while eliminating the small-receiver disadvantages.

Another approach to HCPV uses even lower-cost primary optics that only focus on one axis, and then uses lens secondary optics to raise the concentration enough to make tandem cells affordable. This is taught with a 1-axis-tracked trough primary by Norman, et al. in FIG. 15F of US20100263709A1 (hereinafter referred to as Norman1); and is taught with a 2-axis-tracked trough primary by Wheelwright, et al. in “Freeform lens design to achieve 1000× solar concentration with a parabolic trough reflector”, and by Corino in “Die SunOyster—solare KWK” (hereinafer Corino1) and US20150381110A1 (hereinafter Corino2). While Norman1 teaches this with a separate lens for each focal spot, Wheelwright teaches this with secondary lenses roll-formed as a sheet, but even to barely reach 1000× Wheelwright's lens sheet must be curved (preventing it from being low cost) and each focal spot needs a separate rod lens. Furthermore optical efficiency is reduced by multiple refractive air/glass interfaces with sharp refractive-index changes, and Wheelwright does not even mention many elements needed for a practical system, such as cooling (which is critical because 1000× concentration will melt steel if not cooled and the cells must be kept cool at all times). Corino teaches a similar architecture, and deals with the practicalities; the cells are kept cool by liquid pumped through a pipe under the cells. While this cooling is more expensive than cooling in classical Fresnel/Box HCPV (in which a thick aluminum sheet simply spreads the heat to the module area, where it is carried away by natural convection), Corino offsets this by using the heat as a by-product; this works in cold cities where heat has value, but in sparsely-populated sun-drenched deserts suitable for large-scale CPV there are unlikely to be customers for vast quantities of low-grade heat. While both Wheelwright and Corino use multiple cells (namely, multiple cells in parallel) at the focus of a lens, those cells are all within the same single focal spot; one long cell per lens focus would be more efficient (no gaps) and multiple cells are used because long cells are impractical (being fragile and not packing well on the expensive wafers on which tandem cells are made). Both Corino1 and Corino2 teach multiple cells across the primary concentrator's focus in parallel, neither teaches cells in parallel along the primary concentrator's focus, and Corino2 specifically teaches connecting cells in series along the primary focus to increase the voltage obtained.

Corino2 teaches forming multiple secondary concentrators as an integral part of his casing tube, but teaches away from optically coupling such contiguous parts to the cells: Corino2 teaches minimizing thermal conduction to the casing tube by filling the intervening space with vacuum, inert gas or even a transparent aerogel to minimize heat loss, and these all have refractive indices too low to couple any known practical casing tube material or transparent secondary concentrator material to a cell. Wheelwright teaches roll-forming multiple secondary concentrators as a single part, but also teaches away from optically coupling such contiguous parts to the cells: optically coupling Wheelwright's secondary concentrators to the cells would interfere with using rod lenses to stabilize the focal lines on the cells.

Two-axis concentration onto lens sheets has also been proposed. Norman, et al. teach, in FIG. 6A of US20120037206A1 (hereinafter referred to as Norman2), greater than 100× 2-axis concentration onto a 2D array of 2D-focusing lenses that concentrate less than 10×, producing a semi-dense array of focal spots (a 2D array of items as used herein refers to items arrayed in two dimensions). While Norman2 teaches that such an array can be molded as a single sheet, the lens sheet would be very fragile, with only a thin region interconnecting lenses into a sheet and sharp-tipped notches concentrating stress directly onto the thin connecting regions. Furthermore this requires more-expensive two-axis primary concentration and expensive active cooling, and the cells are individually placed on the fragile lens and individually wired, so large cells must be used to prevent high assembly costs. To simplify alignment during assembly Hayashi2 does fabricate the secondary concentrators as a single physical sheet, with the primary concentrators concentrating in two dimensions onto the secondary concentrator sheet, but the secondary concentrators are far from adjacent (next to each other), and each secondary concentrator receives light from a different primary concentrator; and while this simplifies assembly it adds the cost of molding a second full-light-gathering-area optical layer to the material and processing expenses (and Hayashi2 acknowledges that molding the secondary optics in a single sheet of PMMA acrylic is problematic because PMMA can't reliably handle the concentration from the primary).

Multi-cell dense receiver arrays (DRAs) are also well known, including by Norman et al. in “Shingled-Row Dense Receiver Array for CPV” (hereinafter referred to as Norman3), in which ten receivers in series, each comprising ten cells in parallel along with bypass diodes, share a substrate. But as exemplified by Norman3, these require expensive two-axis optics and expensive active cooling and only serve a single focal spot. These also benefit from large cells; micro-cells would slant excessively if shingled as in Norman3 and would lose light to gaps and interconnects if not shingled, the transmissive optics are already a single thin sheet and would not get simpler, and the overall system size would not decrease.

In addition to multi-receiver DRAs, multi-receiver substrates have been produced for Mirror/box CPV. As disclosed by Proulx, et al. in “Characterization of an Assembly Architecture Incorporating a Multi-Cell Design for Lower Cost Hybrid CPV Modules”, Crystal Green Energy (hereinafter CGE) packs a ring of four series-connected CPV receivers, each with its own cell and its own bypass diode, onto a single substrate. While the number of connector cages and wires is reduced four-fold, connector cages and external wiring are still needed on a per-substrate basis, and CGE still requires the expensive 2D-focusing primary optics and a costly box of traditional mirror/box CPV. While CGE fits four focal spots and four receivers (and thus four cells) onto a substrate, that substrate is 25 times the total cell area instead of HCPV's typical 5 times to 10 times the total cell area; to compensate CGE uses DBC alumina rather than DBC AlN; while this keeps the cost the same (alumina being ˜5× cheaper per area), alumina is 7× less thermally conductive, raising the cell temperature and thus reducing efficiency and cell lifetime.

While CGE says that this can be extrapolated to receivers with higher numbers of cells, this refers not to smaller cells on the same-sized substrate (which would be more cells per area), but to larger substrates, as shown by the paper acknowledging that “the material costs such as DBC carriers will still increase approximately linearly with the number of cells”. While smaller cells could be used at a lesser penalty than with single-receiver substrates (due to only needing one wire and two connector cages for each substrate, rather than for each receiver), the optics would get more sensitive to alignment (both lateral and angular), and the angular sensitivity would further increase if an array of receivers were used rather than a ring of receivers.

In “High-Concentration Solar Trough Collectors and their Application to Concentrating Photovoltaics”, Cooper teaches a multi-receiver substrate sharing common concentrating optics; in FIG. 5.1 Cooper shows a five-receiver substrate that achieves very high cell-to-substrate area ratio. That this is five series-connected receivers (as opposed to Corino1's single 8-cell receiver) is clear from Cooper's description as well as from the per-receiver bypass diodes. However, Cooper only achieved the high density packing of receivers at the cost of high photo-current mismatch between the receivers, which would dramatically reduce efficiency, and in section 5.4.6. Cooper explains that the mini-module was redesigned (becoming like that of Corino1 and Wheelwright) to eliminate that drawback.

Cooper teaches high-concentration CPV for one-axis trackers as well as for two-axis trackers. The level north-south single axis tracker 1D0 of Cooper is shown in FIG. 1D; this is the most common type of single-axis tracker (although steel is more common than concrete). Other examples for CPV include the SunPower C7 tracker, 1D0′, which also shows the mounting of off-axis trough mirrors.

From the above summary of the prior art, it can be seen that dramatically reducing CPV's overall cost is difficult; going to great lengths to beat cost down in one area has merely caused extra costs to pop up in another area, and as a result HCPV has been unable to keep up with the falling cost of silicon flat panels, let alone bring solar's cost down further. There is thus a need for a novel HCPV architecture that reduces cost below Fresnel/box CPV costs in one or more areas without correspondingly increasing cost in other areas.

### SUMMARY OF THE INVENTION

The present invention thus provides cost-effective means for highly concentrating solar energy onto small photovoltaic cells, for extracting usable electrical energy from those cells, for protecting the cells from moisture and excessive mechanical forces, and for removing heat from those cells. For brevity, specific aspects of the present invention are summarized in a depth-first hierarchical fashion with a primary aspect or a group of aspects described, a subordinate aspect (if any) of that primary aspect (or group) is described as a ‘further’ aspect, aspects subordinate to further aspects are described as “even further” aspects, and so on through “still further” and “yet further” aspects. The next primary aspect (not subordinate to any previous primary aspect) is described as “another” primary aspect, or “it is also” an aspect. While the primary aspects may be used independently, they are also cooperative and form a “broad” aspect.

In a broad aspect, the present invention provides multi-stage concentration where the first concentration stage comprises a primary concentrator that concentrates on a first concentration axis and is tracked, to follow the direction of the sun, on at least the first concentration axis; the second concentration stage comprises a plurality of secondary concentrators that each further concentrates a region of the primary concentrator's focus on a second concentration axis and that are tracked to follow the sun the second concentration axis, and where each of the plurality of secondary concentrators produces a focus that does not overlap foci from the other secondary concentrators; and the cost of the overall system is reduced through at least one of
a plurality of photovoltaic cells that are individually connected electrically in parallel with each other and that are arranged to receive light from a corresponding plurality of said non-overlapping foci;
the photovoltaic cells are arranged to receive light from the plurality of said non-overlapping foci, the plurality of secondary concentrators are formed as or on an integral part, and said integral part is optically coupled to said cells without an intervening refractive index lower than 0.25 below the refractive index of the secondary concentrators;
light focused by at least one of said secondary concentrators is further concentrated on a least said primary concentration axis by a plurality of tertiary optical elements, or TOEs, that are molded on or as a single contiguous part;

In a further aspect of the present invention, the primary concentrator concentrates 20× to 70×, and more preferably 30× to 50×, and even more preferably 35× to 45×, onto said secondary concentrators, dramatically reducing their size.

In a further aspect of the present invention, the primary concentrator is an off-axis parabolic trough mirror.

In an even further aspect of the present invention, the trough mirror has a rim angle of less than 30°, and more preferably between 20° and 25°.

The above aspects further aspects and their subordinates form a group of “primary concentrator aspects” and may be combined with any of the primary aspects.

In a primary aspect, the present invention provides multi-stage concentration where the first concentration stage comprises a primary concentrator that concentrates on a first concentration axis and is tracked, to follow the direction of the sun, on at least the first concentration axis; the second concentration stage comprises a plurality of secondary concentrators that each further concentrates a region of the primary concentrator's focus on a second concentration axis and that are tracked to follow the sun the second concentration axis, and where each of the plurality of secondary concentrators produces a focus that does not overlap foci from the other secondary concentrators; and a plurality of photovoltaic cells that are individually connected electrically in parallel with each other and that are arranged to receive light from a corresponding plurality of said non-overlapping foci.

In a further aspect of the present invention, the cells that are individually connected electrically in parallel with each other are also in parallel with a bypass diode.

In a further aspect of the present invention, the cells that are individually connected electrically in parallel with each other absorb light from the foci of at least 3, more preferably at most 12, and even more preferably between 4 and 6 secondary concentrators.

In a further aspect of the present invention, the cells that are individually connected electrically in parallel with each other are microcells that produce in total at least 10 W when the multi-stage concentration is aligned to the sun and under full sunlight, and preferably at least 30 W.

In a further aspect of the present invention, the cells that are individually connected electrically in parallel with each other are separated by at least the cell size in at least one dimension, and preferably in both dimensions.

In a further aspect of the present invention, the cell size, in the direction of secondary concentration, is at most 2 mm, preferably less than 1 mm. Preferably this cell size dimension is also greater than 0.5 mm.

In a further aspect of the present invention, the useable cell yield per wafer is increased by having weaker cells in areas that will be less illuminated, such as the ends of the rows of cells, and better-performing cells in more-illuminated areas, such as the central cells of a row of cells.

In a further aspect of the present invention, the cells that are individually connected electrically in parallel with each other are mounted on a first electrically conductive layer of a contiguous rigid substrate.

In an even further aspect of the present invention, the first electrically-conductive layer comprises two disjoint regions, and cell top contacts are electrically connected to one region and back contacts are electrically connected to the other region, where the region that the cell top contacts are connected to comprises fingers that between cells that receive light from a single secondary concentrator.

In a still further aspect of the present invention, the fingers carry current for more than half of the length of the substrate in the direction along the primary concentrator's focus.

In a still further aspect of the present invention, the top contacts of the cells that are individually connected electrically in parallel with each other are electrically connected to said first conductive layer with wire-bonds and all wire bonds for said cell array are made within a region of at most 100 mm by at most 100 mm, and preferably of at most 50 mm by at most 50 mm.

In an even further aspect of the present invention the contiguous rigid substrate comprises a second electrically conductive layer separated from said first electrically conductive layer by an electrically insulating layer, wherein said second electrically conductive layer and said electrically insulating layer each have a hole for each of said cells, the top contacts of said cells are electrically connected to said second electrically conductive layer.

In a still further aspect of the present invention, the first electrically conductive layer comprises at least 50% of the substrate area.

In a still further aspect of the present invention, the top contacts of the cells that are individually connected electrically in parallel with each other are electrically connected to said first conductive layer with wire-bonds and all wire bonds for said cell array are made within a region of at most ˜100 mm by at most 100 mm, and preferably of at most 50 mm by at most 50 mm.

In a still further aspect of the present invention said holes in said first electrically conductive layer are punched.

In a still further aspect of the present invention, the first electrically conductive layer has solder bonded to it, where the cells will go, and the second electrically conductive layer and the electrically insulating layer are bonded the to the first electrically conductive layer after that solder is bonded to the first electrically conductive layer.

In a yet further aspect of the present invention, the cells are bonded to the solder before the second electrically conductive layer and the electrically insulating layer are bonded to the first electrically conductive layer.

The above primary aspect and its subordinates form a group referred to as “cell-and-substrate aspects”.

In another primary aspect the present invention, provides multi-stage concentration where the first concentration stage comprises a primary concentrator that concentrates on a first concentration axis and is tracked, to follow the direction of the sun, on at least the first concentration axis; the second concentration stage comprises a plurality of secondary concentrators that each further concentrates a region of the primary concentrator's focus on a second concentration axis and that are tracked to follow the sun the second concentration axis, and where each of the plurality of secondary concentrators produces a focus that does not overlap foci from the other secondary concentrators; and the photovoltaic cells are arranged to receive light from the plurality of said non-overlapping foci, with said plurality of secondary concentrators formed as or on an integral part, and said integral part is optically coupled to said cells without an intervening refractive index lower than 0.25 below the refractive index of the secondary concentrators.

In a further aspect of the present invention any refractive index decrease is less than 0.1.

In a further aspect of the present invention the integral part with the plurality of secondary concentrators comprises glass, preferably low-iron glass or ultra-low-iron glass, and the surface upon which light impinges is preferable anti-reflection-coated.

In a further aspect of the present invention the integral part is roll-formed.

In a further aspect of the present invention each secondary concentrator concentrates between 5× and 15× on said secondary concentration axis, preferably 7× to 12×, more preferably 8× to 10×, with 9× to 9.5× being exemplary.

In a further aspect of the present invention concentration on said secondary concentration axis reaches its maximum concentration at substantially same place as concentration on said primary concentration axis reaches its maximum concentration.

In a further aspect of the present invention said secondary concentrators comprise linear lenses.

In an even further aspect of the present invention at least one end of each of said secondary concentrators is curved, in the direction of primary concentration, to refract light toward the center of the tightest focus of said primary concentrator.

The above primary aspect and its subordinates form a group referred to as “Lens tile aspects”.

In another primary aspect, the present invention provides multi-stage concentration where the first concentration stage comprises a primary concentrator that concentrates on a first concentration axis and is tracked, to follow the direction of the sun, on at least the first concentration axis; the second concentration stage comprises a plurality of secondary concentrators that each further concentrates a region of the primary concentrator's focus on a second concentration axis and that are tracked to follow the sun the second concentration axis, and where each of the plurality of secondary concentrators produces a focus that does not overlap foci from the other secondary concentrators; and a plurality of photovoltaic cells that are individually connected electrically in parallel with each other and that are arranged to receive light from a corresponding plurality of said non-overlapping foci, and light focused by at least one of said secondary concentrators is further concentrated on a least said primary concentration axis by a plurality of tertiary optical elements, or TOEs, that are molded as or on a single contiguous part.

In a further aspect of the present invention there is a one-to-one correspondence between TOEs and cells.

In a further aspect of the present invention, the TOEs concentrate at least 1.5× on primary concentration axis, preferably at least 2× and at most 3×, and more preferably between 2.3× and 2.5×.

TOEs are reflective concentrators, preferably using total internal reflection.

In a further aspect of the present invention, the TOEs are non-imaging concentrators.

In a further aspect of the present invention the TOEs further concentrate on said secondary concentration axis.

In an even further aspect of the present invention, the TOEs concentrate less on secondary concentration axis than they do on said primary concentration axis.

In an even further aspect of the present invention, the TOEs concentrate at least 1.25× and at most 2× on said secondary concentration axis, preferably at least 1.45×, and at most 1.55×.

In an even further aspect of the present invention, the final average concentration at the cone egresses is at least 1250×.

In a still further aspect of the present invention, the final average concentration at the cone egresses is between 1400× and 1600×.

In an even further aspect of the present invention, the TOEs are cones with substantially rectangular cross-sections.

In a further aspect of the present invention, the TOEs are less than 8 mm tall, preferably between 2 mm and 4 mm tall, more preferably 3 to 3.5.

In a further aspect of the present invention, the TOEs are molded from transparent material.

In an even further aspect of the present invention, the TOE rows separately molded and rows attached to the lens back.

In an even further aspect of the present invention, the TOEs for a given one of said secondary concentrators are molded on said given one of said secondary concentrators.

In an even further aspect of the present invention, the material is a transparent polymer, preferably flexible, more preferably silicone.

In a still further aspect of the present invention, the cones are flexible silicone and are compressed against cells, preferably >20 and <120 μm, more preferably 60 to 80 microns.

In a further aspect of the present invention, the TOE ingresses are adjacent (within 0.5%, exemplary 0.2% of cone ingress size) in the direction along the secondary concentrator's focus.

In a further aspect of the present invention, the TOEs where focus is less intense have bigger ingresses.

The above primary aspect and its subordinates form a group referred to as “TOE aspects”.

Cell-and-substrate aspects, lens tile aspects and TOE aspects are cooperative (aspects from any two or from all three groups), and when used together form combined aspects of the present invention.

The above aspects may be applied to either a dual-axis-tracked primary concentrator with the secondary concentrators fixed in relation to the focus of the primary concentrator; or to a primary concentrator tracked only on a single axis, with the secondary concentrators fixed in relation to the focus of the primary concentrator on that axis, and with the secondary concentrators micro-tacking on the secondary concentration axis. However other aspects apply only to embodiments with dual-axis-tracked primary concentrators, and still others are directed to embodiments with single-axis-tracked primary concentrators (these may also be applied to two-axis concentrators but are usually less preferred there).

A group of “dual-axis-tracked” aspects of the present invention provides any of the above aspects where in addition to being tracked to follow the direction of the sun on the first concentration axis, the primary concentrator is also tracked to follow the sun on the second concentration axis, with the secondary concentrators fixed in relation to the focus of the primary concentrator on both axes.

In a further aspect of the present invention, there is one single contiguous secondary tile per discrete primary concentrator segment.

In an even further aspect, the present invention efficiently handles the spill zones at the ends of the focus of a given mirror by having one more cells in parallel in the arrays of cells that receive light from the spill zones than for other arrays with which the spill-zone arrays are in series.

In a still further aspect of the present invention, the extra spill-zone cells comprise one additional row of cells per spill zone.

In a yet further aspect of the present invention, the receiver substrates for the spill-zone receivers are one row longer than the other substrates in a module.

In a yet further aspect of the present inventions, the spill-zone receivers each have a separate one-row extender substrate with which they are electrically in parallel.

In a further aspect of the present invention, the secondary concentrators are hermetically sealed to a module back that provides cooling means for the cells.

In an even further aspect of the present invention, the module back rejects heat to ambient air through fins via natural convection.

In a still further aspect of the present invention, the primary concentrator's aperture is at most 3 meters wide in the direction of primary concentration and the most of the heat from the cells is carried to the fins through thermal conduction in non-moving materials.

In a still further aspect of the present invention, the primary concentrator's aperture is at least 1.5 meters wide in the direction of primary concentration and most of the heat conduction to the fins is through a two-phased heat pipe.

In an even further aspect of the present invention, the module back is hermetically sealed to an integral lens tile at least 0.5 meters long, and preferably at least 1 meter long.

In a still further aspect of the present invention the module back and lens tile together have an overall longitudinal CTE less than 17 ppm/K (the CTE of copper).

In a still further aspect of the present invention, the module back and lens tile together have an overall longitudinal CTE greater than 11.5 ppm/K (the CTE of the typical galvanized steel).

In a yet further aspect of the present invention, the module back and lens tile together have an overall longitudinal CTE between 13 ppm/K and 15 ppm/K.

In a still further aspect of the present invention, the module back has a CTE higher than the CTE of the integral lens tile and is bonded to said integral lens tile at a temperature of at least 80° C. so that the longitudinal stress from the CTE mismatch between said heat-sink and said lens tile is at least largely compressive during normal operation of the system.

In a further aspect of the present invention, the receivers interconnect in series through conductive strips as they are bonded to the lens tile.

In an even further aspect of the present invention, the strips are copper.

In an even further aspect of the present invention, the strips are integral with a metal layer of substrate.

In an even further aspect of the present invention, the strips are placed on the lens tile before receivers are placed.

In an even further aspect of the present invention, the strips are bonded on receivers before receivers are placed.

A group of “single-axis-tracked-plus-micro-tracked” aspects the present invention provides any of the above aspects, except for the group of dual-axis-tracked aspects, where the primary concentrator is tracked to follow the direction of the sun only on the first concentration axis, the secondary concentrators fixed in relation to the focus of the primary concentrator on that axis, and with secondary concentrators micro-tacking on the secondary concentration axis.

In a further aspect of the present invention, the secondary concentrators are micro-tracked through rotation about an axis orthogonal to the primary tracking axis, where each receiver has its own lens tile with multiple linear lenses and the receiver maintains its position relative to its lens tile during rotation.

In an even further aspect of the present invention, each receiver has at least four and at most 6 rows of cells.

In an even further aspect of the present invention, each lens tile has at least four and at most six linear lenses.

In an even further aspect of the present invention, the rotation of the lens tile is around an axis that is offset from the center of the combined apertures of the secondary concentrators of a lens tile so the center of the combined apertures is farthest from the primary concentrator's tightest focus when the secondary concentrators are at zero skew angle to the concentrator's primary focus.

In an even further aspect of the present invention, the rotation of the lens tile is on or with axles that also serve as a coolant ingress and a coolant egress for coolant that absorbs heat from the cells.

In a still further aspect of the present invention, the rotation of the lens tile is with an axle that rotates in a grommet seal.

In a still further aspect of the present invention, the rotation of the lens tile is with a grommet seal that rotates on an axle.

In a broad aspect the present invention, provides improved ways to manufacture multi-stage concentration photovoltaic systems where the first concentration stage comprises a primary concentrator that concentrates on a first concentration axis and is tracked, to follow the direction of the sun, on at least the first concentration axis; the second concentration stage comprises a plurality of secondary concentrators that each further concentrates a region of the primary concentrator's focus on a second concentration axis and that are tracked to follow the sun the second concentration axis, and where each of the plurality of secondary concentrators produces a focus that does not overlap foci from the other secondary concentrators; and the cost of the overall system is reduced through at least one of: a plurality of photovoltaic cells that are individually connected electrically in parallel with each other and that are arranged to receive light from a corresponding plurality of said non-overlapping foci; the photovoltaic cells are arranged to receive light from the plurality of said non-overlapping foci, with said plurality of secondary concentrators formed as or on an integral part, and said integral part is optically coupled to said cells without an intervening refractive index lower than 0.25 below the refractive index of the secondary concentrators; light focused by at least one of said secondary concentrators is further concentrated on a least said primary concentration axis by a plurality of tertiary optical elements, or TOEs, that are molded on or as a single contiguous part.

In a primary aspect, the present invention provides improved ways to manufacture multi-stage concentration photovoltaic systems where the first concentration stage comprises a primary concentrator that concentrates on a first concentration axis and is tracked, to follow the direction of the sun, on at least the first concentration axis; the second concentration stage comprises a plurality of secondary concentrators that each further concentrates a region of the primary concentrator's focus on a second concentration axis and that are tracked to follow the sun the second concentration axis, where each of the plurality of secondary concentrators produces a focus that does not overlap foci from the other secondary concentrators; and where a plurality of photovoltaic cells that are individually connected electrically in parallel with each other are arranged to receive light from a corresponding plurality of said non-overlapping foci.

In a further aspect of the present invention, the cells that are individually in parallel with each other and receive light from a corresponding plurality of said non-overlapping foci, where the cells have back contacts that are electrically connected in parallel by bonding the cell backs to an backplane formed from one integral sheet of metal, preferably of copper, and the cells have front contacts that are electrically connected in parallel by bonding the cell backs to a power-plane formed from an integral sheet of metal, preferably of copper.

In an even further aspect of the present invention, the power-plane is formed by punching holes where the cells will go.

In a still further aspect of the present invention, the holes for all cells that are in parallel are punched together with the same punching action(s) to ensure consistent hole-spacing.

In an even further aspect of the present invention the power-plane is bonded to the backplane after the backplane has solder bonded to it where the cells will go.

In a further aspect of the present invention, the useable cell yield per wafer is increased by performance-binning cells and preferentially putting weaker-than-normal cells in areas that will be less illuminated, such as the ends of the rows of cells.

In an even further aspect of the present invention, the power output of a module is increased by preferentially putting stronger-than average cells where they will be more illuminated, such as the centers of rows.

The above primary aspect and its subordinates form a group referred to as “cell-and-substrate manufacturing aspects”.

In another primary aspect, the present invention provides improved ways to manufacture multi-stage concentration photovoltaic systems where the first concentration stage comprises a primary concentrator that concentrates on a first concentration axis and is tracked, to follow the direction of the sun, on at least the first concentration axis; the second concentration stage comprises a plurality of secondary concentrators that each further concentrates a region of the primary concentrator's focus on a second concentration axis and that are tracked to follow the sun the second concentration axis, where each of the plurality of secondary concentrators produces a focus that does not overlap foci from the other secondary concentrators; and where the photovoltaic cells are arranged to receive light from the plurality of said non-overlapping foci, with said plurality of secondary concentrators formed as or on an integral part, and said integral part is optically coupled to said cells without an intervening refractive index lower than 0.25 below the refractive index of the secondary concentrators.

In a further aspect of the present invention, the plurality of secondary concentrators are formed as or on an integral part by means of roll-forming, preferably in low-iron or ultra-low-iron glass.

In an even further aspect of the present invention, the roll-forming is done on large sheets that are subsequently cut into multiple parts that each comprises a plurality of secondary concentrators

Because the most-preferred secondary concentrators comprise lenses, the above primary aspect and its subordinates form a group referred to as “lens manufacturing aspects”.

In another primary aspect, the present invention provides improved ways to manufacture multi-stage concentration photovoltaic systems where the first concentration stage comprises a primary concentrator that concentrates on a first concentration axis and is tracked, to follow the direction of the sun, on at least the first concentration axis; the second concentration stage comprises a plurality of secondary concentrators that each further concentrates a region of the primary concentrator's focus on a second concentration axis and that are tracked to follow the sun the second concentration axis, where each of the plurality of secondary concentrators produces a focus that does not overlap foci from the other secondary concentrators; and where light focused by at least one of said secondary concentrators is further concentrated on a least said primary concentration axis by a plurality of tertiary optical elements, or TOEs, that are molded on or as a single contiguous part.

In a further aspect of the present invention, the TOEs are molded from transparent material.

In an even further aspect of the present invention, the TOE rows separately molded, from transparent material, and a TOE row is attached to a secondary concentrator's back.

In an even further aspect of the present invention, the TOEs for a given one of said secondary concentrators are molded on said given one of said secondary concentrators.

In a still further aspect of the present invention, the TOEs are doled using a mold that is itself molded from a TOE master formed from interdigitated parts.

The above primary aspect and its subordinates form a group referred to as “TOE manufacturing aspects”.

Cell-and-substrate manufacturing aspects, lens tile manufacturing aspects and TOE manufacturing aspects are cooperative (aspects from any two or from all three groups), and when used together form combined aspects of the present invention. Manufacturing aspects can also generally be combined with non-manufacturing aspects to form hybrid combined aspects.

In a further aspect of the present invention, there is a one-to-one correspondence between TOEs and cells.

In an even further aspect of the present invention, the material is a transparent polymer, preferably flexible, more preferably silicone.

In a still further aspect of the present invention, the cones are flexible silicone and are compressed against cells, preferably >20 and <120 μm, more preferably 60 to 80 microns.

The above primary aspect and its subordinates form a group referred to as “TOE manufacturing aspects”.

In a primary aspect, the present invention provides improved ways to manufacture multi-stage concentration photovoltaic systems where the first concentration stage comprises a primary concentrator that concentrates on a first concentration axis and is tracked, to follow the direction of the sun, on at least the first concentration axis; the second concentration stage comprises a plurality of secondary concentrators that each further concentrates a region of the primary concentrator's focus on a second concentration axis and that are tracked to follow the sun the second concentration axis, and where each of the plurality of secondary concentrators produces a focus that does not overlap foci from the other secondary concentrators; and the cost of the overall system is reduced through at least one of:
a plurality of photovoltaic cells that are individually connected electrically in parallel with each other and that are arranged to receive light from a corresponding plurality of said non-overlapping foci;
the photovoltaic cells are arranged to receive light from the plurality of said non-overlapping foci, with said plurality of secondary concentrators formed as or on an integral part, and said integral part is optically coupled to said cells without an intervening refractive index lower than 0.25 below the refractive index of the secondary concentrators;
light focused by at least one of said secondary concentrators is further concentrated on a least said primary concentration axis by a plurality of tertiary optical elements, or TOEs, that are molded on or as a single contiguous part;
   and the improved ways to manufacture comprise improved ways to assembly the components into a module.

In a further aspect of the present invention, TOEs that comprise a flexible transparent material are molded on the secondary concentrators, and during module assembly those TOEs are compressed against photovoltaic cells.

In a further aspect of the present invention, the secondary concentrators are formed in or on an integral part that is at least 500 mm long, and multiple substrates, each comprising at least one photovoltaic cell, are mounted to the integral part and the photovoltaic cells are optically coupled to the integral part, and the integral part is mounted in the focus of a primary concentrator that is tracked to follow the sun on two axes.

In an even further aspect of the present invention, the substrates are connected in series by mounting them to the integral part comprising the secondary concentrators.

In a still further aspect of the present invention a substrate is connected in series with a previously-mounted substrate by having a viscous electrically conductive material, which may preferably be electrically conductive epoxy or electrically-conductive silicone, dispensed on or near at least one or end of the substrate, with this dispensed electrically conductive material then contacting an electrical conductor that has previously been mounted on the integral part comprising the secondary concentrators.

In a yet further aspect of the present invention, where the electrical conductor that has been previously mounted is part of, or is attached to, a previous such substrate that has been mounted on the integral part comprising the secondary concentrators.

In a yet further aspect of the present invention, where the electrical conductor that has been previously mounted is one of a plurality of conductive strips that have been mounted on the integral part comprising the secondary concentrators before any of the substrates are mounted.

In a further aspect of the present invention forms a heat rejection means for the photovoltaic cells by first forming an integral part comprising fins that are wider, in the direction of the primary concentration, than the secondary concentrators are in that direction, where the fins are formed as an integral part with a base that is a least as wide as the fins, and, subsequent to forming the fins, cut the base free from the fins for part of its width but with the base still remains integral with the fins, and folding at least part of the cut-free width of the base to form one or more flanges, and then bonding the one or more flanges to an integral part comprising multiple secondary concentrators (preferably with dispensing a compliant thermal conductor between the back of substrates mounted on the integral part comprising multiple secondary concentrators), and then mounting the integral part comprising the secondary concentrators in the focus of a primary concentrator that is tracked to follow the sun on two axes.

In an even further aspect of the present invention, the integral part with the fins has a higher CTE than the integral part with the secondary concentrators, and these parts are bonded together at a temperature of at least 50° C. and more preferably at least 80° C.

The above primary aspect and its subordinates form a group referred to as “Manufacturing assembly aspects”.

All of the above aspects can be used to drive electrical circuitry that is in regions of low DNI, by using photovoltaics to transfer energy from photons of sunlight to electrons, wherein the sunlight is in regions of high DNI and is concentrated by means according to any of the aspects as described above, and the electrical energy produced is then transmitted over a transmission line to a regions of low DNI where it is used to drive electrical circuitry. The use of previously-discussed aspects to power circuitry in low DNI regions using sunlight concentrated in high-DNI regions is referred to as a “remote power displacement” aspect.

All of the above aspects can be used to displace fossil fuels, by using photovoltaics to transfer energy from photons of sunlight to electrons that then drive electrical circuitry, wherein the sunlight is concentrated by means according to any of the aspects as described above, and the electricity produced is then used to displace fossil fuels.

In a further aspect of the present invention, electricity produced by said above aspects displaces electricity that would have been produced through the combustion of fossil fuels for electrical power generation.

In an even further aspect of the present invention, the electrical circuitry comprises storage means, including, but not limited to, pumped-storage hydroelectricity, compressed-air energy storage, batteries, or electricity-to-fuels converters, where the store energy is then used to produce electricity that displaces electricity that would have been produced through the combustion of fossil fuels for electrical power generation.

In a further aspect of the present invention, fuels produced, by electricity-to-fuels conversion of electricity produced by said above aspects, are used to displace the consumption of fossil fuels in transportation, or electrical power generation.

The use of previously-discussed aspects to displace fossil fuels forms a group of aspects referred to as “fossil-fuel displacement” aspects.

Some of the above aspects of the present invention also can have uses outside of solar energy. By removing the tracking and the optics and replacing the CPV cells with LEDs of similar or lesser heat dissipation (and bypass diodes may be replaced with ‘LED Shunts’, also known as “LED Open Protectors), the cell-and-substrate aspects can be applied to arrays of LEDs. By including the TOE aspects and the lens tile aspects; these aspects can function as collimators for light from the LEDs. In particular the modules taught in the dual-axis-tracked CPV aspects, with their low-cost substrate, efficient low-cost optics, and integrated low-cost cooling, can have CPV cells replaced with HBLEDs, their flow of current reversed, and become low-cost, high-brightness luminaires that are highly suitable for architectural lighting or for horticulture (as exemplified by, but not limited to, vertical farms and container farms). These aspects form a group of aspects referred to as “LED-compatible” aspects.

### Definitions

“Acceptance Angle” as used herein means the angular range over which light entering the tracker aperture or mirror aperture will generally be reflected, refracted and/or diffracted so that it reaches the cell of a receiver, and is thus ‘accepted’ by those cells.

“Active Cooling” as used herein means a system that uses applied power to remove heat, such as pumps or fans. See also “Passive Cooling”.

“Altitude” as used herein means vertical angle above the horizon (e.g., the altitude of the sun is the angle that the sun is above the horizon).

“Altitude Tracking” as used herein means motion in the vertical direction to track the height of the sun.

“Aperture” as used herein means the profile of the light-collecting area as seen from a direction that maximizes its apparent (effective) size.

“Aperture area” as used herein means the light-collecting area of the aperture.

“Bus Bar” as used herein means a large conductor that receives electrical current from, or delivers electrical current to, a number of smaller conductors. Also written as “bus-bar”.

“Bypass Diode” as used herein means a one-way device for electrical current, which will let current substantially freely flow across it in one direction if the voltage on a first side of the diode is higher than the voltage on a second side, but will substantially block the flow of current in the reverse direction if the voltage on the first side is lower than the voltage on the second side.

“Cell” as used herein means a photovoltaic cell with external contacts (as opposed to the sub-cells of a multijunction cell). While it will be obvious to one familiar with the art of mounting PV cells that dual-back contact cells and dual-front contact cells can be used in many of the preferred embodiments, in all embodiment cells with one contact polarity on back and the other contact polarity on front are preferred, and all examples use such cells.

“Cell String” as used herein means a string of photovoltaic cells that are connected in series. While a string of cells adds cell voltages (rather than cell currents) and thus minimizes conductor sizes and resistive losses, the cells must either be evenly illuminated or have bypass diodes to prevent a less-illuminated cell from reducing the efficiency of the entire cell string. Also called a “String of Cells”.

“Coefficient of Thermal Expansion” and “CTE”) as used herein means the rate at which the size of an object changes due to changes in the object's temperature, usually measured in parts-per-million per Kelvin (ppm/K). Differences in thermal expansion can cause thermal stress in materials especially when large regions of rigid materials with substantially different CTEs are bonded together at one temperature and then heated or cooled to a significantly different temperature.

“Compound Parabolic Curve”, or “CPC” as used herein means a shape formed from the union of two parabolic curves. CPC can also refer to a Compound Parabolic Concentrator, which is a concentrating optical element whose shape has cross section, in at least one dimension, that is substantially a Compound Parabolic Curve.

“Cold Plate” as used herein means a cooling device with numerous small channels cut into it to allow for high channel surface area near a surface to be cooled.

“Concentration” as used herein can be either geometric concentration, which is the ratio of the aperture size to the focal spot size (this ignores imperfections in mirrors and minor shadows but is useful for calculating acceptance angles and focal spot sizes), or illumination concentration, which is the ratio of the intensity of focused sunlight to the intensity of direct sunlight, and which thus includes the losses from such imperfections. Geometric concentration is symbolized with an ‘x’ (e.g., 100×), whereas illumination concentration is measured in ‘suns’ (e.g., 1000 suns).

“Cooling Tube” as used herein means a tube that carries a fluid to cool a photovoltaic receiver.

“Cylindrical” as used herein means a surface that at every point bends in at most one direction, with the directions of curvature at all points substantially parallel to each other (like a section of a cylinder).

“Dense Receiver Array” as used herein means a receiver array where the photovoltaic cells of an array of cells are packed into an area less than twice as large as the total receptive area of the cells themselves. See also “Semi-dense Receiver Array” and “Sparse Receiver Array”.

“Focus” when used as a verb herein is meant redirecting light from a larger area to a smaller area so that the light in the smaller area is more intense (more light per area) than the light in the larger area was.

“Focus” when used as a noun herein is meant a smaller area that light from a larger area is directed into, with the light in the ‘focus’ area being more intense (more light per area) than the light in the larger area was.

“Focuses on” as used herein refers one element being in the focus of another element, but not necessarily at the tightest focus.

“Focal Length” as used herein means the distance from focusing a mirror or a lens at which the focus and the focal spot are smallest.

“Focal Line” as used herein means a linear region (much longer in one dimension than it is wider in the perpendicular direction into which substantially all of the light focused by a lens or a mirror is concentrated.

“Focal Width” as used herein means the width of a focal line.

“Fossil Fuels” as used herein means fuels that are obtained from long-dead plants, fungi, bacteria, archaea and/or animals or other life-forms yet to be discovered.

“Fresnel Lens” as used herein means a lens that instead of using a continuously curved surface (which results in a standard lens whose thickness, for given focal length, grows approximately with the square of its diameter), uses discontinuous segments of comparable curvature and angle to the standard lens surface but arranged so that the segments form a thin sheet whose thickness is relatively independent of the lens diameter. This emulates the focusing of a standard lens, but requires much less material for even a moderate-aperture lens.

“Full sunlight” as used herein means sunlight with a Direct Normal Insolation of 1000 W/m² with an air-mass 1.5 spectrum.

“Grazing angle” as used herein means a very low incidence angle that causes much of the light incident at that angle light to be reflected from a surface, even the surface would readily absorb such light if it came in at a higher incidence angle.

“Grid finger” as used herein means a long, narrow, electrically-conductive part of the top grid (of a photovoltaic cell) that has photo-receptive regions on at least two sides.

“HCPV” as used herein means CPV that uses a concentration ratio of at least 100× (and more typically 600× to 2000×). This concentration range is readily achievable with two-axis focusing. See also “High Concentration” and “Very High Concentration”.

“Heat Pipe” as used herein means a sealed tube, or pipe, that transfers heat from a hot region to colder regions of the heat pipe. By starting with just a liquid (such as water) and its vapor in the pipe, the liquid is rapidly evaporated at the hot region and there is little resistance to the vapor travelling to all colder surfaces of the pipe, where it condenses and whence it is returned either by gravity or by capillary action to the hot end of the pipe to complete the cycle. Since evaporating a liquid absorbs a lot of energy and the vapor can move at up to the speed of sound, a heat pipe can provide thermal conductivity over a hundred times higher than solid copper.

“High Concentration” as used herein means at least 100×. This concentration range is readily achievable with two-axis focusing. See also “Very High Concentration”.

“Imaging” as used herein means an optical element (or shape thereof) that focuses light without scrambling it, so that a sheet of paper held at the focus would show an approximate image of the object from which the light originates. See also “Non-imaging”.

“In Parallel” as used herein means photovoltaic cells that are connected so that their ends are at substantially the same voltages and their photocurrents add together. See also “In Series”. Sometimes referred to as “individually connected electrically in parallel” to emphasize the difference from putting series-connected groups of things (e.g., photovoltaic cells) in parallel.

“In Series” as used herein means photovoltaic cells that are connected together so that the higher-voltage contact of one cell is connected to the lower-voltage contact of the next cell. In this way the voltages of the cells add together, while the current from the cells is not increased. See also “In Parallel”.

“In the focus of” as used herein refers to mounting something where it will receive the focus of something, but is not necessarily at the tightest focus. For example, in many preferred embodiments a trough focuses on a lens tile, but the front of the lens tile is slightly before the trough's tightest focus because this lets the trough's focus continue converging (rather than start diverging) within the lens tile.

“Inverter” as used herein means a device that converts direct current (the output of essentially all photovoltaic systems) into alternating current (the type of current carried by essentially all power lines (with a few very long transmission lines being exceptions).

“Kerf” as used herein means the region of an item that is reduced to sawdust when the item is cut with a saw.

“Lens Sheet” as used herein means a contiguous sheet of transparent material in which, or on which, numerous individual lenses are formed.

“Lens tile” as used herein means a contiguous sheet of transparent material comprising multiple lenses, and including TOEs if those are molded on the lens sheet.

“Light-gathering area” when used without qualification herein refers to the primary light-gathering area of a PV system.

“Linear lens” as used herein means a lens that has a substantially uniform profile in one dimension for more than half of its length in that dimension.

“Low-iron Glass” as used herein means a very clear (low absorption, low dispersion) soda-lime glass commonly used in thin window and in solar energy. As its name suggests, low-iron glass is very low in iron content. See also “Ultra-Low-iron Glass”

“Microcell” (also “micro-cell”) as used herein means a photovoltaic cell with an area of less than 1 mm² (or less than one one-millionth of a square meter).

“Multi-junction cell” as used herein means a photovoltaic cell that has multiple photovoltaic junctions (electron-liberating regions) stacked on top of one another. Because most semiconductors are transparent to photons of lower energy than their band gap, high band-gap layers capture the most energetic photons (e.g. ultraviolet, blue) to generate power, while letting lower-energy photons pass on to the next junction (photovoltaic region), etc. This raises the overall efficiency because the photons absorbed by each layer have only a little excess energy above that needed to liberate an electron over the band gap. However, the photocurrents (number of electrons liberated per unit time) of the junctions must typically be matched because the layers are typically in series (which adds the voltages of the layers, reducing resistive losses).

“Non-Imaging” as used herein means an optical element (or shape thereof) that concentrator light without maintaining an image of the object emitting the light. While for a telescope the image of an object is essential, an image is not essential for a solar energy receiver, and not having to maintain an image creates more freedom in concentrator design and allows for significantly higher concentration.

“Off-axis” as used herein means a mirror or other concentrator whose aperture is solely to one side of its focus so that if focusing light onto a receiver the size of the concentrator's focal line or focal spot, the concentrator would not be shaded by the receiver.

“Optical Efficiency” as used herein means the percentage of light entering the aperture of a concentrator that reaches a receiver that that concentrator is focusing on.

“Optically Coupled” as used herein means that one substantially transparent object is optically joined to another object through a substantially transparent material whose refractive index is preferably between that of the two materials and is at most 0.25 higher than the refractive index of the object with the higher refractive index and at most 0.25 lower than the refractive index of the object with the lower refractive index.

“Passive Cooling” as used herein means a system that uses no applied power other than the heat itself to move heat from a hot region (such as a solar cell) to a cold sink (such as the atmosphere). See “Heat Pipe” and “Active Cooling”.

“Petzval effect” as used herein refers to light reaching a lens (or other concentrating element) at a range of angles in one dimension ‘seeing’ a range of curvatures, and thus focal lengths, in the orthogonal dimension.

“Photocurrent” (also “Photo-current”) as used herein means the current generated by a photovoltaic cell (which comes from the rate at which electrons liberated at a photovoltaic junction are collected and delivered to a photovoltaic cell contact).

“Photovoltaic” as used herein means using the energy of individual photons of light to liberate electrons from a semiconductor, and collecting those electrons to deliver them as electrical current.

“Polymeric Optical Materials” as used herein refers to transparent materials that comprise long molecular chains of repeating unit. These are generally soft and easy to mold compared to glass.

“PPM” (also “ppm”) as used herein means parts per million.

“Primary Concentrator” as used herein means the first concentrating element that incident sunlight is reflected by in a system with multiple focusing elements in its light path. See also “Secondary Concentrator”.

“Receiver” as used herein means a device comprising one or more photovoltaic cells that are individually connected electrically in parallel with each other. A receiver generally includes ancillary functions such as mechanically supporting the cell(s) cooling for the cell(s).

“Reflection” as used herein refers to the symmetric change in angle of a light ray as that stays within one medium after reaching the interface to another medium.

“Refraction” as used herein refers to the change in angle of a light ray as it passes from one medium to another medium.

“Resistive Losses” as used herein means the loss of power through the voltage drop caused by electrical resistance. These losses are proportional to the resistance times the square of the electrical current.

“Rim Angle” as used herein means the half the angle that concentrator subtends when viewed from the focus of that concentrator.

“Secondary Concentrator” as used herein means an entity that further concentrates and redirects light focused by a primary mirror or lens.

“Semi-Dense Receiver Array” as used herein means a receiver array where the photovoltaic cells of an array of cells are spread across an area at least twice as large as the total receptive area of the cells themselves, and at least ten times smaller than the overall primary aperture through which sunlight will be focused onto the cells.

“Solar Thermal” as used herein means a system that captures the sun's energy as heat, which is then typically put to productive use to generate steam to run a turbine to turn a generator to produce electricity.

“String” as used herein means a set of photovoltaic elements (cells, receivers or modules) connected in series. While a string of such elements adds voltages (rather than currents) and thus minimizes conductor sizes and resistive losses, the photovoltaic elements must either be evenly illuminated or have bypass diodes to prevent a less-illuminated element from reducing the efficiency of the entire string.

“Substrate” as used herein refers to a contiguous mechanical support on which one or more photovoltaic cells are attached. The substrate is typically highly thermally conductive and sometimes also electrically conductive, and is often made up of one or more electrically conductive layers alternating with one or more electrically insulating layers.

“Suns” as used herein means the ratio of the intensity of focused sunlight to the intensity of direct sunlight, which is similar to geometric concentration but also includes losses such as shadows from supporting structures and mirrors not being perfectly reflective. See also “Concentration” and “X”.

“Tertiary Optical Element”, or “TOE”, as used herein refers to an optical element that is the third optical element in series that guides light to reach one or more photovoltaic cells.

“Thermal Expansion” as used herein means the change in size of an object due to changes in the object's temperature. See also “Thermal Coefficient of Expansion”.

“TOE” as used herein refers to a Tertiary Optical Element.

“Top Contact” as used herein means an electrical contact on the top (receptive) surface of a photovoltaic cell that is connected to a bus-bar that serves as one of the cell's electrical contacts.

“Top Grid” as used herein means an electrically conductive region the top (receptive) surface of a photovoltaic cell that comprises one or more grid fingers, and typically comprises at least one bus-bar and at least one top contact.

“Tracker” as used herein means a device that changes angle as the sun ‘moves’ so as to keep one or more mirrors or lenses on the tracker focused on one or more receivers.

“Triple-junction Tandem Cell” as used herein means a photovoltaic cell that has three different junctions with three different band-gaps stacked on one another so that each can absorb photons of an energy that it can convert efficiently to electricity. Triple-junction cells currently have a maximum efficiency of around 46%, which is much higher than that of silicon cells or thin film photovoltaics. On the other hand, triple-junction cells currently cost 1000 times more per area than silicon cells, and so require concentrated light to be economical.

“Two-Axis Tracker” as used herein means a tracker that tracks in two dimensions to compensate for the changing position of the sun. Two-axis trackers are generally azimuth/altitude trackers, where one tracking dimension corresponds to the compass direction of the sun and the other dimension corresponds to its height above the horizon. Daily/seasonal trackers and X/Y trackers also exist but are less common.

“Ultra-low-iron Glass” as used herein means a very clear (low absorption, low dispersion) soda-lime glass. As its name suggests, ultra-low-iron glass is even lower in iron content than low-iron glass, and hence is even clearer, and is typically used in thicker glass windows for skyscrapers.

“Very High Concentration” as used herein means 500× to 2000×, ideal for high-efficiency triple-junction cells at today's cell costs. See also “High Concentration”.

“X” as used herein means the geometric concentration. When a focal spot has its own aperture area, or light gathering area, this is simply that areas divided by the focal area; when a primary aperture feeds multiple foci it is the aperture area divided by the total focal area. When referring to part a more complex part of a focus, X refers to the intensity ratio (“suns”) divided by the optical efficiency (this is a more generalized definition that reduces to the geometric area ratio in the simpler case). See also “Concentration” and “Suns”.

### BRIEF DESCRIPTION OF THE DRAWINGS

FIG. 1A is an illustration of the prior art of a Fresnel/Box HCPV system.

FIG. 1B is a more detailed illustration of a receiver of the prior art of a Fresnel/Box HCPV system.

FIG. 1C is an illustration of the prior art of two-axis trackers, which are used in most HCPV systems.

FIG. 1D is an illustration of the prior art of single-axis trackers, which are used in some of the HCPV systems that use single-axis primary concentrators.

FIG. 2 is an overview illustration of the present invention, showing a linear primary concentrator focusing on a lens tile, as is characteristic of the preferred embodiments of the present invention.

FIG. 3A is a more detailed illustration, of a cross-section across the primary concentrator's focus, of a lens tile with multiple linear lenses, with each lens focusing on a row of tertiary optical element, each of which guides light to a photovoltaic cell, as is characteristic of most preferred embodiments of the present invention.

FIG. 3B is a more detailed illustration, of a cross-section along the primary concentrator's focus, of a lens tile with multiple linear lenses, with each lens focusing on a row of tertiary optical elements, each of which guides light to a photovoltaic cell, as is characteristic of most preferred embodiments of the present invention.

FIG. 3C is a similarly detailed illustration, of a cross-section along the primary concentrator's focus, of a lens tile with multiple linear lenses, with each lens focusing onto a row of photovoltaic cells, with all cells of the multiple rows of cells in parallel.

FIG. 4A is a detailed illustration of a conical tertiary optical element, as is characteristic of most preferred embodiments of the present invention

FIG. 4B is a detailed illustration of an algorithm to optimize a conical tertiary optical element for preferred embodiments of the present invention, along with the geometry on which the algorithm is based, specifically for a first flat facet.

FIG. 4C is a detailed illustration the algorithm of 4B extended to a curve approximated by additional facets.

FIG. 4D is an illustration of a unit section of a master array of TOEs, and of how multiple such units can interdigitate to form a master array of TOEs that can be used to make inexpensive molds to mold arrays of TOEs on the back of lens sheet.

FIG. 4E is an illustration of a mold made that may be made from a master array of TOEs and can be used to mold arrays of TOEs on the back of lens sheet.

FIG. 5A is an overview illustration of how the three-stage optics transform sunlight first to a long, narrow focus, then to a series of short focal lines, and then to an array of tiny rectangular foci, with that array of tiny foci matched by a segmented array of microcells, as is characteristic of most preferred embodiments of the present invention.

FIG. 5B is a cross-section illustration of a receiver with a 2D array of microcells on a contiguous substrate, as is characteristic of the present invention.

FIG. 5C is a cross-section along the troughs focus, showing a tertiary optical element compressed against a cell and against the cell's bondwire, as is characteristic of some preferred embodiments of the present invention.

FIG. 6A is an illustration of a preferred process for accurately producing high-accuracy hole in the thin isolation under the power plane aligned with more-relaxed holes in the power plane itself.

FIG. 6B is an illustration of a substrate that is manufacturable with a standard insulated-metal-substrate process and that may be used with many preferred embodiments of the present invention.

FIG. 6C is detail illustration of the area around one photovoltaic cell site of the substrate illustrated in 6B.

FIG. 6D is an illustration of an alternative preferred process for manufacturing a substrate that may be used with many preferred embodiments of the present invention, in which solder is bonded to the substrate backplane before the power plane is bonded to the substrate backplane.

FIG. 7 is a detailed illustration of the optimized top grid for a tandem microcell as used in some preferred embodiments of the present invention.

FIG. 8 is an illustration of preferred ways to optimize the module of the present invention for the uneven distribution of light across the trough's focus.

FIG. 9 is an illustration of a preferred arrangement of modules of the present invention, together with their mirrors, mounted on a two-axis tracker.

FIG. 10 is detailed an illustration of the tapering of light intensity in the spill zone at the of the linear primary concentrator's focus, and showing the preferred receivers for the module ends to compensate for the tapering intensity.

FIG. 11A is an along-the-primary-focus illustration of a preferred module housing and cooling for an exemplary embodiment of the present invention.

FIG. 11B is an across-the-primary-focus illustration of a preferred module housing and cooling for an exemplary embodiment of the present invention.

FIG. 11C is an along-the-primary-focus illustration of an extruded profile suitable for a second preferred module housing and cooling for an exemplary embodiment of the present invention.

FIG. 11D is an across-the-primary-focus illustration of the second preferred module housing and cooling for an exemplary embodiment of the present invention.

FIG. 12A is an across-the-primary-focus illustration of an alternate cooling arrangement that uses a thermosiphon heat pipe with multiple fin tubes to provide more aggregate fin area than can be efficiently provided by simple fins.

FIG. 12B is an along-the-primary-focus illustration of an alternate cooling arrangement that uses a thermosiphon heat pipe with multiple fin tubes to provide more aggregate fin area than can be efficiently provided by simple fins.

FIG. 13A is an along-the-primary-focus illustration of a preferred arrangement of receivers micro-tracked on a second axis when a primary concentrator that concentrates on a single axis is tracked only on that axis.

FIG. 13B is an across-the-primary-focus illustration of a preferred arrangement of receivers micro-tracked on a second axis when a primary concentrator that concentrates on a single axis is tracked only on that axis.

These figures are presented by way of example, and not by way of limitation, and unless otherwise specified in the accompanying text, the provision of a given number of items, or a given style of an item, is merely illustrative.

For consistency and ease of understanding, items in figures are numbered FS###, where F is the Figure number, S (optional) is the figure suffix when several related figures share a figure number and a (for brevity a suffix is not used for items introduced in the ‘A’, figure of a set of figures), and ### is the hierarchical component number in the following hierarchy:
F0=Tracker
   F01=rails to attach primary concentrators to
F1=Primary concentrator/mirror
   F10=sheet of primary concentrators
   F11=individual primary concentrator of sheet
F2=Secondary concentrator/lens
   F20=lens sheet
   F21 lens tile
      F210=Lens glass
      F211=lens
         F2111=lens end
   F22=indent
   F23=support
      F231=hard stops
F3=TOEs (Tertiary Optical Elements)
   F301=TOE-master sparse-array unit
      F3011=finger of sparse-array unit
      F3013=TOE of spare-array unit
   F302=TOE casting mold
      F3020=Row of TOE cavities of TOE casting mold
      F3023=TOE cavity of TOE casting mold
      F3025=Photodetector pair TOE cavity of TOE casting mold
   F31=TOE/cone
      F311=TOE ingress
      F312=TOE egresses
      F3131=flat facet of TOE body
F4=Receiver
   F4′=receiver being placed
   F4″=previous receiver placed
   F41=substrate
      F410=heat spreader
      F411=Conductor
         F4111=backplane
            F41111=exposed end of backplane
            F41112=finger of backplane
            F41113=enlarged area on finger of backplane
            F41115=cell site on backplane
         F4112=power plane
            F41121=smear or burr from power plane punching
            F41122=finger of power plane
            F41125=cell hole in power plane, optionally thin isolation
            F411253=bond-wire site on power plane
      F412=Isolation
         F4120=isolated sheet
         F4121=thick isolation (capable of withstanding high voltage)
         F4122=thin isolation
         F4123=etch stop
         F4124=patterned soldermask
      F413=punch for punching power-plane/isolation holes
   F42=bypass diode
   F43=connection strip
   F462=connector cage per receiver
F5=Cell
   F5′=central cells
   F5″=peri-central cells
   F5′″=peri-end cells
   F5″″=end cells
   F50=row of cells/cell row
      F50′=extra row of cells
      F50″ row next to extra row of cells
   F51=active area
   F52=bus bar
      F521=bonding pad
      F522=grid fingers
   F53=bond wire
      F530=bond wire contact point
   F54=Edge of cell
      F541=near edge (of cell)
F6=Whole module
   F61=housing
      F611=module back
         F6110=material that will become the module back
         F6111=flanges
         F6112=flange extensions
         F6113=notches
         F6114=axle
         F6115=actuator pivot
         F6116=actuator rod
         F6117=wicket
         F6118=wicket bead
      F613=fins
         F613x=removed material
      F614=evaporation chamber or cold plate
         F6141=cover
         F6142=common coolant pipe
         F6143=fin tube
         F6144=fins
         F6145=wick
         F6146=coolant
            F61460=pool level
   F62=connector cages
F7=Joining material
   F71=solder
   F72=optical coupling
      F721=coupling block
   F73=conductive adhesive
   F74=mechanical adhesive (lens-to-substrate)
   F75=thermally conductive adhesive (substrate-to-housing)
   F76=weatherproof adhesive (lens-to-housing)
F9=Light
   F90=light-gathering area
   F91=trough's focus
      F911=spill zone
         F9110=spill zone middle
         F9111=spill zone strong end
         F9112=spill zone weak end
      F912=far-edge light
      F913=near-edge light
   F92=lens focusing
   F93=tiny foci from TOEs

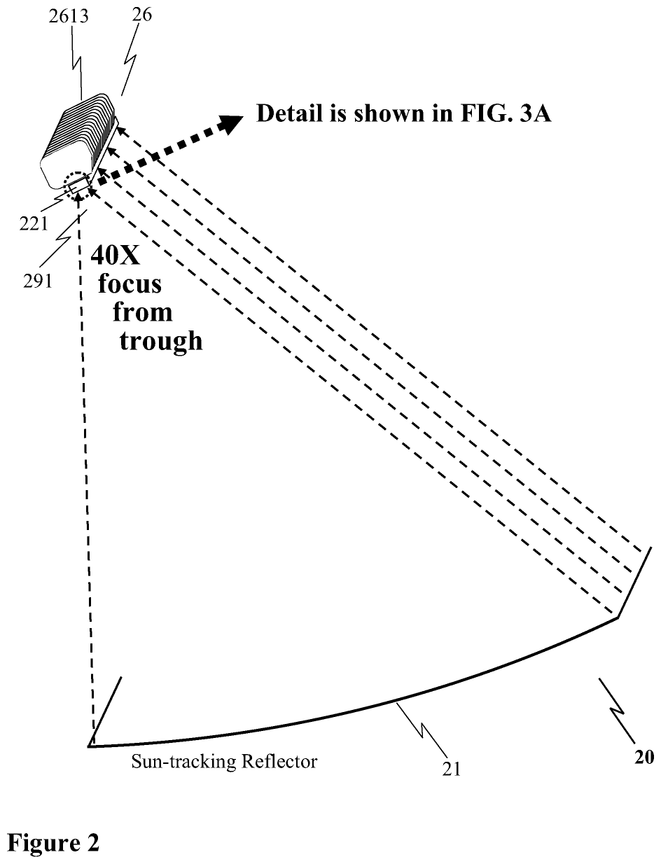

For example, item 221 would refer to FIG. 2 component 21, or a lens tile (F21) in FIG. 2. If the same item is shown in more than one figure, it keeps the number of first use. A zero generally refers to a group (e.g., F50 is a row of cells F5), and a 9 generally refers to something that is produced (e.g., the focus of the trough F91 is not something manufactured, but is produced by the trough mirror being oriented to the sun).

### DESCRIPTION OF THE PREFERRED EMBODIMENTS

While scaling system optics to small dimensions and using microcells brings numerous advantages, individually assembling vast numbers of tiny receivers and distributing them across the entire light-gathering area has made microcell HCPV systems too costly to displace fossil fuels (or to even compete with inefficient low-cost-semiconductor flat PV panels). Applying primary concentration to a prior-art air-gap-free microcell array would be counterproductive because such arrays already push material and manufacturing limits to reach ˜1000×. This can clearly be seen in the steep-sided 2D-focusing lenses of the Hayashi1 microcell system, which complicate molding (already precluding low-cost roll-forming), and increase surface reflection even with tailored anti-reflection coatings, and barely reach 150× with a highly non-uniform light distribution. Concentrating a trough's focus on a second axis would suffer from the Petzval effect on the secondary concentration, even further reducing the already-too-low concentration. That higher concentration is key can be seen by Hayashi moving away from the solid sheet and reintroducing an air-gap in Hayashi2, raising the final concentration from ˜150× in Hayashi1 to about 480× in Hayashi2 (still on the low side to make tandem cells cost effective), even at the cost of molding two sheets instead of one, and even at the cost of reducing optical efficiency with the addition of a sharp refractive index change on each side of the air gap (eliminating what Hayashi1 had highlighted as an advantage).

While Furman teaches reaching 1000× onto microcells, it can be seen that the system (namely, Furman's system) is again a large, sealed box, giving up much of the scaling advantage, and the optical efficiency is only around 80%. Furthermore Furman requires a separate ball lens for each microcell; these are another part to place in vast quantities, they further complicate subsequent receiver handling by transforming the thin, flat pre-lens receiver into a bulky 3D structure, and they preclude unifying the optics into a single sheet.

In both Hayashi and Furman, the Petzval effect (light reaching a lens at different angles in one dimension ‘seeing’ a different curvature, and thus focal length, in the orthogonal dimension) from primary concentration would reduce the lenses' ability to concentrate on the second axis, thus reducing the concentration and increasing the cell cost. The higher power density would also complicate the cooling, reducing one of microcells' key strengths of a thin metal sheet, already used for the module back, efficiently spreading the heat to an area the size of the whole light-gathering area. Using a trough primary concentrator would thus be an anathema to Hayashi and Furman, amplifying key weaknesses and reducing key strengths.

Similarly scaling the prior-art linear-primary-concentration HCPV systems to use microcells would be counterproductive. Corino1 is illustrative—scaling the lenses and receivers to use microcells even a full millimeter on a side would not change the receiver length, but would require three times as many receivers, with each receiver having 24 small cells instead of 8 medium cells. There would be three times more discrete lens elements, three times more receivers to assemble, place and interconnect, and, with the substrate still needing space for diodes, connector cages and the patterned top metal to support them, the total area of expensive metalized electrically-isolating thermal conductor would increase as well. Furthermore the number of cells to place would increase nine-fold; the number of inter-cell gaps would triple, tripling light losses into the gaps, and the proportion of the cell area devoted to bus-bars would increase three-fold as well, increasing the cell fabrication cost (and microcells even smaller than a square millimeter would make these drawbacks even worse).

In “High-Concentration Solar Trough Collectors and their Application to Concentrating Photovoltaics”, Cooper discusses that narrower trough rim angles can reach higher concentration in systems where trough-based primary optics and linear secondary concentrators are used, but teaches away from lens secondary concentrators and toward CPC or similarly-shaped DTERC reflectors as secondaries, and teaches away sheets of secondary concentrators, with individual linear secondaries that rotate to track the sun on one axis to achieve higher concentration, with each linear secondary requiring its own flexible connections to a pumped coolant supply. This would also not be suitable for microcells for similar reasons to SunOyster, and would have the further penalty addition of increasing the number of mobile mechanical and coolant connections. Cooper thus teaches a series of foci similar to SunOyster but even larger, with five 1 cm² or 500 mm² in total versus the 72 mm² of SunOyster's eight 3 mm×3 mm cells.

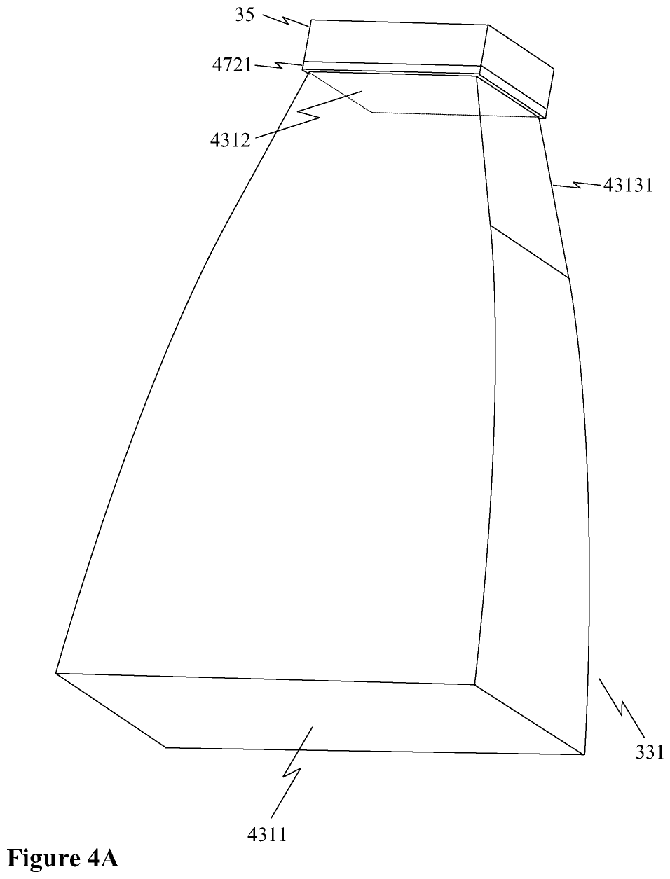

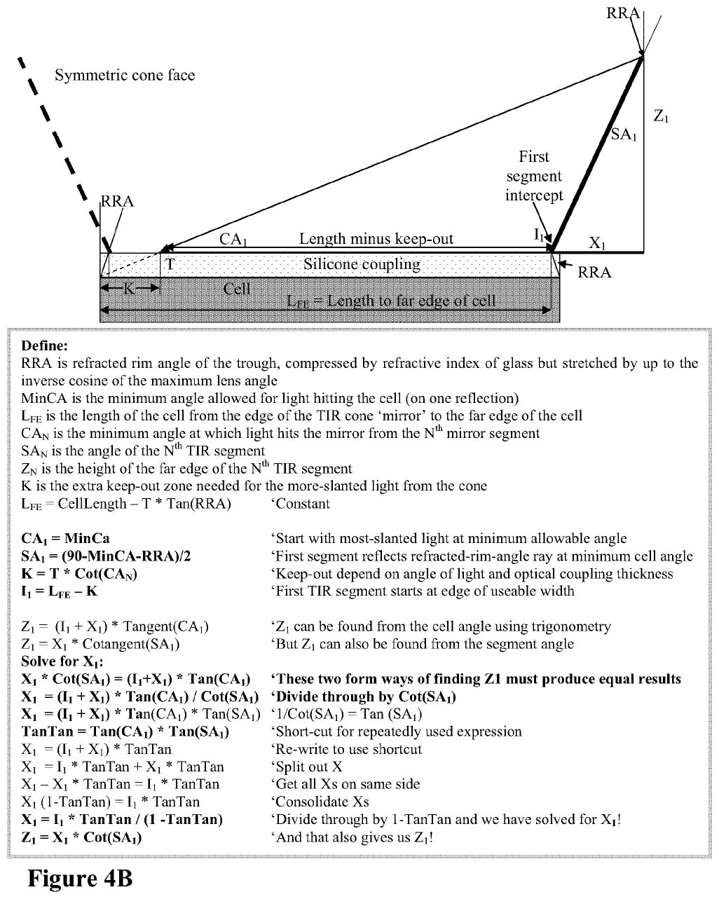

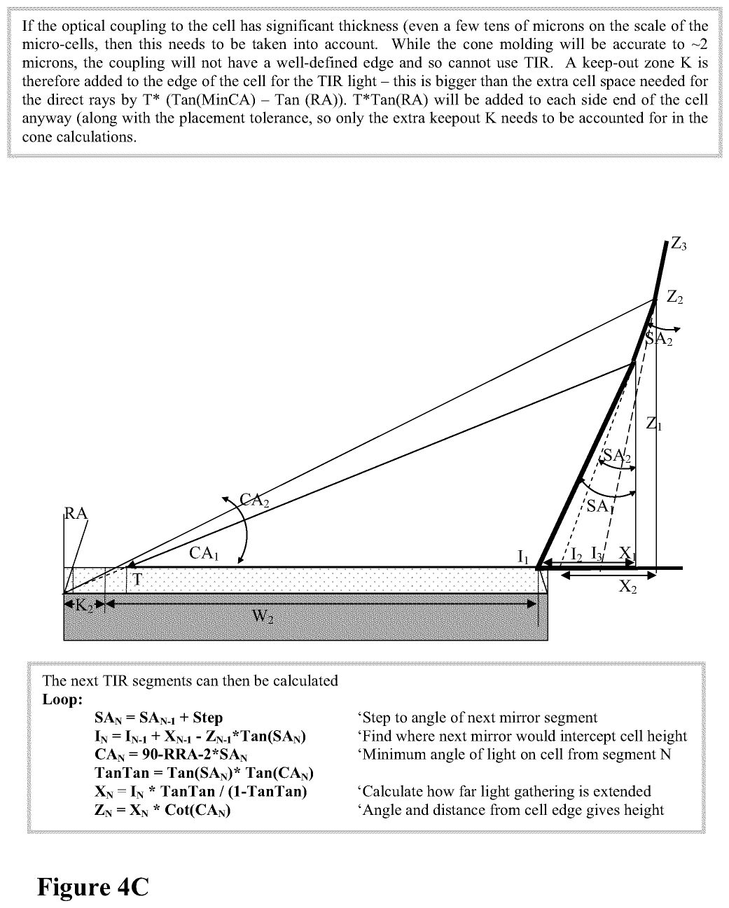

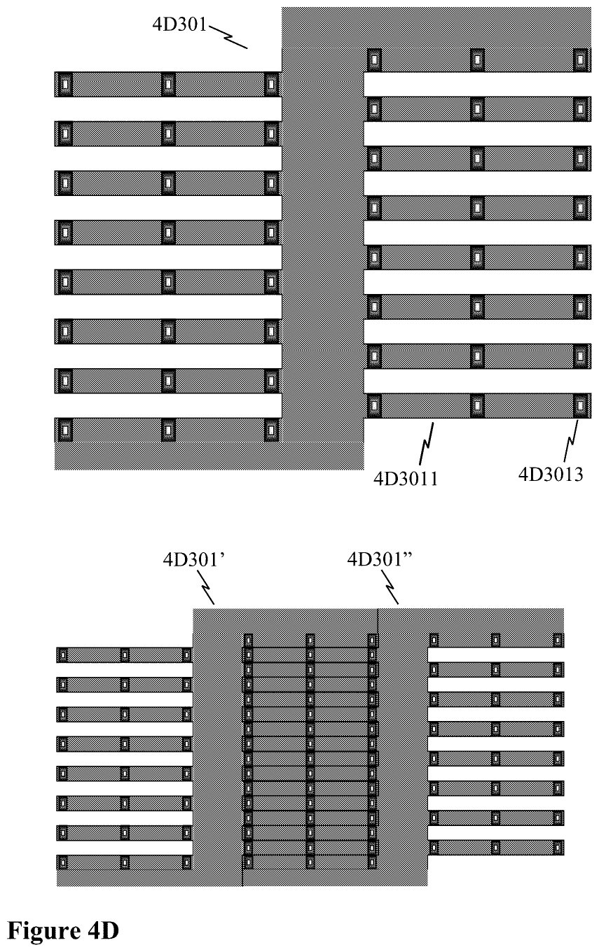

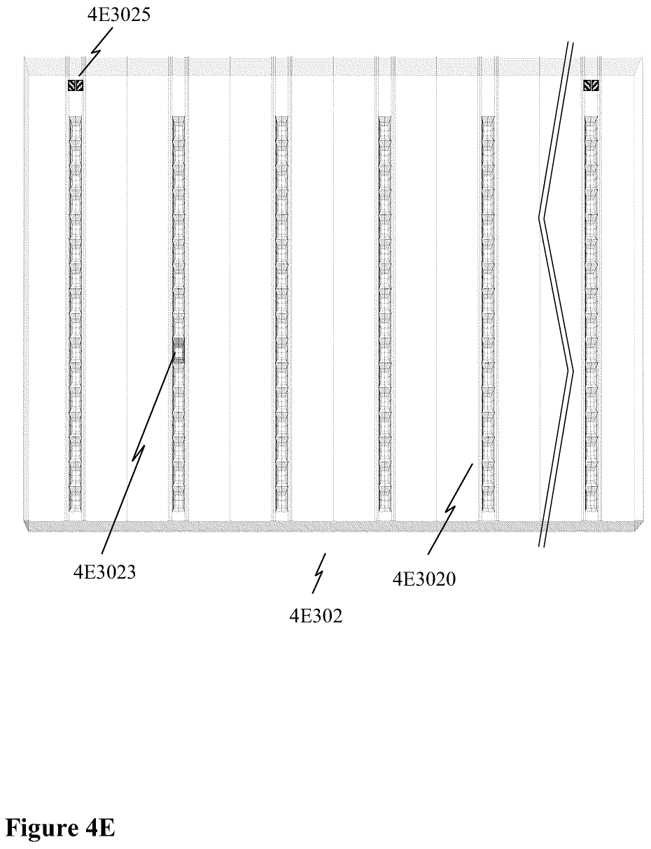

While Cooper's FIG. 4.28 shows that a reflective secondary concentrator can deliver light to multiple CPC tertiary concentrators, not only is each secondary made of two independent large parts, but each of the even more numerous tertiary concentrators is a separate part. Even with macrocells (>1 mm²) this is an impractical design, and Cooper only mentions it in the context of an exhaustive catalog of design variations; with microcells the number of secondaries would grow linearly with the reduction in cell scale and the number of tertiaries would grow with the square of the reduction in cell scale, so Cooper's design teaches toward larger scales rather than smaller (as shown by Cooper's work on how to make very large trough primary concentrators).

The present invention overcomes almost all of these limitations of the prior art and significantly ameliorates the other limitations. As shown in overview FIG. 2, which illustrates a cross-section across the trough's focus, in a preferred embodiment the HCPV system 20 comprises a linear primary concentrator 21, such as the parabolic trough shown, that focuses onto a long, narrow module 26. The trough's rim angle is kept low; although this significantly reduces the primary concentration, which limits the reduction in module size, the module is still dramatically reduced compared to a prior-art microcell module (namely, a prior-art microcell module of comparable power), so the further reduction foregone is modest. The trough's focus 291 is intercepted, shortly before its tightest focus, by a lens tile 221 on the front of the module 26. The module cooling will be addressed later, but may comprise fins 2613 on the back of the module 26.

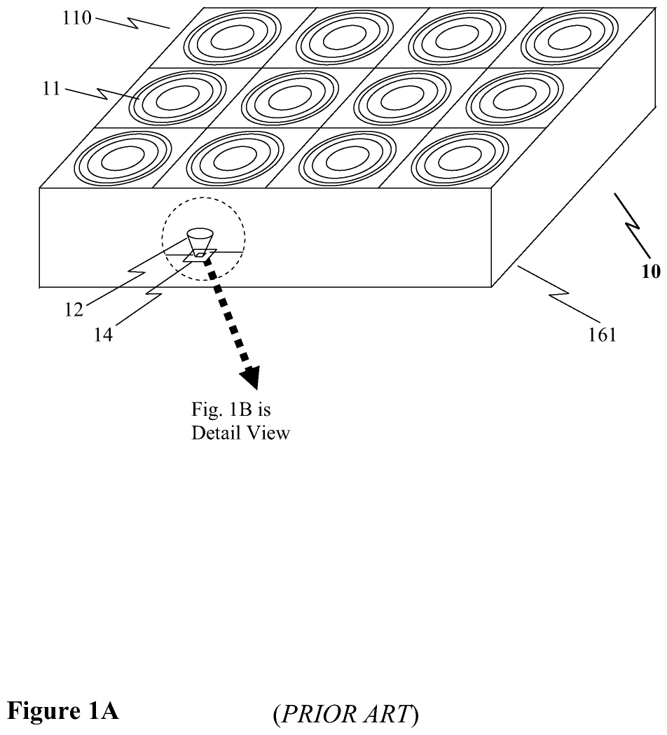

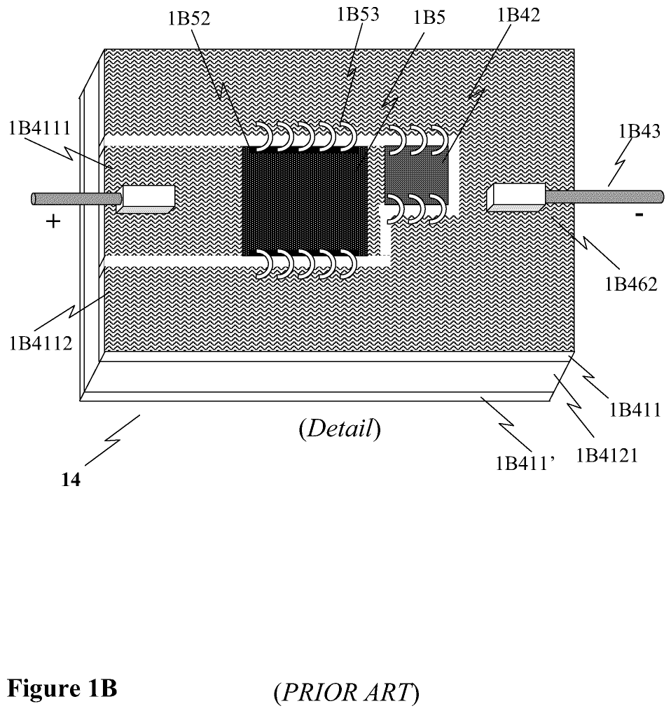

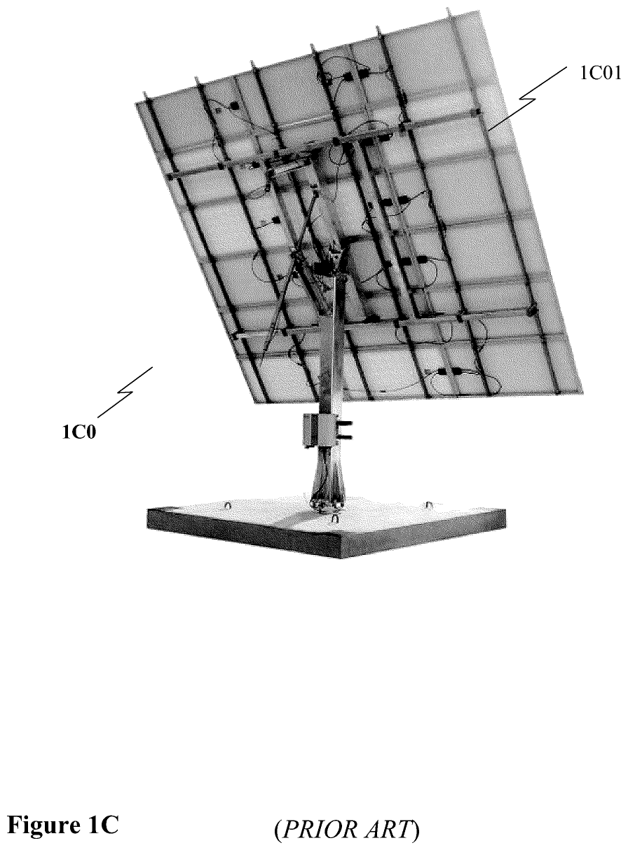

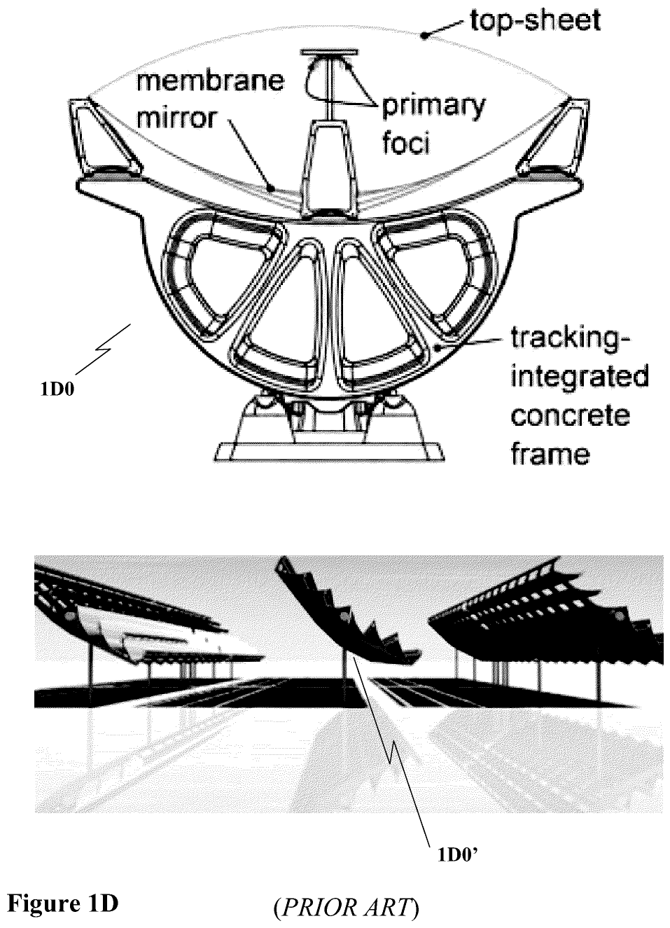

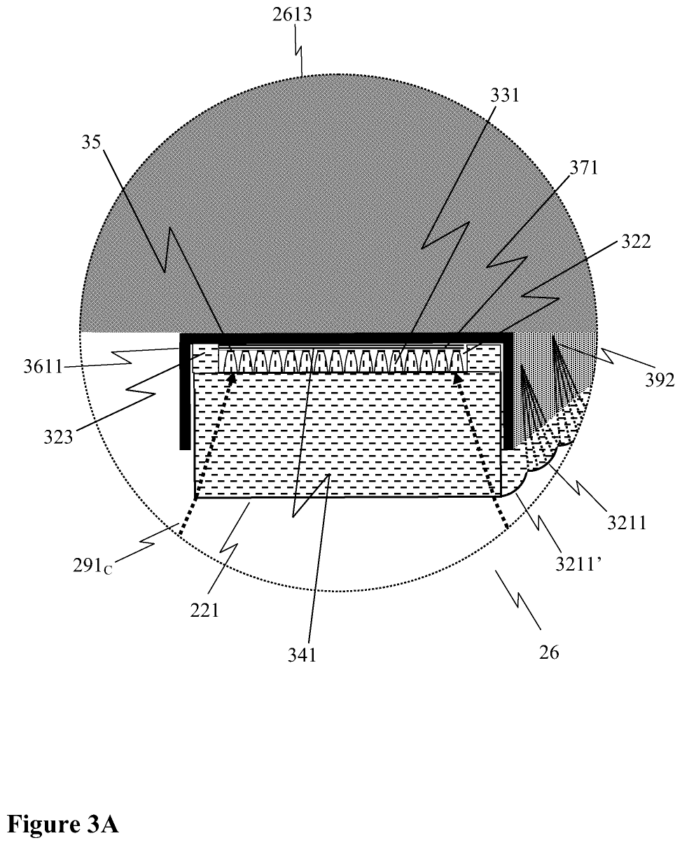

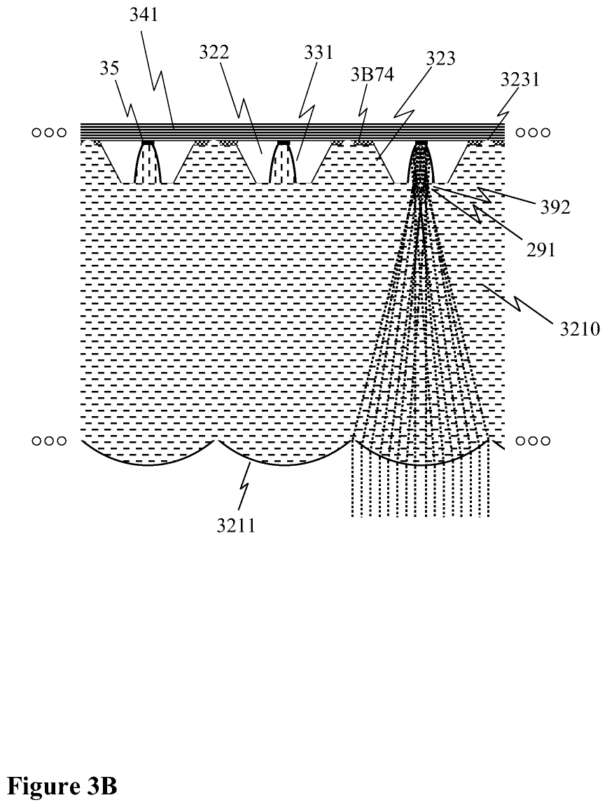

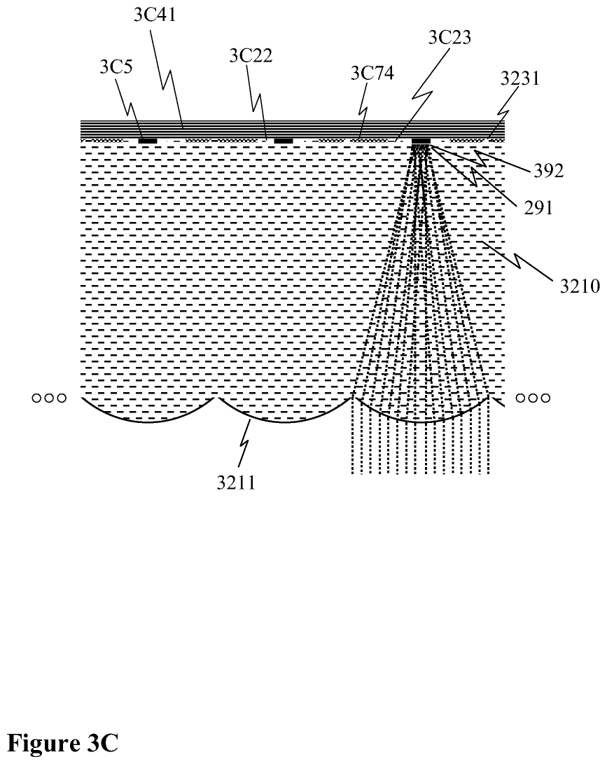

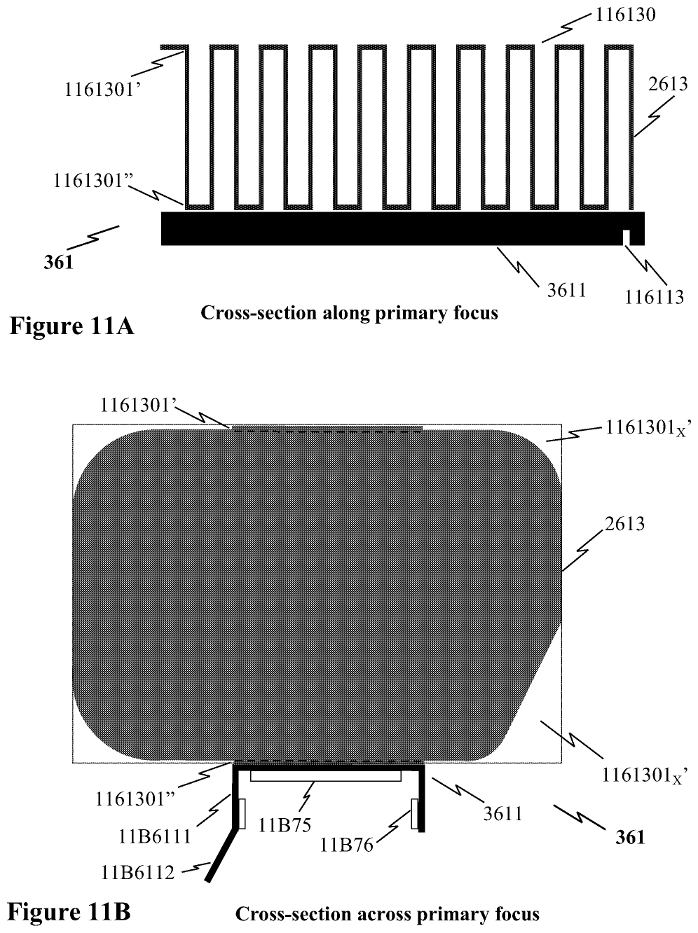

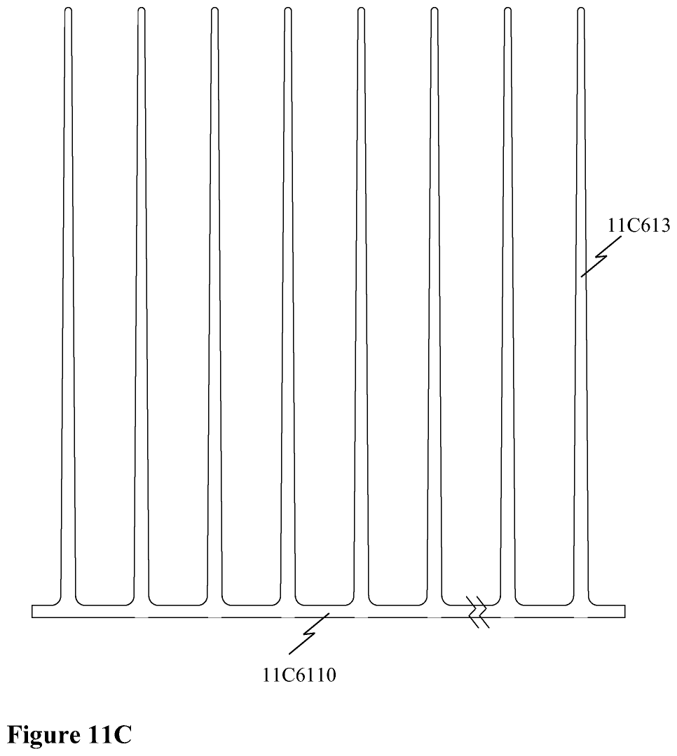

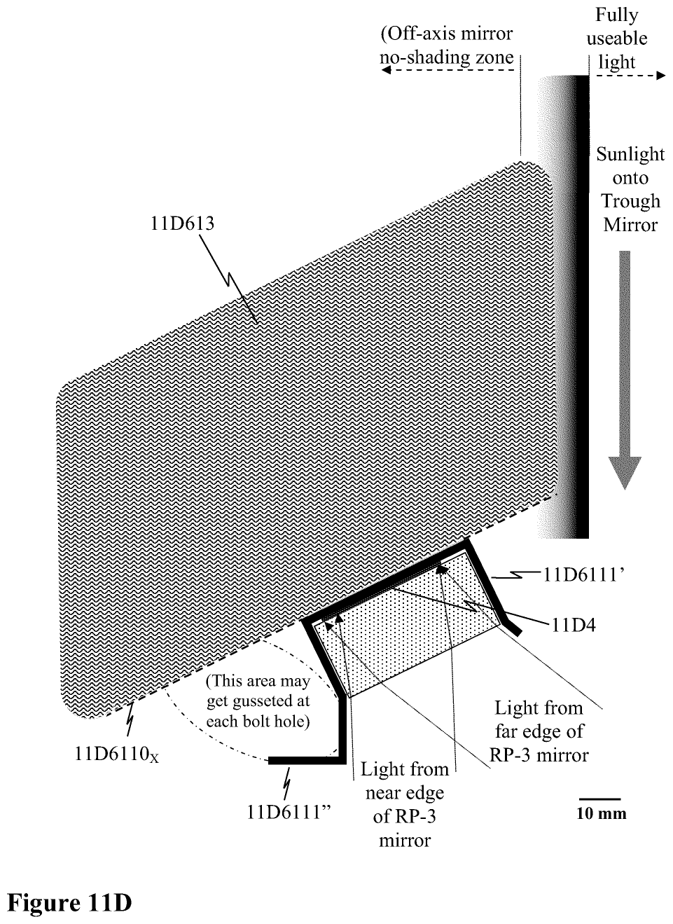

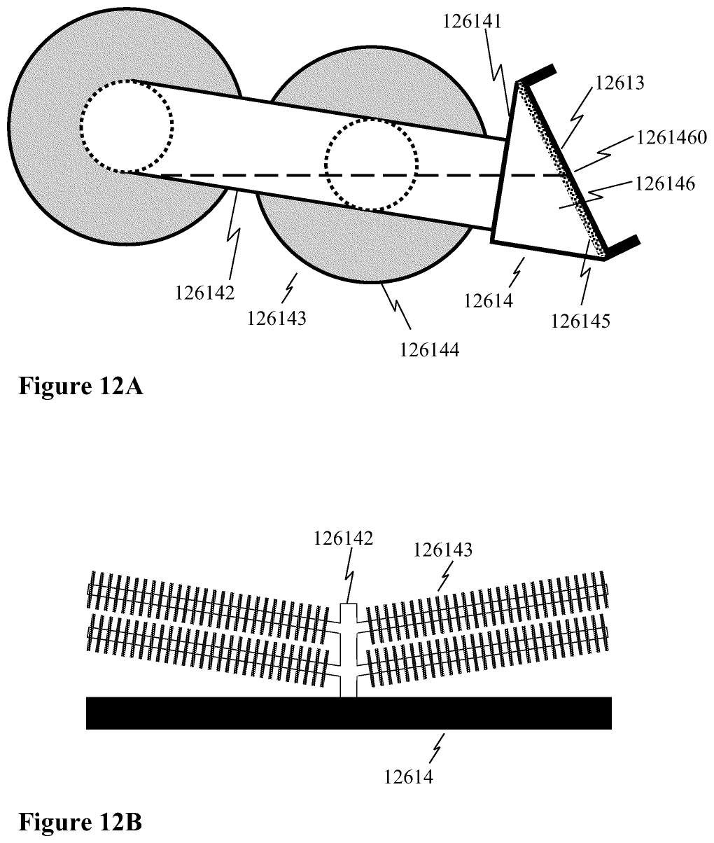

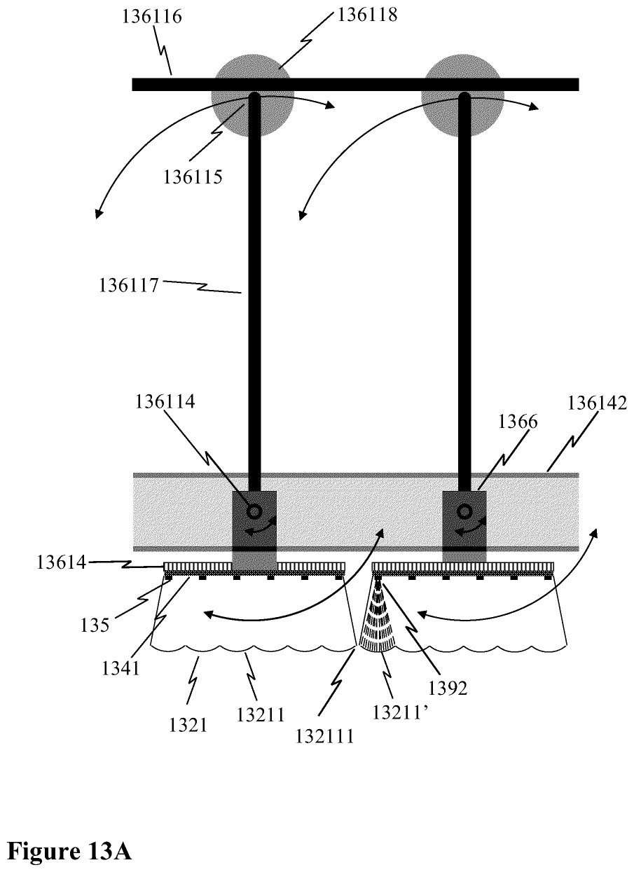

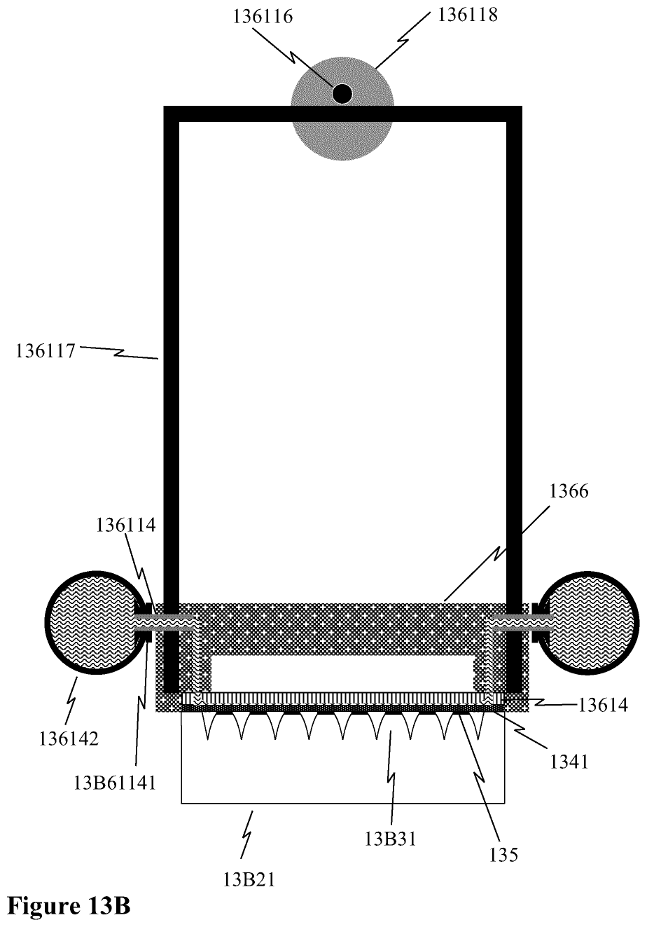

As seen in FIG. 3A, which is a detailed view of the part of the across-the-trough's-focus cross-section of the module 26 that is within the dotted circle in FIG. 2, in a preferred embodiment the front surface of lens tile 221 comprises a series of linear lenses 3211 that each focuses light on a second axis, orthogonally to the trough's focus. Preferably each lens 3211 focuses onto an indent 322 formed in the back of the lens tile; the lens curves are not as steep as in Hayashi1 (namely, the lens curves of preferred embodiments of the present invention do not reach angles as steep as the roughly 67 shown in FIG. 1b of Hayashi1), limiting their concentration and requiring a thicker lens relative to a lens's focal spot width (namely, since a less-steeply-curved lens has a longer focal length, and this embodiment avoids an air-gap by having the lenses focus within the lens tile, the lens tile must be thicker to match the lenses' longer focal length); so to keep the absorption in the lens low with low-cost glass, a very narrow lens focus is used, which pushes the cell width to be even smaller than the microcells of Hayashi1. The indent's depth is sufficient to accommodate cells 35, and in most preferred embodiments also tertiary optical elements (hereinafter referred to as TOEs) 331. FIG. 3A is a cross-section through the middle of lens 3211′, and thus along the middle of a row of TOEs 331 that can be seen in indent 322, with lens support 323 in the near background. Part of one of the fins 2613 can also be seen. It should be understood that not all preferred embodiments use fins directly attached to the module back; FIG. 11A shows fins that are directly attached, FIG. 12A shows fins that are indirectly connected via heat pipes, and FIG. 13B shows cooling vis pumped fluid). The focusing of the lenses 3211 would not be visible in a true cross-section, but lens focusing 392 is projected onto the side of the module so that its orientation orthogonal to the trough's focusing can be seen (namely, that the trough's sill-converging focus 291_{C} continues converging within the lens tile 221 until it reaches substantially the same depth within the lens tile as lens foci 392). The lens focusing will be shown in greater detail in FIG. 3B.

While less reduction in module size, lower concentration, thicker glass, and very small cells does not sound like a promising start for a practical HCPV system, let alone a system that can beat silicon flat panels on cost, each of these sacrifices has been carefully chosen to have an acceptable negative impact while enabling much larger positive impacts elsewhere, particularly in cost savings. While other types of linear concentrators can be used (such as circular or hyperbolic cylinders, compound parabolic curve cylinders, or even linear Fresnel lenses or linear Fresnel reflectors), preferably the linear primary concentrator is a parabolic trough. Preferably the primary concentrator has a rim angle below 30 and even more preferable between 20 and 25°, providing a suitable amount of light, from an easily manufacturable width, without too long a focal length. In an exemplary embodiment the primary concentrator is a single RP-3 inner mirror, approximately 1641 mm wide (namely, the width of the mirror measured along the arc is approximately 1641 mm, and the light-gathering width is approximately 1582 mm) and 1700 mm long, with a focal length of 1710 mm and a rim angle of 24.35°; while this rim angle is on the high end of the especially-preferred range, this mirror is exemplary for economic reasons, being available from multiple suppliers in vast quantities at low cost for solar thermal troughs.

Preferably the lens tile 221 intercepts the trough's focus at between 20× and 70× concentration, more preferably between 30× and 50× concentration, especially preferably between 35× and 45× concentration. In combination with an RP-3 inner mirror primary, with standard tracking errors (with which a full RP-3 trough would reach over 70×), and with a lens tile made from ultra-low-iron glass in a 19 mm thickness (namely, which produces an average thickness of 19 mm after roll-forming, and which is commercially available for skyscraper windows), intercepting the focus at between 38× and 42× is exemplary; this combination maximizes the cell size at a given concentration while keeping absorption loss in the glass acceptably low.

Preferably the lens tile 221 has multiple lenses 3211, with each lens 3211 providing light to a row of cells 35; and preferably a substrate 341 that support the cells has multiple rows of cells 35, with each row of cells positioned at the tips of a row of TOEs 331 in the indent 322 behind a lens 3211 of lens tile 221 (solder 371 attaches cell 35 to substrate 341, but is not thick enough to be clearly seen). Several lens features can be better seen in FIG. 3B, which is an illustration of the cross-section along the trough's focus. A multi-row substrate 341 spans multiple lens supports 323, adding stability during assembly through the viscosity of adhesive 3B74 as well as reducing the number of substrate/lens matings. With 19-mm thick ultra-low-iron glass used for the lens tile as described above, preferably each lens is between 5 mm and 12 mm wide, more preferably between 7 mm and 10 mm wide, and in exemplary embodiments is between 8 mm and 9 mm wide; this balances a wider cell (lower kerf losses, lower assembly costs, and higher placement tolerances) against a flatter lens (easier to manufacture accurately, lower reflective losses, and a narrower angle that allows higher concentration in subsequent concentration stages.

Preferably each lens 3211 concentrates the light between 5× and 15×, more preferably between 7× and 12×, especially preferably between 8× and 10×, and in an exemplary embodiment the lens concentrates between 9× and 9.5×. This concentration is orthogonal to the trough's concentration, so the concentrations multiply for a combined concentration of between 400× and 450× at the focus of the lenses, which is also at or very near the tightest focus of the trough (as refracted by the lens material). The congruence of the tightest foci in the two orthogonal dimensions can be seen in FIG. 3B by the position of the trough's tightest focus 291 in the lens glass 3210 being at substantially the same position (namely, depth in the lens glass) as the focus 392 of a lens 3211.

Preferably these features of the lens tile are molded in a large sheet of low-iron or ultra-low-iron glass, and the large sheet is then cut into a plurality of lens tiles with each lens tile preferably having a plurality of rows of lenses. Since roll-forming is generally the lowest-cost accurate molding for glass sheets, preferably the lens tile glass pattern is optimized to allow the lens tile to be easily and accurately roll-formed. While a constant profile in the rolling direction is not essential, it is the easiest pattern to roll-form so optically-active features (in this case the lenses 3211) should have an approximately constant profile in the rolling direction, which preferably is orthogonal to the axis on which the lenses will focus light. While other hard optical materials such as acrylic or polycarbonate can be roll-formed, or the lens front could be a separate optical material (such as silicone) moulded onto the glass, glass has a lower thermo-optic coefficient (i.e., the focal length of the lens change less when the temperature changes), so glass is preferable even in embodiments where the lens surface is not exposed to the elements (for example, when the PV system is inside a glasshouse), and in embodiments where the surface is exposed to the elements (weather and harsh UV), glass (including anti-reflection-coated or surfaced [namely, anti-refection-surfaced] glass or glass treated to be soiling-resistant) is especially preferred. Low-iron glass lens sheet together with mirrors where the reflective layer is silver forms an exemplary embodiment for concentrating light for today's tandem cells because both have high optical efficiency in the wavelength range that today's tandem cells can utilize, including longer UV wavelengths, while silver and lower-iron glass filter out complementary portions of the shorter UV that can damage cells or the optical coupling to the cells.

As also seen in FIG. 3A and especially in FIG. 3B, an indent 322 behind each lens can be provided. This can serve multiple other purposes as will be discuss subsequently, but for the context of roll-forming the lens sheet, in exemplary embodiments the indent may have a cross-sectional area substantially equal to the cross-sectional area of the lens that it is behind. This lets the rolling process push glass from the indent on one face, with the same volume of glass going into the lens bulge on the opposite face, avoiding lateral displacement of the glass on a scale larger than a lens.

While the above elements (namely, the primary and secondary concentrators) of the preferred embodiments do not in themselves reach sufficiently high concentration to make current tandem cells cost-effective against today's silicon, if tandem cells were to drop dramatically in cost (on the order of one tenth the per-area cost of today's commercial tandem cells) this would become sufficient (and a wider trough rim angle and wider lenses with thicker glass would be even more preferable for minimizing cost). However these embodiments (namely, with the preferred primary and secondary concentrators as described in the preceding paragraphs) are preferred today because in addition to providing fairly high concentration at high optical efficiency and at very low cost, the angular range spanned by the focused light is narrow enough to allow a third optical stage (namely, the TOEs) to further concentrate the light.

FIG. 3C shows how the arrangement shown in FIG. 3B would look without the TOEs (as would become preferred if cell costs were much lower): TOEs 331 are removed, and the indents 3C22 and thermally-conductive supports 3C23 between them are reduced to just accommodate the rows or cells; without the TOEs the cells 3C5 become wider in the direction seen in the cross-section, and longer in the traverse direction, becoming closely packed within each row, but the receiver substrate 3C41 still has a plurality of rows of cells (preferably 3 to 6 rows of cells), with all cells in all of these rows electrically in parallel with each other.

While imaging TOEs could further concentrate the light, non-imaging optics can provide higher concentration from the angular range spanned by the compound trough/lens focus. Compound parabolic curves, or CPCs, are ideal non-imaging curves from an optical perspective (conservation of etendue), and conical CPC concentrators, or ‘Winston Cones’, are well known in the art of HCPV. True CPCs bring light onto a cell at the bottom of the cone at grazing angles, so the prior art includes truncating the cone's curve (namely, since the cell absorbs light less well a grazing angles). However slightly higher concentration can be obtained with a flat facet 43131 at the angle at which a CPC would be truncated, as seen in FIG. 4A, followed by a broader truncated CPC starting where light from the far end of that facet would reach the far edge of the cell. CPCs also reach vertical angles when concentration is maximized, which complicates molding, so truncating the tops to provide draft angles of at least 3° helps keep molding cost low.

CPCs can in general be hollow with mirrored walls, solid with mirrored walls, or solid with a substantially higher index of refraction than the surrounding medium (which is typically air) and reflect light that hits at shallow angles through total internal reflection, or TIR. As long as the light hits the sharp refractive-index change at below the ‘critical angle’ which depends on how large the refractive index change is), this reflection is nearly 100% efficient, in contrast to regular mirrors that lose a few percent of the light. Since an index of refraction at least as high as the glass lens minimizes reflective losses at the lens/cone interface and cone/cell interface, solid conical TOEs are preferred, even more preferably with steep-enough sides for total internal reflection to reflect the light from the cone sides. Preferably the cones are CPCs or modified CPCs, more preferably are truncated CPCs or modified truncated CPCs, and in exemplary embodiments the TOEs may be CPC cones truncated at their mouths to provide draft angles of at least 3, truncated at their bottoms to avoid delivering light at grazing angles (less than about 20°, where the cells start reflecting much more light) onto the cells, and have substantially flat facets at the bottoms to increase overall concentration within these other parameters. An algorithm to produce an appropriate curve, and the geometry it is based on, are shown in FIG. 4B for generating the first facet, and FIG. 4C for generating subsequent facets. From the foregoing it will be obvious to one skilled in the art that a well-known optimization technique such as multi-surface optimization could be used to fine-tune the lens and cone curves, but the method taught above provides good-enough results and can be driven by a simple Excel spreadsheet (namely, a spreadsheet implementing the algorithms shown in FIG. 4B and FIG. 4C, for example).

While round CPC cones reach the highest concentration, their ingresses would not pack in a row to fill the focal line from a lens, and would thus lose light beside where their circular mouths would meet, significantly lowering optical efficiency. Square cones with substantially the same concentration on both axes can provide the highest concentration of shapes whose ingresses pack well into a gap-free line, but symmetric concentration with square cones would produce very small cells (roughly 0.5 mm on a side).

But unlike the prior art discussed above, the 3-stage optics of the present invention can reach high enough concentration to make it preferable to sacrifice some concentration to enable other improvements. With today's tandem cells, lower cost can be obtained by concentrating slightly less on significantly larger cells that provide lower handling costs and better assembly tolerances. By using cones 331 that have rectangular ingresses 4311 and egresses 4312 and that concentrate less along the trough's focus than across the trough's focus, the cell size can be increased while still reaching the optimum concentration of around 1500× for today's cells (this balance may shift back with future cells that can handle higher concentration, or it may shift to even larger cells at lower concentration if cell costs drop dramatically). Since any gaps between TOE ingresses lose light, the ingresses should be very close to adjacent, preferably within 1%; in Fresnel lens silicone is molded to a 2 μm radius, which allows gaps as small as 0.2% of the exemplary TOEs of the 16-cells-per-row examples used for RP-3 mirror.

The TOEs thus preferably concentrate between 1.5× and 3× across the trough's focus, and between 1.25× and 2× along the trough's focus, and preferably they raise the final focus to at least 1000×; more preferably the TOEs concentrate between 2× and 2.5× across the trough's focus, and between 1.4× and 1.7× along the trough's focus, and more preferably they raise the final focus to at least 1250×; and in exemplary embodiments with the exemplary trough and lens tile as described above, the TOEs may be cones that concentrate between 2.3× and 2.5× across the trough's focus, and between 1.45× and 1.55× along the trough's focus, and reach between 1400× and 1600× concentration (when averaged across all cone [namely, TOE] egresses 4312 of a given lens).

While the TOEs could be molded in the lens glass itself, they have a dramatically varying profile in the direction intended for rolling, which would make accurate rolling impractical if not impossible, and even if the lens tile were compression-molded instead of roll-formed, the sharp profile would concentrate mechanical stress between the cones in a row, significantly weakening the lens tile. To avoid lens-glass forming difficulties and high stress-concentration, the TOEs are preferably separately molded. This can be as a row with a common root (like the teeth of a comb) inserted into an indent enough deeper to accommodate that root, held in place with an optical adhesive; however this is only preferred if the cone material selected cannot be molded, or is costly to mold, on the back of the lens tile (e.g., if the cones are a high-refractive-index material such as flint glass that has a high melting point, namely, higher than low-iron glass). More preferably the TOEs are molded or hot-embossed on the back of the lens tile in a polymeric optical molding material such as silicone, acrylic or optical epoxy; these materials and process are already used in HCPV to produce the acrylic and silicone-on-glass lenses for Fresnel box HCPV. With the trough (or other linear primary concentrator) providing primary concentration, roughly 40 times less glass area and 400 times less cone area is needed with the present invention than with Fresnel/box CPV, so although the glass is six times as thick and the cones are roughly five times as tall as the Fresnel lens features, the cost can be very low. While polymeric optical materials were not preferred for the lens surface, the cones are not refractive elements and so are almost immune to the thermo-chromic effect, and are also protected from the elements (from weather by the lens glass, and from harsh UV by the complementary filtering of low-iron glass and the silver reflective layer of most solar mirrors), and so polymeric materials are preferred (for the TOEs) for their low cost and high moldability.

Making accurate molds with smooth surfaces is well known in the art of molding optical components such as Fresnel lenses and secondary optical elements, where optical silicone is molded into features with radiuses as small as 2 microns. While such accuracy is desirable, such molds are expensive, so a lower-cost way of molding optical silicone with almost as fine features may be used in more-preferred embodiments. Many of the preferred embodiments have conical TOEs that have rectangular cross-sections, making this shape, and sparse rectangular arrays of this shape, easy to form in metal with wire EDM (which, with ‘skim passes’ can achieve 0.2-micron accuracy. The TOEs may not be packed more densely than the diameter of the EDM wire, but a dense array may be produced from multiple sparse arrays. A preferred sparse array unit, as illustrated in FIG. 4D, may have ‘fingers’ 4D3011 that each have half of the TOEs 4D3013 from multiple row of a dense array of TOEs. As also shown in FIG. 4D, multiple such sparse array units, 4D301′, 4D301″, etc. can then be interdigitated to form the semi-dense array (TOEs densely packed within a row but with broad spaces between the rows) as desired. Keeping the dense units 4D301 small allows very high accuracy in wire EDM by reducing the wire length, so preferred units 4D301 are less than 100 mm in any dimension; with the units of this example, 66 units would be interdigitated to reach the length of a module matching an RP-3 mirror. A single such series of interdigitated parts may be used to make a mold for a single lens tile's array of TOEs; the units can also be array in the other dimension (with appropriate interlocking keys added to ensure longitudinal alignment) to produce a TOE mold for a larger lens sheet. The units 4D301 may be bolted to a flat metal slab to hold them securely, and as well known in the art of mold making, other parts such as side to constrain a liquid can also be bolted on (or welded, or epoxied, etc.). Either the master array or the individual units may be coated with a thin conformal coating (for example, 2 μm of Parylene C) to produce optically-smooth surfaces without requiring mirror-polishing of every TOE surface.

Many TOE array molds 4E302, as shown in FIG. 4E, may then be cast from this TOE master array, preferably using a flexible polymer such as silicone, urethane, or latex to make removing the mold from the lens sheet easier. Since these polymers all have much higher CTEs (coefficients of thermal expansion) than glass, each such mold preferably comprises a core of a strong material with a CTE that is a lower than the lens-sheet material's CTE so that the overall mold CTE is a good match (preferably within 2 ppm/K, and more preferably within 1 ppm/K) to the lens sheet. In the case of low-iron glass lens sheet, Kovar and various low-CTE iron/nickel alloys offer appropriate CTEs while being flexible in the thicknesses needed. The molds are then preferably coated with a micron or two of Parylene (which prevents cure inhibition by latex or urethane, and acts as a permanent mold release, while providing an optically-smooth surface). Such molds can be inexpensively produced in large enough quantity to allow a standard slow-curing optical silicone, such as DOW Sylgard, to be used in the molding of the TOEs themselves, without requiring a large investment in molds.

Preferably each TOE array mold 4E302 has optical alignment means; for example matched photodetector pairs 4E3025 are placed each end of a mold. A photodetector pair is centered relative to a row of TOE cavities, and a laser (or other narrow-beam emitter) is attached to the mold and centered onto the photodetector pair so that the photodetectors produce equal signals). When a lens sheet is place into a TOE array mold 4E302 so equipped, the photodetectors of a pair 4E3025 will produce equal signals only when the intervening lens is centered relative to the pair, so when both pairs 4E3025 produce equal signals the lens tile is aligned both longitudinally and rotationally in a mold 4E302. As for lateral alignment, the lenses are linear so alignment is non-critical; even in embodiments where the ends of a lens are curved toward the receiver (as will be discussed later), a millimeter makes little difference, so mechanical alignment means, such as aligning the lens sheet to the edge of the mold are sufficient.

To mold the TOEs on a lens sheet (or an area thereof), a mold such as 4E302 may preferably be used as follows—the mold's TOE cavities 4E3023 may be mostly-filled with vacuum-degassed optical silicone (typically with a curing agent mixed in), and the whole mold re-degassed (removing any air rapped in the corners of the TOE cavities, and the cavities topped up with degassed silicone. The lens sheet may have a small bead of optical silicone dispensed along the middle of where each row 4E3030 of TOEs will be molded (preferably a viscous optical silicone so that it does not drip or run). The lens sheets is then held flat above the mold 4E302 and gently lowered into it. If the beads of viscous optical silicone are present they will contact the silicone in the TOE cavities first; this is preferred both because it allows the optical mold alignment to be used before the lens sheet is resting on the mold, making its position easier to adjust if a large (heavy) lens sheet has TOEs over-molded, and because as the lens sheet is lowered further each bead of silicone will push an air-free interface across the width of each TOE row, minimizing the entrapment of air without resorting to placing the lens sheet in a vacuum.

A mold 4E302 with the lens sheet in it is then left until the silicone cures, which may take less than an hour or may take longer than a day depending on silicone type, amount of curing agent used, and curing temperature. Temperature greatly speeds curing, and having the mold CTE-matched to the lens sheet simplifies using elevated temperatures. The mold, the lens sheet and the silicone may preferably all be preheated to speed the cure; with some common optical silicones a temperature of at least 50° C. speeds the cure to less than an hour, allowing each mold to be reused many times per day, and with each square meter of lens sheet producing lens tiles for roughly 15 kilowatts of modules, very high production may be obtained from a modest number of low-cost molds. While molding TOEs in a mold that is itself molded from a master TOE array introduces additional inaccuracies compared to molding in the best machined mold, coating thicknesses and mold material shrinkage can be accounted for in the mastery array so the main impact is that a 2 μm-radius between cones would be difficult to achieve. However, a 5 μm radius loses only 0.5% of the light from the secondaries when the TOEs are in accordance with the exemplary TOEs as described herein, which is an acceptable efficiency penalty to be able to produce numerous low-cost molds from one master TOE array.

Returning again to FIG. 3B, in especially preferred embodiments the cones (or other TOEs) may comprise silicone molded onto the back of the lens sheet before it is cut into lens tiles, and the silicone cones are between 2 mm and 4 mm tall, and even more preferably between 3 mm and 3.5 mm tall; this allows the cones to support cells up to 1 mm long, while keeping the cones short enough that the high thermal expansion of the silicone cones, while constrained between the lens glass 3210 and the cells 35 on substrate 341, does not buckle the cone at high temperatures or lift the cone from its optical coupling to the cell at low temperatures. In exemplary embodiments with the trough and lens and cones as described above, each cell 35 is between 0.8 mm and 1 mm long in the direction across the trough's focus, and between 0.6 and 0.7 mm wide in the direction along the trough's focus.

While the cells could be individually placed against the cones (namely, the TOEs) on the back of the lens tile, as Hayashi1 teaches placing cells individually on the back of a lens array, the cells of the preferred embodiments are even smaller than Hayashi's cells and thus are even more numerous, increasing the difficulty of this approach. Hayashi2 teaches a two-dimensional array of microcells on a circuit-board that fits in moderate-speed chip placement equipment, reducing cell placement costs, but the circuit-board is made of glass, with the cells on the back. This avoids wire bonding (the substrate of Hayashi2 is too large to fit into typical high-speed wire-bonding equipment), but it requires that the cells have their positive back contacts mapped to the cell front, raising the cell cost, and it requires a separate heat spreader, comprising a separate heat sink for each 1×5 row of microcells, as well as a thick aluminum plate final heat spreader. The cells of Hayashi2's cell array are also not individually connected electrically in parallel with each other, but are in five strings each with five cells electrically in series, with the cells strings then electrically in parallel. This requires that the illumination on each cell in a string be substantially identical, since without bypass diodes a single weak under-illuminated cell in a string of 5 cells would pull the whole string down to its photocurrent, and with five such strings in parallel would thus pull 20% of a module down to is level, which would pull any other modules in series down to that level (unless a per-module bypass diode were used to bypass the whole defective module). While a lens-sheet primary will deliver equal light to all cells under ideal conditions (when perfectly made, perfectly aligned, perfectly clean, etc.), conditions outside of a laboratory are rarely ideal. While Hayashi could add a bypass diode per cell (converting each 5-cell string into five receivers in series sharing a substrate and sharing assembly costs as taught in CGE), each cell only produces ˜120 milliWatts so this would require vast numbers of tiny bypass diodes, increasing cost, and the substrate and the secondary optics sheet would still span the light-gathering area.

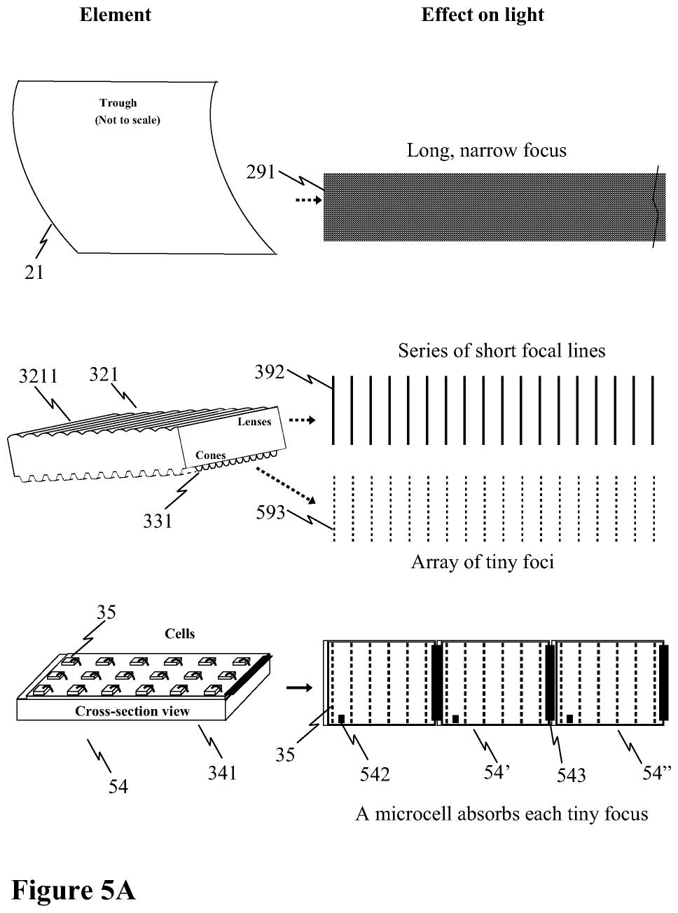

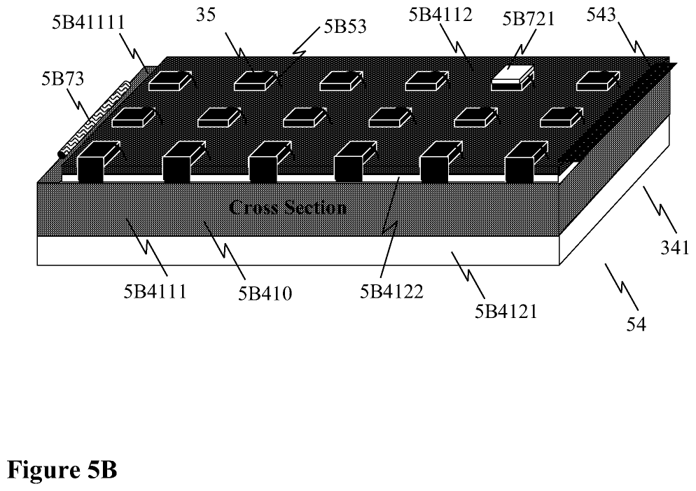

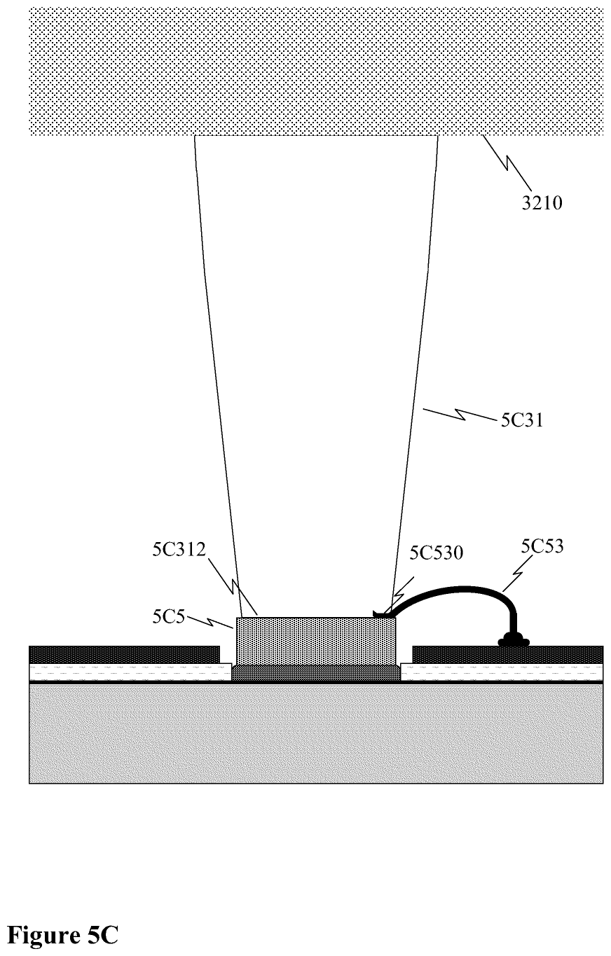

As can be seen in FIG. 5A, the linear primary concentrator 21 of the present invention produces a long, narrow focus 291, which lenses 3211 of lens tile 321 refocus orthogonally to a series of short focal lines 392. A row of cones 331 (namely, TOEs 331) converts each short focal line 392 into a row of tiny foci 592, producing an array of such foci from the series of short focal lines. In a preferred embodiment each lens focuses onto a single row of TOEs 331, and each TOE 331 further concentrates the light onto a single tandem cell 35; in exemplary embodiments the row of TOEs is located in an indent on the back of the lens; with the maximum focusing of the trough and the lenses occurring substantially at the entrance to the TOEs. While in the exemplary embodiment the focus of each lens ends up on a row of cells, this is very different from what Corino, Wheelwright and Cooper teach because the cells are not packed side by side with minimal gaps to capture a single focus from the lens (namely, the secondary concentrator), but are separated from each other, with each cell each capturing its own tiny focal spot from a single TOE.

Preferred embodiments of the present invention overcome the limitations of per-cell substrates for micro-cells and without trading them for the limitations of prior-art multi-cell substrates. A 2D array of microcells 35 is supported, by a contiguous substrate 341, to form a receiver 54. All cells on a receiver are in parallel, allowing a receiver to have just a single bypass diode 542 and a single electrical connection to the next receiver (e.g., 54′ to 54″) via a single connecting strip 543. As shown in FIG. 5B, a detail view of a receiver 54 in cross-section with thicknesses exaggerated for visibility, substrate 341 comprises a highly-thermally-conductive heat spreader 5B410 for a two-dimensional array of microcells 35, where the array is substantially smaller than the light-gathering area that the array of cells receives light from. Even when the substrate size is reduced more than 40 times by the exemplary primary concentration disclosed above, spanning a 2D array of cells still requires a larger substrate area per Watt than a traditional Fresnel/Box CPV system (in which the substrate for a 1000× concentration is typically five times the cell size, or 200 times smaller than the light gathering area). Even in Fresnel/box CPV the DBC/AlN typically used is a significant cost (NREL's CPV costing “A Bottom-up Cost Analysis of a High-Concentration PV Module” shows it as 6% of the total cost in a module that is several times too expensive to be competitive), so DBC/AlN 1/40^{th} of the light-gathering area, or five times bigger still, would be cost-prohibitive. While DBC/alumina is five times less expensive, it is also eight times less thermally conductive, replacing a prohibitive cost by a high cost compounded by poor thermal performance.

Preferred embodiments of the present invention may therefore use a heat spreader 5B410 that is preferably made of Aluminum/Silicon-Carbide, or AlSiC, which has comparable thermal conductivity to, and almost as low thermal expansion as, DBC/AlN, but is far less costly. This change is not straight forward because DBC/AlN provides a complexly-patternable electrically conductive layer on top of an AlN core that provides thousands of volts of electrical isolation (needed to get a module safety-certified), as well as high thermal conductivity. In contrast AlSiC itself is electrically conductive and thus provides no electrical isolation, and since cells have both plus and minus contacts, the substrate needs at least one additional electrically-isolated electrically conductive layer to electrically connect to at least one of the polarities. If that layer's electrical isolation were thick enough to provide the needed several thousand volts of isolation, then to avoid significantly impeding the heat flow the electrical isolation would need to be an excellent thermal conductor like AlN, so it would increase rather than reduce the total cost.

Preferred embodiments of the present invention may resolve this by using two separate electrically-isolating layers: a thin electrical isolation layer 5B4122 under an added electrically-conductive power-plane layer 5B4112, with that thin isolation 5B4112 just needing to provide sufficient isolation to withstand the receiver's own voltage (a few volts instead of a few thousand volts), and a thick electrical isolation layer 5B4121 on the back of the AlSiC to provide the several thousand volts isolation required for safety. Since the AlSiC spreads the heat out to from the cell's >1000× concentration (1500× in exemplary embodiments with current cells) to only the roughly 40× primary concentration, the 25-times to 40-times lower heat flux allows much lower cost electrical isolation. For example, ventec's VT-542 ‘prepreg’ for thermally conductive circuit boards has a DC withstanding strength of 4500V for an 80 μm thickness, and a thermal conductivity of 2.2 W/mK; while this provides sufficient electrical isolation with a thermal resistance per area roughly ten times higher than the traditional 635 μm of AlN (and provides only 1/1000 of the heat spreading), with the heat flow already spread out to 25 to 40 times lower flux, the prepreg's thermal penalty is lower that AlN (and far lower than alumina), and prepreg costs much less in spite of the larger area needed. In addition to thin isolation 5B4122 only having to withstand a single receiver's voltage, thin isolation 5B4121 is not even in the thermal path from the cell; as will be seen later the heat flux from the lens is several hundred times lower than that from the cell and the lens is less heat-sensitive, so ordinary circuit-board insulation can be used at even lower cost.

With two separate conductive layers, backplane 5B4111, which in preferred embodiments is the heat-spreader 5B410 itself, and power plane 5B4122, the present invention also simplifies the conductor patterns. Tandem cells are normally made with their backs as positive contacts, so in preferred embodiments the cell backs are bonded to the electrically-conductive AlSiC through electrically-conductive means such as solder or sintered silver; this lets the AlSiC heat spreader 5B410 serve as an electrical backplane 5B4111, as well as a mechanical support and heat spreader, for the array of cells. This places all cells 35 on substrate 341 electrically in parallel so that they comprise a single receiver 54; this eliminates photocurrent matching issues within the two-dimensional cell array on the substrate, which eliminates the need for the optics to provide similar illumination to multiple receivers on the substrate as would be needed with the multi-receiver substrates of Norman1 or of CGE or of Cooper.

This also allows all cells 35 on a substrate 341 to have their top (negative) contacts connected, preferably through wire-bonding with wire-bonds 5B53, to a common conductive layer such as power plane 5B4112, simplifying the top conductive plane as well. Rather than a complex lithographically-patterned conductive layer, power plane 5B4112 can be a simple as a sheet of resin-coated-copper punched with holes matching the cell pattern, with each hole oversized so that the cell edges do not touch the copper surrounding the cell. The cells can then have their bus bars wire-bonded to the top copper power plane, just as they traditionally are wire-bonded to the negative region of the complexly-patterned copper of DBC/AlN.

But to avoid missing light, the cells 35 need to be oversized (compared to the cone egresses 4312, as was seen in FIG. 4A) by the cell's positional precision in each dimension, and high-precision placement in a tight hole is generally more expensive than less-precise placement in a more-relaxed hole. Using the surface tension of solder for centering a chip is well known in the art of electronics assembly. As exemplified by Hayashi2's use of this to center the microcells, this is done by controlling the position of the solder, which can typically be controlled to +/−10 μm accuracy. This would be easy to apply to the present invention; aluminum and silicon carbide both repel most solders, so the AlSiC heat spreader 5B410 needs to be plated for soldering anyway, and plating just the regions where the cells are supposed to go would confine the solder to those areas.

However, that would require aligning the power plane's hole pattern to the AlSiC's plating pattern, and preferably that alignment requirement is eliminated by plating the whole AlSiC surface for solderability, or even more preferably is relaxed by plating a generous area for each cell when the plating is expensive (a gold final coat is typically used for best solderability), and modifying power plane 5B4112 instead. While the prior art of patterning ‘solder stop’ on a power plane could still control the solder, that would be an extra alignment and patterning step.

Power plane 5B4112 resembles a circuit-board power plane, and these are preferably copper for easy patterning and low resistance, and normally the copper for a power plane is patterned by coating it with photo-resist, lithographically patterning the resist, dissolving un-patterned resist to form a mask, and using that mask to control the etching of the copper. But even after that complex process, separate patterning of holes in the resin film would be needed to prevent the resin film from electrically isolating the cells from the AlSiC, and this would need to be aligned with the power-plane pattern.

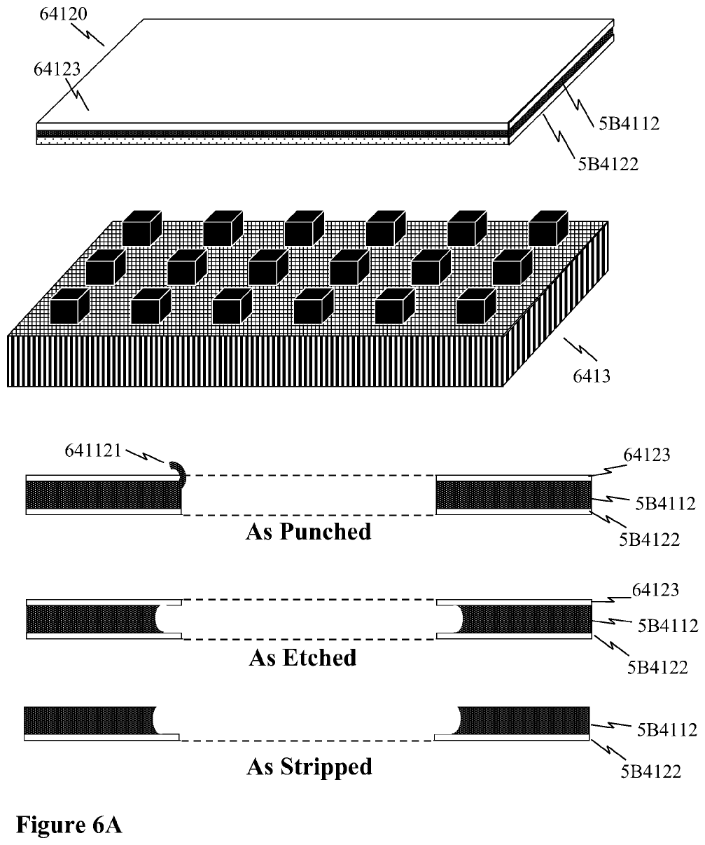

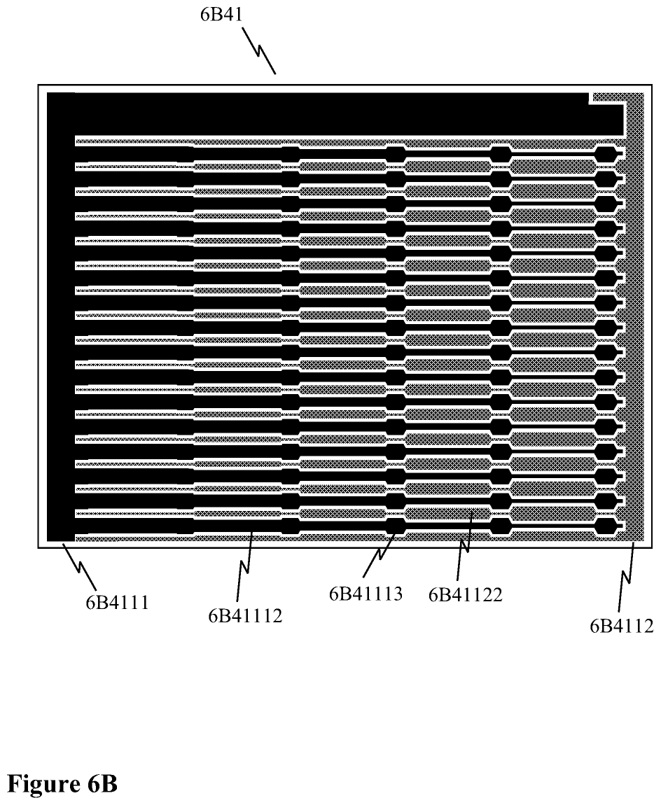

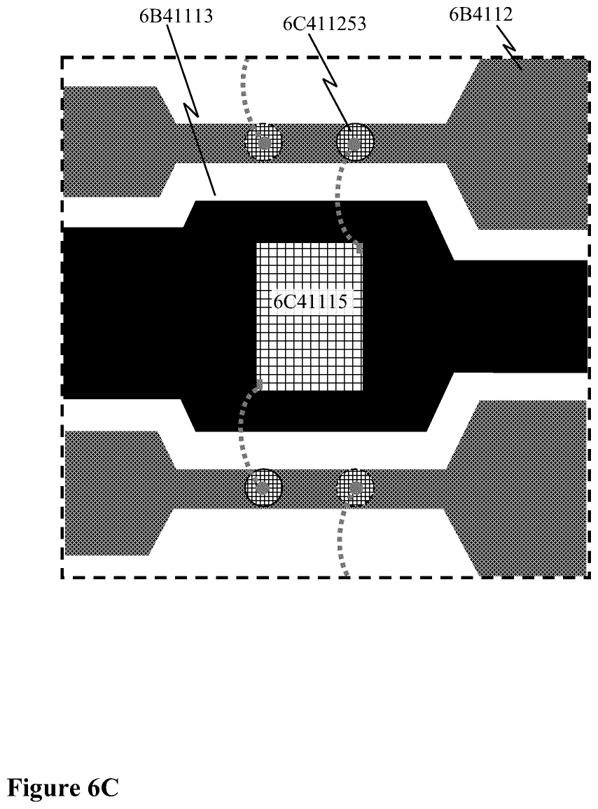

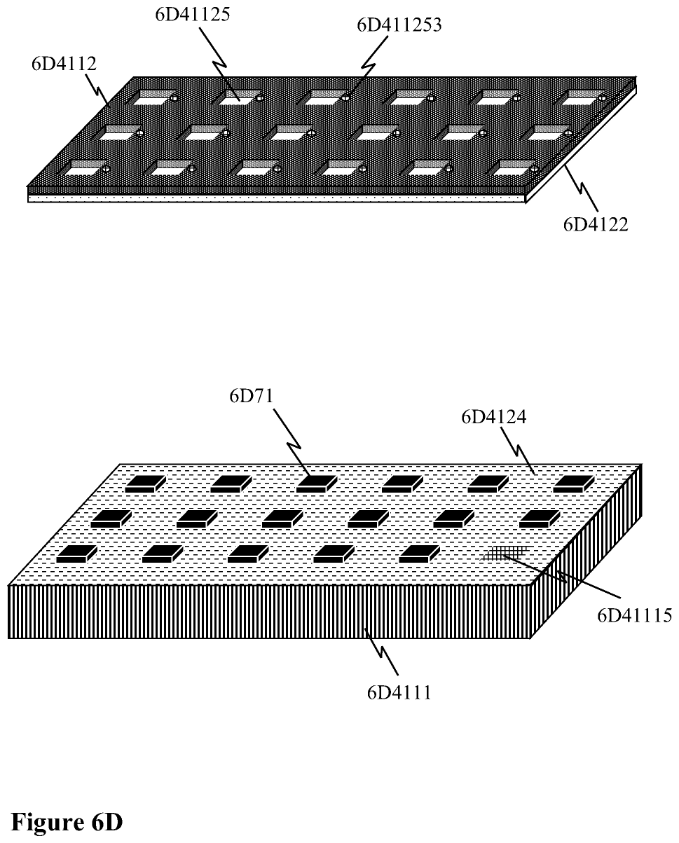

As shown in FIG. 6A, preferred embodiments of the present invention overcome these drawbacks of the prior art by coating the copper foil that will become the power-plane 5B4122 with an etch stop 64123; more preferably resin-coated-copper is used so that the resin can serve as the backside etch-stop and then serve as thin isolating layer 5B4122; otherwise both faces of the copper are coated with a removable etch-stop before punching. Holes are then punched through the copper and the etch stop of coated copper sheet 64120; punching holes in copper is far lower in cost than lithographically patterning a photoresist. In even more preferred embodiments, the holes are punched at once with a single multi-punch die 6413, the holes can then have extremely accurate hole size and relative positions (better than low-cost lithography as well as better than the +/−10 μm solder control that Hayashi achieves. In still-more-preferred embodiments the copper is then etched back from the hole edges (removing smears of copper such as 641121 in the process), and the etch stop on the top face is then removed; in yet-more-preferred embodiments the copper is etched back at least 30 microns which will allow for low-cost high-speed placement of the cells. The patterned power plane 5B4112 with its patterned isolation 5B4122 is then bonded to electrical backplane 5B410 (as seen in FIG. 5A), exposing the backplane only where the holes in the thin isolation layer 5B4122 are, and with the copper of power plane 5B4112 etched away in a ring around each hole.

While the cells drive the need for precision, holes can simultaneously be created in the power plane and its isolation to expose other areas of the electrical backplane where contact with that backplane is needed, for example where other components such as a bypass diode will be placed and where contact to an electrical conductor to another receiver will be made; in exemplary embodiments all backplane exposures for electrical contacts are made by the same punching step. The etch stop is removed so that it does not interfere with cell placement and wire-bonding to the power plane; this can be at any point after etching and before cell placement. This whole process is fewer steps than are used in a single layer of a circuit board, and the alignment is much more relaxed, so these steps are very low cost.

As illustrated in FIG. 6B, a standard integrated-metal-substrate, or IMS, process can also be used to produce a substrate 6B41 suitable for an array of microcells of the present invention. The least-expensive suitable standard IMS process uses only a single patterned conductive layer on a layer of thermally-conductive prepreg on a roughly 0.5-mm-thick copper base sheet, so backplane 6B4111 under the cells comprises backplane fingers 6B41112 interdigitated with power plane fingers 6B41122 to allow wire-bonding from the cells to the power plane while power-plane 6B4112 remains disjoint from backplane 6B4111. In general the fingers taper roughly proportionately to the current that they will carry, but where each cell will go its backplane finger preferably has an enlargement 6B41113. This enlargement serves two purposes—it spreads the heat of the cell in the enlarged area of copper before the heat is conducted through the thermally-conductive prepreg, and, as seen in FIG. 4C, it provides copper around the cell site 6C41115 that provide a flat foundation for photoimagable soldermask to constrain the solder that will go under the cell, providing precise cell alignment though molten-solder surface tension during reflow. The photoimagable solder mask can also define bond-wire sites 6C411253 on the power plane fingers (the soldermask is not shown FIGS. 6B and 6C because it would cover everything except cell sites 6C41115 and bond-wire sites 6C411253, and would thus hide all other items in these figures); this allows a single ENEPIG-plating step to ensure excellent solderability of the cell site and excellent wire-bondability of the bond-wire sites. While this uses as standard process and so is preferred for prototyping, even with tapered fingers sharing a conductive layer between the power plane and the backplane produces higher resistance than giving each plane its own conductive layer, and even the best thermally-conductive prepreg increases the thermal resistance significantly since it is now in the thermal path before the heat has been fully spread by the base sheet, so this is less preferred than a punched-sheet solution for high-volume production. 411253

Hybrid solutions are also possible. In a preferred embodiment, flat, electrically-conductive, thermally-conductive backplane 6D4111, which may, for example, be of a metal-matrix compound such as AlSiC or a metal such as copper, is patterned using photoimagable soldermask. Soldermask is preferably applied to the whole backplane surface and is then patterned with a lithographic mask whose pattern comprises the cell sites 6D41115 for a whole receiver's array of cells, which ensures precise relative positioning of the cell sites since they are all defined at the same time with the same lithographic mask. The soldermask is then developed to expose the backplane cell sites 6D41115 (becoming patterned soldermask 6D4124); the cell sites may then be cleaned, plated and/or fluxed for solderablity as is well known in the art of printed circuit board assembly. Power-plane 6D4112 and isolation 6D4122 are patterned with holes 6D41125 that will expose the cell sites 6D41115, and are then bonded onto backplane 6D4111; since these holes do not define the outlines of cell sites 6D41115, these holes can be oversized by hundreds of microns to avoid needed precise alignment to the backplane.

The holes in the power-plane and isolation may be produce by punching; for example, isolation 6D4122 may comprise punchable prepreg (that may have low thermal conductivity, reducing its cost), and power-plane 6D4112 may comprise punched copper sheet, and these may be punched separately, or a single sheet (for example, of resin-coated copper) may comprise both isolation 6D4122 and power-plane 6D4112 so that they are punched together. Copper smears (as illustrated in FIG. 6A) typically form only in one direction; as long as this direction is away from backplane 6D4111 then such smears do not even have to be removed. If the punching process used leaves smears that would short power-plane 6D4112 to backplane 6D4111, then etching can be used, or more preferably the power-plane 6D4112 is punched separately and then has smears flattened (for example, by rolling) or partially removed (for example, by sanding) before the power-plane is bonded to the other substrate layers. This allows a substrate to be made without any etching.

Common lead-free solders such as SAC305 have melting points higher than typical prepreg curing temperatures, so the solder 6D71 can be applied to cell sites 6D41115 before the prepreg and power-plane are bonded to backplane 6D4111. This can eliminate the need to coat or plate the cell sites for solderability; the cell sites 6D41115 can be cleaned and even fluxed if needed and solder 6D71 may then be applied, and flux residue then cleaned off if flux is used. Solder application may comprise (without limitation); placement of solder preforms (as illustrated in FIG. 6D, which shows backplane 6D4111 just before the last preform is placed) or stamping or stenciling solder paste, followed by solder reflow; or may comprise application of molten solder, such as dipping in a molten solder bath, with or without subsequent hot-air solder leveling, or placing the backplane 6D4112 against a mold that has a cavity filled with molten solder for each cell site, and then letting the solder solidify in contact with the backplane. The soldermask 6D4124 can then be stripped, or, if it comprises a typical epoxy-based soldermask material, it can be left in place and isolation 6D4122 (and via the isolation, the power-plane 6D4111) bonded to it. Preferably when solder 6D71 is applied before bonding the isolation and power-plane, the solder thickness is less than the thickness of the power-plane 6D4112 plus isolation 6D4122 (plus the thickness of the soldermask 6D4124 if it is not stripped) so that the solder 6D71 is flush or recessed relative to power-plane 6D4111 during bonding, allowing pressure to be applied to the power-plane with a flat plate during bonding (alternatively a plate with recesses matching the cell sites could be used). It is within the scope of the present invention that a soldermask material could be only partially cured (by the developing and the brief exposure to solder temperatures) and could then be used to also bond the power plane, thus serving as isolation 6D4122 as well as lithographically defining the cell sites. It is also within the scope of the present invention that the cells could be soldered before the power plane is bonded; with the solder applied as paste or preforms the cells could be placed and bonded during the reflow that bonds the solder to substrate, or, when molten solder is applied to the backplane and allowed to solidify, the cells can then be placed and a subsequent reflow step used to solder the cell. When attaching the power plane after the solder is applied to the backplane, power-plane 6D4112 preferably has bond-wire sites 6D411253 prepared, such as by ENEPIG-plating, before attachment (plating is generally thin enough to not need recesses in a pressing plate during bonding). This is strongly preferred if the cells are also placed on the backplane before the power-plane is attached since this avoids exposing the cells to the plating (or other bond-wire-site-preparation) process.

Whether the power plane is patterned with punching or with etching, in more-preferred embodiments of the present invention electrons can flow in the power plane between the cells that receive light from a given secondary concentrator. Allowing the electrons to flow between these cells, instead of having to flow around a whole row of cells, shortens the path in the direction that the receivers are in series, which is along the focus of the primary concentrator, thus reducing resistive losses for a given power-plane thickness. In punched power planes this is achieved by having a small hole in the power plane for each cell rather than one larger hole for each row of cells. With power planes that share a copper layer with the backplane, this is achieved by having the power-plane fingers, such as 6B41122, pass between the cells, in spite of being constricted to allow enlargements in the backplane fingers 6B41112, rather than using much broader fingers running across the receiver (in the direction across the primary concentrator's focus).

The power plane and its thin isolation can be patterned in areas sized for a single receiver, but preferably they are patterned as a larger sheet and cut into multiple receiver-sized pieces before being bonded to their electrical backplanes, and even more preferably they are patterned as large sheets that are bonded to large sheets of electrical backplane material (which in exemplary embodiments is plated AlSiC, namely, a highly thermally-conductive, electrically conductive material with a solderable surface at least where the cells will go copper), and the bonded sheet is then cut into multiple receiver substrates. AlSiC can be roll-formed as large sheets, or sheets can be cut from a large cast block of AlSiC to allow better control of thermal expansion (and in high-volume production wire-sawing could bring the cost even lower than rolled AlSiC). The punched-copper sheet can also be fabricated in large sheets, and since no precise alignment to the AlSiC is need, they can be bonded as large sheets and cut into receiver-sized slabs after bonding. To cut receiver substrates from a sheet, AlSiC can be cut by saw or by laser; when a saw is used it can be advantageous to remove copper from the power plane along the kerfs to prevent the sawing from smearing the copper and shorting it to the backplane. While a dotted line of holes separated by at most twice the etch distance could be punched along the kerfs for etching to remove the copper, the punch-and-etch process is better suited to larger hole with little etching copper (the etchant has trouble getting into small holes, and large holes with little etching would leave a fragile kerf-line during etching and bonding). However, since much less precision is needed for the kerfs, the top (or bottom) etch stop can be eliminated from such lines by less precise means, including but not limited to scraping, heating, dissolving, or by preventing it from being deposited there by pre-coating such lines with a dissolvable material that repels the etch-stop. If singulation means that do not risk smearing the copper (namely, distorting the conductive planes so that they short together) are used, such as a laser or water-jet cutting, there is generally no need to remove copper (namely, conductive material) from the kerfs before singulation.

With each hole in the resin (namely, in the patterned solder-repellant material, whether it be the resin of resin-coated copper, prepreg, or solder-mask) being very close to the size of the cell, and with the resin repelling solder to confine it to the hole in the resin and with a ring around the resin hole free of any copper for the solder to stick to, the solder does not need to initially be accurately aligned to the resin hole, and the cell as initially placed does not need to be accurately aligned, either. This allows, without limitation, solder paste to be jetted into each hole, or to be stamped or stencilled into all holes at once, or plated onto the back of the cell wafer before it is diced, and allows the cell to be placed without high precision. As long as some solder touches the backplane in the hole and no solder touches the power plane, and as long as the cells touches the solder and the cells do not touch the power plane, then as is well known in the art of electronics assembly with small components (and taught by Hayashi for small tandem cells), when the solder is reflowed to bond the cells, the solder's surface tension will draw each cell's solder fully into its hole and center the solder there, and center the cell on the solder, producing an accurately-aligned array of cells all soldered to a common backplane. It should be noted that while sintering silver, Z-axis film, or conductive epoxy could also be used, these lack the self-centering properties of melting solders and hence are less preferred due to requiring more-accurate placement.

In preferred embodiments of the present invention, a receiver comprising a two-dimensional array of cells may have the cells electrically in parallel on an electrically-and-thermally-conductive substrate that serves as a common electrical backplane for the back contacts of the cells, and in further preferred embodiments the top contacts of the cells are each connected to a common power plane on top of the substrate and electrically isolated from it, and in even further preferred embodiments the common power plane is a metallic sheet, preferably primarily comprising copper, more preferably between 30 and 100 microns to provide low resistance with low cost, and in exemplary embodiments is ‘2-oz copper’ (2 ounces per square foot, which is close to 70 microns thick) as is widely used for circuit-board power planes. For lowest total resistive losses without excessive cost, the backplane has electrical resistance roughly comparable to the power plane; for AlSiC this is roughly 1 mm thick, so AlSiC between 0.5 and 2 mm thick is preferred, with 0.8 mm to 1.2 mm exemplary.

Referring again to FIG. 5A, to ensure that handling costs are lower than for silicon-cell PV, the receiver 54 may have a contiguous substrate 341 that is smaller than a typical silicon wafer (smaller than 17000 mm²) and produces more Watts (when the optics are optimally aligned to the sun) than a single silicon PV wafer (which is currently ˜3.5 W for the best silicon wafers). More preferably the receiver produces at least 10 W (namely, under full sunlight of 1000 W/m² DNI, when the optics are properly aligned to bring maximum light to the cells), and in especially-preferred embodiments the receiver produces at least 30 W. For even lower cost in connecting the cells' top contacts to the power plane, the receiver is preferably small enough to fit in a high-speed wire bonder. These typically have a bond area of at least 50 mm×50 mm, and at most 100 mm×100 mm, so even more preferably the receiver's cell array is smaller than 100 mm×100 mm, and still more preferably is smaller than 50 mm×50 mm. With the exemplary trough and lens tile widths already discussed, the lens tile is less than 50 mm wide already, so a single receiver can span the trough's focal width (and thus the length of a row of cells focused on by a lens). In the other direction a receiver's length depend on how many rows of cell it holds; with lenses roughly 9 mm wide, and thus the cell rows on a roughly 9 mm spacing, up to 12 rows could fit with the area to be wire-bonded (9 mm times one less than the number of rows, plus less than 1 mm for the bond wire length) could fit in a 100 mm wire-bonding area, or up to six rows could fit in a 50 mm bonding area, so these form exemplary receiver sizes when combined with those embodiments.

With of all cells 35 in parallel, the current of a receiver 54 is proportional of the number of cell rows that the receiver comprise, so shorter receivers have lower current (and the receivers will be placed in series so shorter receivers produce a higher voltage per module). Most CPV systems try to minimize the cell area in parallel to reduce current and thus minimize resistive losses from receiver to receiver, and it is possible to go to a single row of cells per receiver and remain within the broadest scope foreseen for the present invention. However, in the present invention this is sub-optimal; with the exemplary power plane and backplane the resistive losses are already sufficiently low, and single-row receivers would produce such a high module voltage (over 500V with exemplary dimensions detailed above) that module strings would be too short and too low current, requiring more external wiring to harvest the electricity produced. Each receiver will have a bypass diode 542, and the most cost-effective size currently matches 6 rows of today's tandem cells (but this will change with future cells that have more junctions, and may change with future diodes). Cells can trade voltage for current efficiently within about a 2% range, so having roughly 50 or more microcells 35 per receiver provides redundancy in case of a defective cell or bond; thus with the exemplary embodiments described above having 16 cells per row, there is also another advantage to at least 3 rows of cells per receiver. Having a row of modules on a tracker add up to an efficient voltage for an inverter simplifies wiring, but inverters have different voltages and trackers are different sizes, so between 3 and 6 rows of cells per receiver the ideal number depends on circumstances in which the module is to be used; fortunately, the present invention is easily adaptable to any number of rows in this range. Preferred embodiments therefore have at least 2 and at most 12 rows of cells per receiver, and more preferably at least 3 and at most 6 rows. 6 rows is used in subsequent examples because it currently the most cost effective, but it should be understood that difference is small enough that inverter-voltage matching consideration can easily over-ride the small savings and it is the principles that are important rather than the current optimum.

Even a lens highly transparent in the wavelengths critical for tandem cells absorbs some energy in those wavelengths (on the rough order of 1% to 2%, but highly dependent on the type of glass), and the lens material absorbs more at longer wavelengths that are less important to, or even not useable by, today's tandem cells. While the exact absorption in the lens depend on how much of the longer wavelength the mirrors absorb as well as the specific lens glass, on the rough order 5% of the optical energy is absorbed, so at roughly 40× overall concentration it absorbs roughly twice as much energy per area as a black sheet in full sunlight, or roughly 0.2 W/cm². While at this modest heat flux even just re-radiation in infrared and natural convection would keep the glass cool enough not to harm the glass, the expansion of the hot glass relative to the cooler receiver would shift the lenses relative to the cells. If the module is narrow the glass can be cooled from the edges, and if the cones (namely, the TOEs) are also flexible (e.g., silicone) and are attached to the cells, then the cones will flex enough to still guide the light to their cells, but this adds an unnecessary constraint. The narrow cones pressing on the cells also only provide a small total area to hold the receiver and the lens in position relative to each other.

However, in many preferred embodiments an indent 322 (as seen in returning to FIG. 3B) will be formed under each lens 3211 anyway to increase the lens accuracy, and one can be roll-formed in at essentially no cost even if not otherwise needed. The indent depth can be chosen so that the material between the indents forms lens support 323 to hold the lens and receiver alignment and also provide thermal conductivity to keep the lens temperature close to the receiver temperature so that they expand and contract together. The indent's width and profile can be chosen so that the indent's cross-sectional area provides the right amount of material for the bulge of the lens. The exact indent depth depends on the layers involved, and is best understood by example. In the exemplary embodiments disclosed above, the distance from the indent to the substrate is the height of cone 331 [namely, TOE 331] (plus any thickness allowance for optical coupling 4721 to the cell, which, as will be discussed shortly is typically self-adapting within a range of a few tens of microns) plus the thickness of cell 35, plus the thickness of solder under the cell (typically a few tens of microns, as is common in the art of circuit board assembly); this should be equal to the depth of indent 322 minus the thickness of the power plane 5B4112 and its thin electrical isolation 5B4122, and minus the thickness of the mechanical adhesive 3B74 that will bind the lens and receiver mechanically together (which is also generally self-adapting, being applied in a liquid state). Layer thicknesses and molding are generally well controlled, and as noted a viscous liquid or paste adhesive such as epoxy (and the optical coupling, namely, when a liquid optical coupling is used) can squished before curing to comply with any minor variations.

When flexible TOEs are compressed against the cells, the viscosity is preferably sufficient to hold the receiver in place against the force required to compress the array of TOEs; however the preferred optical silicones are very soft, the TOE compression is only a few percent, and the aggregate TOE cross-sectional is small, so the forces involved are typically on the same order as the weight of the receive, and in any case are small compared to the force required to pull the receive from the lens tile against the suction of a viscous liquid or paste.

In spite of serving as a thermal conductor to cool the lens, the mechanical adhesive 3B74 does not need high thermal conductivity; with roughly half of the lens area in contact, the heat flux through the adhesive is at only very roughly 400 mW/cm²; an un-filled epoxy generally has a thermal conductivity of roughly 1.3 mW/cmK, so a 100 μm layer (i.e. 1/100 cm thick) would raise the lens temperature by only 3° C., and with a filled commercial epoxy such as JB Weld, the temperature rise would be less than 1° C. Glass is more thermally conductive, but the heat must flow much farther in the glass; thermal modeling in COMSOL shows that the lens of the exemplary embodiments will average roughly 10° C. warmer than the substrate when in full sunlight, and the shear strength of typical epoxy is easily enough to constrain the relative expansion, especially if the SiC percentage in the AlSiC is tuned so that the substrate has a very slightly higher CTE than the lens glass. Preferred embodiments therefore have a substrate 341 with an average CTE (including the minor effect of the adhesives and copper layers, and averaged over the −30° C. to +80° C. temperature range that a solar module must endure to be broadly useable in most high-DNI regions) of between 1 PPM/K lower and 3 PPM/K higher than the lens tile 321, and more preferable between that of the lens tile and 1 ppm/K higher than the lens tile.

With optical coupling between the cells and cones (namely, TOEs) that is liquid (namely, compliant) when the receivers and lens tile are bonded, and with the adhesive between them also being liquid (namely, compliant), these interfaces can adapt to the position of the receiver relative to the lens. Small-electronic-parts placement generally has tight horizontal control, and presses a part into place in the vertical direction, but if the cones are flexible silicone, none of these provide tight vertical control. Pressure during placement can provide such control, but is sensitive to adhesive viscosity, which strongly depends on temperature, and viscosity may also vary during the pot-life of the adhesive, so there is a risk that during assembly a too viscous mechanical adhesive would prevent the optical coupling material from connecting the cones to the cell surface, or that a too-low-viscosity mechanical adhesive would allow one or more or the adhesives to squish to where it would interfere with the optics or the electrical connections. It is therefore useful to provide hard stops 3231 for the vertical movement during assembly; these can easily be formed in the lens tile during rolling as one or more small ridges in the lens support 323 between the indents 322.

Preferred embodiments of the present invention therefore have lens supports 322, that bond with adhesive to substrates 341 (between cell rows) after the receivers 54 are mated to the lens tile 321 during receiver-to-lens assembly, in more preferred embodiments this lens support 323 is formed during roll forming, in even-more preferred embodiments the support has sufficient contact area to the lens and the adhesive is thermally conductive enough to conduct heat from the lens to keep that average lens temperature less than 20° C. above the substrate temperature under full sunlight, and in exemplary embodiments the supports have small ridges roll-formed in that serve as hard stops 3231 for vertical motion during receiver-to-lens assembly.

The present invention is not restricted to tandem cells, but could use other cells suitable for very high concentration and small cell sizes, and it can easily be adapted to larger cells at lower concentration if such cells cost enough less per area to be cost-effective. However tandem cells are the best match among cells commercially available today, so the optics in all examples are optimized for today's tandem cells. In particular, most tandem cells today are triple-junction tandem cells that have excess photocurrent for their bottom junction; the low-iron glass and ultra-low-iron glass used in the preferred embodiments is exemplary with such cells because although it absorbs significant light for the third junction wavelengths, that merely reduces the excess photocurrent of the third junction, and the glass is extremely transparent for the wavelengths used by the top two junctions. Many experimental cells have less excess photocurrent; for example, Boeing Spectrolab's five-junction cells have two junctions in the wavelength range where iron absorbs more light, and have only 6% and 12% excess photocurrent for the 4^{th} and 5^{th} junctions versus the almost 100% excess typical of the 3^{rd} junction in today's 3J cells. With a 19-mm low-iron glass lens and two passes through 3 mm or 4 mm of low-iron glass in typical mirrors, the iron absorption consumes more than the 6% and 12% excess, whereas ultra-low-iron glass is still a good match (and is still highly affordable). Other future cells might not have that excess photocurrent, but antimony can be added to the glass to transform absorbing 2+ iron ions to a much less absorbing 3+ state. This does not work for the mirrors, which are relatively thin float glass, because the tin that the glass floats on with absorb the antimony. But since the lens is being roll-formed anyway rather than needing to be flat, the lens sheet of the present invention can be made with sufficient antimony to have more Fe+++ ions than Fe++ ions. Thus preferred embodiments of the present invention roll-form lens sheet (for lens tiles 321) from a lens glass 3210 with a low-enough Fe++ content that the bottom junction for a three-junction or a 4-junction cell or the bottom two junctions for a 5-junction or a 6-junction cell are not the current-limiting junction(s) when the primary concentrator is illuminated with an AM1.5D spectrum (typical of operation), and more preferably are not the current-limiting junction(s) when the primary concentrator is illuminated with an AM1.0D spectrum (the ‘bluest’ spectrum frequently encountered in normal operation), and in exemplary embodiments the Fe++ content of the lens glass 3210 is reduced through the addition of antimony.

An alternative to improved lens glass would be a shorter path in the lens glass. While TOEs that are optically coupled to the secondary concentration means are preferred, the TOEs can be molded on separate receiver-sized sheets of glass (or on a large sheet that is then cut into receiver-size regions). With an air-gap between the lens sheet and the TOE sheet, this allows a shorter path in the lens-tile glass, and that path can be independent of focal width on the secondary concentration axis, allowing wider cells without high absorption losses in the module optics. However the addition of two air/glass interfaces induces some optical losses (which could be acceptably low with nano-textured anti-reflection coatings), and with the receivers not bonded to the lens tile obtaining and maintaining alignment becomes more difficult. The drawbacks currently outweigh the benefits, so an air gap between lenses and TOEs is not currently preferred, but it could become preferred in the future. In addition to future cells having less excess photocurrent at wavelengths where low-iron glass absorbs more of the light, future cells with more junctions will have higher voltages and lower current per area, reducing the small-cell efficiency advantage and thus pushing the optimum to larger cells and thus wider lenses and a longer lens focal length. An air-gap between lens sheet and TOE sheet is thus discussed as a possible preferred embodiment in case antimony in the glass is precluded or is insufficient. Having a receiver-sized array of TOEs molded on a glass sheet allows handling the array without distorting the relative positions of the TOEs. The lens sheet can be conductively cooled from its sides, or high-thermal conductivity material between the lenses, such as 1-mm-thick aluminum sheet, can conduct the lenses' heat to the receiver substrate.

Returning to the currently-preferred embodiments, most tandem cells for high concentration are made with a bus bar along two opposite edges of the surface of the cell, and these bus bars are typically wide enough to land a wire-bond on, most typically between 150 μm and 250 μm wide. While on a large cell 5 mm to 10 mm square (5000 μm to 10,000 μm on a side) this is a small die-area cost to pay for the convenience of being able to land multiple bond wires anywhere along those edges, for microcells less than 1000 μm on a side such bus bars significantly increase the die area and thus the cell cost. Microcells therefore use narrower and more complex bus bars, but the cost is still high; for example, in both Hayashi1 and Hayashi2 the cell has a total area of 0.94 mm² of which only a central octagon of 0.672 mm² is a photovoltaic region. As well as being easy to bond to with short bond wires, bus bars on the sides of the cell can be out of the path of the concentrated light and thus not block it. To keep the current from having to travel too far in the narrow bus bars, multiple contacts (wire-bonds or solder) are used. In the both the Furman and Hayashi microcells, two top-grid contacts are used in the cell corners, while the other two corners are occupied by re-mapped bottom cell contacts.

However while corner-contacts can be used with the present invention, the current from a microcell is sufficiently low to be carried by a single bond wire, and as seen in FIG. 7, preferred embodiments of the present invention may reverse the top grid to carry the electrons to a single bonding pad 7521 near the center of the cell 35 rather than to multiple contact points on the edges of the cell. While this does occupy some of the illuminated surface, the high-speed wire-bonders for small substrates can easily hit a tiny pad on an electronic chip (over 10 trillion wire bonds are made each year on small substrates), so the bonding pad can be very narrow. The bonding pad 7521 can taper in each direction to become a narrow central bus bar 752 that collects electrons from grid fingers 7522 on the cell surface; the bus bar does not need to reach the cell edge but merely the last grid finger toward each edge, reducing the area that it (namely, the bus bar) occupies. A central bus bar allows slightly shorter grid fingers than carrying electrons to bus bars on two cell edges (since the fingers do not need to reach the cell edges), and much shorter grid fingers than would be needed to carry electrons to a single cell edge, reducing the grid finger area enough to compensate for the area of the bus bar itself. This keeps the cell efficiency high while eliminating the die area normally spent on edge bus-bars, and allows using a single bond wire 753 (shown as a dotted curve because it is not part of the cell but is bonded after the cells are placed). For cells less than a millimeter long, a single central contact is optimal, but for longer cells this could be extended to provide a bonding pad every millimeter or so down the middle of a cell.

Optimally such a single-bond-wire's contact point 7530 is centered in the length of the cell but is closer to one edge than the other on the width of the cell (closer to the edge that the other end of the bond wire is closer to, hereinafter referred to as the ‘near edge’ 7541); this shortens the bond wire and thus reduces its cost (bond wires are typically gold), its resistance, and its shadow on the cell. While this does lengthen the distance that some electrons travel in the central bus bar to reach the bond wire, it shortens the path of others, and for small shifts from the center these almost balance. With metal thickness typical of a cell's top grid and bond-wire diameters optimal for carrying a single microcells current the optimum position is generally between 30% and 40% of the way across the cell, but it is a pretty flat optimum. An asymmetric bus bar could slightly reduce the bus bar area for a given average resistance, but the savings is small enough that a symmetrical cell is preferred to eliminate one cell placement constraint.

In preferred embodiments of the present invention, the cells 35 have a central bus bar 752, that includes a bonding pad 7521, for their top contact, more preferably running across the narrow direction of the cell, even more preferably tapered to be narrower toward the edges of the cell, still more preferable stopping at the last grid finger toward each edge of the cell, and in exemplary embodiments symmetric. In preferred embodiments the central bus bar in contacted by a wire bond whose contact point 7530 is closer to one cell edge than the other, and in exemplary embodiments that center of the wire-bond contact is between 30% and 40% of the way from the near edge 7541 of the cell to the opposite edge.

In a typical Fresnel/Box CPV system, all cells in a module are in series and thus must match photocurrents. However even cells made by the same company with the same process are not truly identical, but can vary considerably in performance from cell to cell. While cells can efficiently trade voltage for current within a narrow range, performance variation can exceed this range even for cells cut from the same cell wafer. Cells are typically therefore individually tested not just for gross defects, but for performance, and are usually sorted into performance ‘bins’ with a narrow enough range for the cells to match photocurrents efficiently when illuminated similarly. However with preferred embodiments of the present invention having 10 to 20 cells per cell row, and 3 to 6 cell rows per receiver 54, there are many tens of cells per receiver. With all cells of a receiver in a parallel, only the photocurrent from the whole receiver must match the photocurrent from other similarly-illuminated receivers. The large number of cells allows the performance-binning to be forgone because even if the individual cells vary by up to 10%, the few ‘hero cells’ will tend to balance the few laggard cells, and with most cells in the middle of the pack the average of one receiver's cells will be very close to the average of another receiver's cells. Only the non-functioning cells and really poor performers need to be removed; this allows less-precise testing at lower cost.

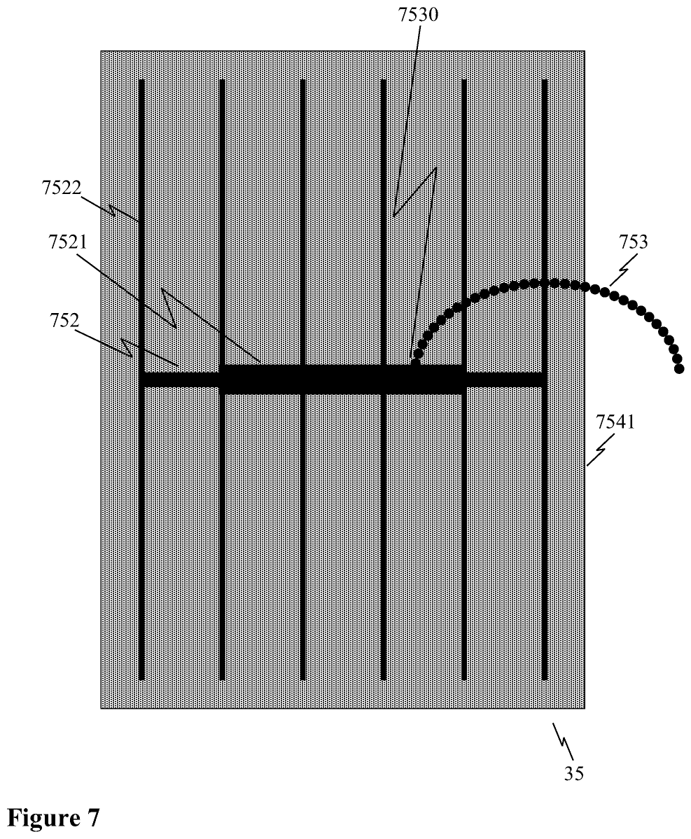

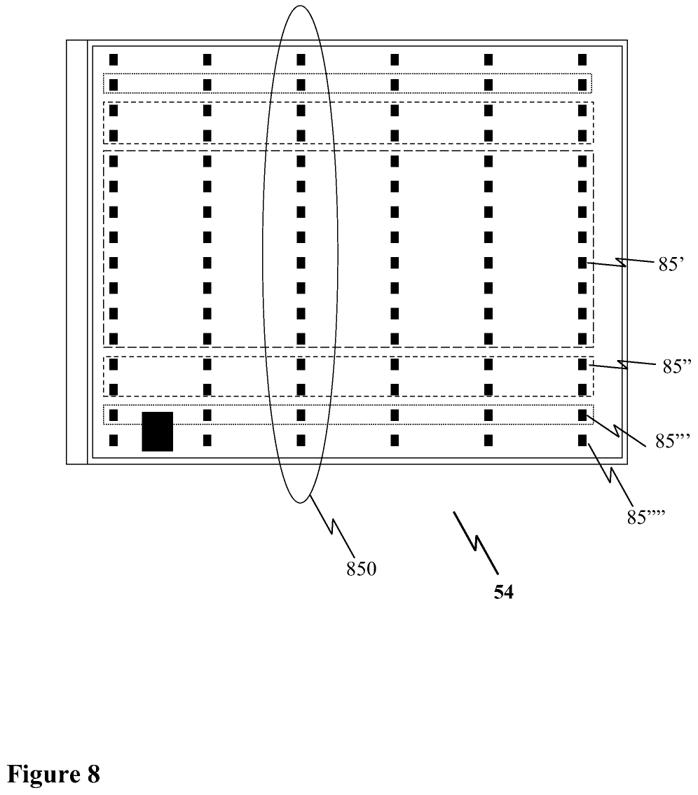

However, performance binning can still be useful. The array of tiny foci will be very even from row to row, but it will not be even along a row. In particular while the central half of a row will be intensely (and evenly) illuminated, the very end cells of a row only catch light from the edge of the sun that hits a slightly misaligned mirror when the tracking is slightly off, and all errors are in the same direction. Rather than foregoing binning to slightly reduce cost, binning can be used to separate out below-average cells that can be used toward the ends of each row. Consider a cell that is 20% below average performance—such a cell would normally fall below the last bin because with the typical high cost of bringing light to the cells, there would be no market for a module made with such cells. If, however such a cell were used at the end of a row where it is only catching stray light, the loss of energy from its lower performance (although proportionately the same) will be greatly reduced because there is less energy to lose. And although outlier cells vary more in performance, with many cells in parallel (on the order of 100 in exemplary embodiments) a few cells 20% below average instead of 10% below average (by way of example), make only a few tenths of a percent difference in array output, which is within the range the cells will compensate efficiently for by trading voltage for current. Since cell yield is a significant contributor to cell cost, being able to use ‘off-spec’ cells efficiently can significantly reduce total cell cost. Several bins can be used; for example, as shown in FIG. 8, with the exemplary sixteen cells per cell row 850, the eight central cells 85′ in each row can all be cells that are average or above, the next two cells 85″ on each side of the center can get the lower-middle performance bin, and the next cell 85′″ on each side can get the normal bottom bin, and the last cell 85″″ on each side can be a cell that would otherwise be thrown away. The performance will be as high as if the cells were not binned, but the yield of useable cells will be increased from 14 to 16 cells. Hybrids are also possible with fewer but broader bins that combine quicker testing with being able to accepting more cells. While this slightly complicates component management, high-speed placement equipment normally handles dozens of different component types at a time so that actual assembly impact is very low. With cells being by far the largest module cost, the savings would currently be worthwhile, but it should be noted that if cell cost were to drop dramatically, the value of using off-spec cells would decrease as well.

Currently-preferred embodiments of the present invention therefore either use un-binned cells (with just cells with gross defects removed) to reduce cell testing costs, or used performance-binned cells and place higher-performing cells in the more-illuminated middle cells of each cell row.

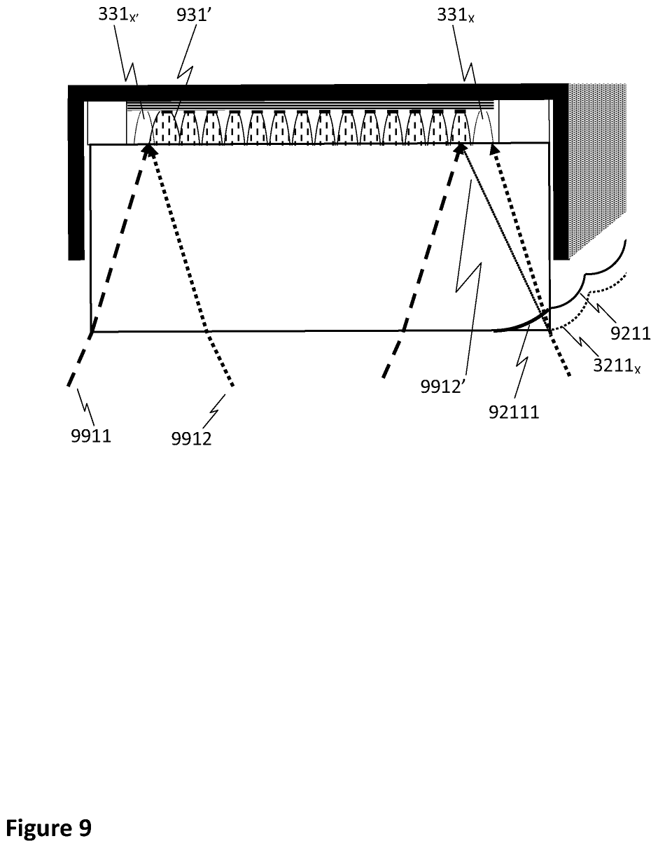

Another way to deal with the weaker light at the edges of the trough's focus is to compress some of it into stronger light. The spread of the sun's image is proportional to distance, so as also shown in FIG. 9, light 9212 from the far edge of the trough (farther from the axis of symmetry, and thus farther from the focus) spreads more than light 9211 from the near edge; with an off-axis trough this is significant even at the rim angle of a single RP-3 inner mirror. The light from the far edge of the trough is thus wider than the light from the near edge, and thus some of the lens front is illuminated only by light from the far edge of the trough. The far end 92111 of each lens 9211 can be slanted or even curved toward its row of cones (namely, TOEs) to direct light from near the edges of the lens more toward the center of that row. The effect is not large because the lens is not thick, and at the index of refraction of glass versus air (1.5:1) the slant of the light 9912′ in the lens is only changed by at most roughly ⅓ as much as the surface of the lens is slanted. But since the effect increases the average concentration without increasing the peak concentration, the savings can be well worthwhile. This does make lens sheet profile in the direction of rolling non-constant, but many roll-forming patterns are even further from constant, so the accuracy is maintained (especially in the intensely illuminated middle of the lens tile) as long as the slant is not too steep. But slanting the lens ends should not be taken to extent that it significantly complicates forming the lens.

Since the light from the far edge of the trough hits the lens at the steepest angle, it focuses before the cones (namely, before the TOEs). Slanting the lens surface toward the cones changes this angle: at the edge of the lens tile nearest the far edge of the trough, not only brings the lend surface closer to the cones but decrease the angle of the light to the lens, which reduces the Petzval effect and increases the effective focal length of the lens, improving (narrowing) the focusing of the lens for slight slants, so the lens ends can have the same secondary focusing curve as the middle of the lens. If slanted enough that the same secondary-focus curve would have a focus broader that an un-slanted lens then the secondary-focusing curve of the lens can have its radius of curvature decreased slightly to compensate (this is exaggerated in FIG. 8 for visibility); while a greater slant would normally reflect slightly more light, except in extreme cases that is more than balanced by the reduced angle of the light in the other direction (and the light is weak in this area anyway, so the net effect is small). The lens slant is beneficial up to about 30°, after which the returns decrease and the costs increase; this can thus slant the light by roughly 10 degrees which narrows the trough's focus (and thus the length of the cone row) by up to roughly 3 mm in the preferred embodiments, thus eliminating the need for cone 331_{X} and its cell.

While 3 mm hardly sounds worthwhile, it is 9% of the focal width from the exemplary mirror, or roughly two cells of a 16-cell row. This does slightly compete with using weaker cells at the row ends, but a cell avoided is even lower cost than tolerating a low-performing cell, and the row ends are still less illuminated than the center, so these strategies can be used together for minimum cost. While the slants described do not significantly complicate roll-forming, they do significantly complicate the manufacture of the roll-formers, so slanting the lens ends is only worthwhile at significant production volume where the cost can be amortized across vast areas of lens sheet. Embodiments of the present invention more-preferred for high volume production therefor slant (curve) the ends of the lenses toward the cone (namely, TOE) tops, in especially preferred embodiments the slant reaches between 20° and 30° on the lens end nearest the far edge of the trough (namely, the edge of the trough farthest from the focus) and the slant reaches between 10° and 20° on the lens ends nearest the near edge of the trough (namely, the edge of the trough nearest the focus), and in exemplary embodiments this is combined with performance binning the cells and using lower-performing cells in the less-well-lit areas.

On the near end of the lens (nearest the near edge of the trough), slanting the surface toward the cones is not useful on its own because light from the far edge of the trough drives the length of the cone row. But it can be used in conjunction with a third way to deal with the weaker light at the row end, which is to modify the cones (namely, the TOEs) at the row ends. If the near lens ends is slanted, then light reaching the last cones comes in from only the far edge of the trough, so the cones can be slanted toward that light, and, with a much narrower angular range along the row, can concentrate that light much more. However, slanting the cones complicates the molding, so this is not preferred unless cone rows (namely, TOE rows) are molded separately with a common root.

But the concentration power of a cone (namely, a TOE) can be increased even without slanting it if the loss of light in the corners of the cones is accepted; since there is less light to lose at the row ends, the cones there could concentrate roughly 20% more at the loss of 2% of that light. Just as with using lower-efficiency cells at the row ends save more on cells than the less-efficient use of the weak light costs, so, too, can less-efficient cones that concentrate more save more in cell cost than a slight loss of weak light. At current cell costs this would be worthwhile at large production volume, so more-preferred embodiments for high-volume production use cones 931′ at the cone row ends that have wider acceptance (namely, acceptance angle) for incoming light) along the row than the cones 321′ in the center of the row, and accept cone optical losses of up to 3% for the end-of-row cones. This is almost sufficient to eliminate a cone 331_{X}′ and its cell, and since slanting the far end of the lens gained just more than one cone, upon reading this it will be obvious to one skill in optics to re-center the row of cones (and, if needed, to slightly resize cones and cells) to eliminate full cones (namely, full TOEs) and their cells.

The receiver interconnections, the module length, the module housing, and the heat rejection have not been discussed to this point because the they differ significantly based on whether the module of the present invention is on a tracker that trackers on one axis, like a solar thermal trough and like the CPV module disclosed in Cooper, or is tracked on two axes, like traditional Fresnel/Box CPV module and like the trough based CPV system of Wheelwright and SunOyster, while the discussion up to this point apply to both versions of the present invention. The single-axis version is discussed briefly, to the extent that the above-disclosed aspects of the present invention apply. The two-axis-tracked version is then discussed in greater detail because it is simpler and currently will produce electricity at lower cost (but if cells drop in price faster than two-axis tracker, or when heat is desired as a by-product, the one-axis version becomes more preferred).

### Preferred Embodiments of the Present Invention Directed to Single-Axis Trackers

Single-axis trackers are well known in the art of concentrating solar energy, with almost all achieving 1-degree accuracy, most achieving 0.25 degree accuracy and many achieving 0.1 degree accuracy. While most single-axis trackers have level axes of rotation that are oriented north/south, east/west axis orientations are also found, as well as intermediate orientations. North-south orientations are preferred; an east/west orientation may be used but the sun's very high skew angle near dawn and dusk, especially near the equinoxes, will cause loss of light at those times. The single-axis-tracker-specific preferred embodiments of the present invention will work with level-axis trackers, or with slanted-axis tracker; for a given trough length, trackers with equatorial slants are preferred outside of the tropics. Longer troughs are also more preferred than short troughs due to less loss of light at the ends of the rough at high sun skew angles. Preferably the single-axis tracking means supports one or more primary concentrators and their narrow modules, with primary-concentrator-to-module alignment within 10 millimeters, preferably to within 3 mm, with alignment to within 1 mm exemplary, with the tracker providing alignment to the sun to within 1 degree, preferably to within 0.25 degrees, with within 0.1 degrees exemplary.

A provisional patent application on the novel features of the present invention specific to single-axis tracking is being prepared, and is expected to be co-pending with this application. While that application will go into much more detail, the same receiver as taught so far is mated to a receiver-length lens tile, and the receiver with its lens tile form a mini-module. Many such mini-modules are aligned along the trough's focus (with the same RP-3 mirrors being suitable, namely, for the primary concentrators), ganged together to be rotated in unison by a common control rod. With the teachings of Cooper (namely, the rotation of each receiver, together with its secondary concentration means and its cooling means, about a secondary tracking axis, with all receivers driven by a common linear actuator) and the teachings heretofore presented in the present application, this is sufficient to enable one skilled in the art to implement the basic aspects of the present invention (namely, including, but not limited to, the lens tile with multiple linear lenses, the receiver with cells in parallel receiving light from multiple secondary concentrators, the TOEs molded on the back of the lens tile, the optimized cells and substrates, and various combinations thereof as described in the preferred embodiments above) in CPV systems that use trough mirrors tracked on a single axis (namely, as primary concentrators).

Preferred embodiments of the present invention may provide multiple significant improvements over the prior art of high-concentration from single-axis-tracked primary concentrators. As taught in Cooper (and Norman1), high concentration from a single-axis-tracked primary may be achieved by intercepting the primary concentrator's focus with receivers that comprise secondary optics where the receivers individually rotate to align to the sun's direction on the second concentration axis. Because the individual receivers are small, and move only a small distance, this is often referred to as micro-tracking.

There are optical, thermal, and mechanical advantages (many of which have been taught above in the present application and in prior art such as Hayashi1) to keeping the light path in secondary (and tertiary) optics in a solid medium, and in his FIGS. 4.2.4 and 4.2.5 Cooper discusses the limits that closely-spaced solid secondary concentrators must fit within to order to be able to rotate without interfering with each other during rotation. Regardless of scale, the allowable thickness of the secondary and can be seen to be less than 1.5 times the width of the secondary concentrator, and an ordinary lens of ordinary lens glass lens (including entry-level instrument-grade glass as well as commodity low-iron glass) cannot focus within itself in less than 1.5 times its width, and even Fresnel lenses decrease significantly in efficiency if pushed to such short focal lengths relative to their width. While the shorter focal length from a high-refractive-index flint glass or leaded crystal glass can be within 1.5 times the lens's width, such glasses are less transparent across the wavelength range that CPV uses, and are far more expensive, and thus are currently not preferred for the lens sheet material.

However Cooper's exhaustive study missed the case of multiple secondary concentrators coupled to a rigid receiver that has multiple rows of cells to absorb the foci of the multiple secondary concentrators, and Cooper teaches away from this because a longer receiver (in the direction along the trough's focus, puts part of the receiver farther from the optimum height within the primary concentrator's focus as the receiver rotates to track the sun's skew angle (its angle relative to the primary concentrator's focal line). However preferred embodiments of the present invention may overcome this limitation, as illustrated in FIG. 13A, with a short section 1321 of lens tile of the present invention. The short section of lens tile comprises just few lenses 13211 that each focuses on a row of cells (with just one cell 135 of each row seen in this cross-section). The focusing 1392 onto a cell of one lens (labelled 13211′) is shown, and, as can be seen, its focal length within the lens tile may be much longer than 1.5 times the lens width, and yet if both receivers, with their lenses, are rotated about their axles 136114, the receivers and lenses will not interfere with neighboring receivers and lenses. Nor will they hit common coolant pipes 1361423 because those, as can be seen in FIG. 13B, are not in the same plane as the space that the receivers rotate in. The short lens tile may also have TOEs 13B31 (as shown in lens tile 13B21 of FIG. 3B but not in lens tile 1321 of FIG. 3A).

The receivers could be cooled by any of many means that are known in the art of cooling CPV receivers, (including, without limitation, impinging jets as taught by Cooper, and thin micro-channel cold plates taught by Norman2). While coolant ingresses and egresses could be through flexible tubes as taught by Cooper, more preferably the receiver axles comprise rigid coolant ingress and egress tubes 136114 that preferably sit in grommet-seals 13B61141 in common coolant pipes 136142 so that they may rotate with little force while remaining leak-free (no distinction is made in the drawings because in these example ingress and egress are symmetric down at the level of detail shown). The other ends of these ingress and egress tubes are embedded in receiver housing 1366, which may preferably be molded from a fairly-low-thermal-expansion polymer such as BMC, and which carries coolant to and from cold plate 13614, which is in intimate thermal contact with substrate 1341 and, through it, with cells 135.

Multiple receivers, with their short lens-tile sections, are linked to a common control rod 136116. Each linkage is through a bead 136118 that is affixed to the control rod, and thence trough wicket 136117 that is constrained by bead 136118 but is free to rotate within it on one axis (parallel to the axis of secondary concentration). The length of the wicket's legs provides leverage to easily rotate the receiver, and also to ensure a well-controlled rotation angle. Preferably common control rod 136116 is made of a material with similar thermal expansion to coolant pipes 136142 (copper pipes and a 304-stainless steel control rod being an exemplary combination) so that several meters of wickets, and thus of receivers, can retain their relative alignment to within 0.25°, and more preferably to within 0.1, in temperature swings from winter to summer. A multi-lens tile may rest flat against a flat surface, so preferably during module assembly the beads 136118 may be loose on control rod 136116, all lens tiles are rested against a flat surface, and then each bead adhered to the control rod with a drop of adhesive, locking in the relative alignment of all wickets and thus their receivers. As is known in the art, the common control rod can be driven by a linear actuator, preferable driven by a stepper motor, through a hinged linkage. An exemplary embodiment of a module may hold 80 receivers each with a 6-row receiver and a six-lens lens tile using the exemplary lens width describe previously. After accounting for module ends and half-millimeter gaps been lens tiles at tropical noon), this produces a 4060 mm module matching a standard length of solar thermal trough receiver tubes.

Rotating a secondary concentrator around a second focusing axis perpendicular to a trough's focus (or other linear primary focus) necessarily puts different parts of the secondary concentrator before or beyond the trough's tightest focus by an amount proportional to the length of the secondary concentrator's aperture (along the trough's focus) times the sine of the skew angle (the aperture's angle to the trough's focal line). Cooper teaches rotating a receiver about the middle of the aperture of its secondary concentrator to minimizes the distance above or below the focal line by putting half above and half below the focal line. However, this is not optimal, especially at low trough rim angles, because the trough focus is narrow when the sun is at low skew angle and broader at high skews angles. For a single RP3 mirror's rim angle, the trough's focus is almost twice a wide at a 60° skew angle (e.g, a level trough noon on December 31 at latitude 37° N) as it is at zero skew angle (a level rough with the sun straight overhead). If the receiver is wide enough to catch most or all of the focus in the winter, it has excess width in the summer and with most CPV cells the efficiency would be higher if the summer focus were wider (spread across more cells). Preferred embodiments of the present invention may therefore offset the center of rotation on the secondary tracking axis so that the secondary concentrators are more centered in the focus at high skew angles than at low skew angles.

60° is a preferred skew angle to optimize for because few areas with good sun for CPV are at latitudes much higher than 37°, where the maximum skew angle is 60°. Closely-spaced secondary concentrators also shade each other significantly at high skew angles; at a 60° skew angle only half of each set of secondary concentrator will be illuminated, so the illuminated half of the secondary concentrator set's aperture length is centered in the trough's focus for a 60° skew. The offset (vertical distance in the orientation of FIG. 13A) between the center of rotation and the center of the secondary aperture is then increased until the farthest corner 132111 of the lens tile 1321 just has sufficient clearance, from the receiver housing 1366 of the next receiver, at their closest approach during micro-tracking. Even with this offset maximized, with a 6-row receiver+lens tile of the exemplary dimensions described above, and an RP-3 mirror as a primary concentrator, the focus at all lower skew angles is narrower than at 60° skew, so this optimization allows a smaller receiver to capture the trough's focus over the whole range of skew angles.

The micro-tracked receivers and the micro-tracking mechanism may be robust enough to survive weather and repeated cleaning of dust, or they may be protected from the elements by any of numerous means known in the art. Example include, but are not limited to, ‘tenting’ the module and its primary concentrator as taught by Cooper, a glasshouse covering multiple primary concentrators as used in some solar thermal rough mirror installations, or by enclosing multiple receivers in a glass-fronted box as is common in CPV.

### Preferred Embodiments of the Present Invention Direct to Dual-Axis Trackers

Two axis trackers are well known in the art of concentrating solar energy, with almost all achieving 1-degree accuracy, most achieving 0.25 degree accuracy and many achieving 0.1 degree accuracy. All preferred embodiments of the present invention may be mounted on any two-axis tracking means that supports one or more primary concentrators and their narrow modules, with primary-concentrator-to-module alignment within 10 millimeters, preferably to within 3 mm, with alignment to within 1 mm exemplary, with the tracker providing alignment to the sun to within 1 degree, preferably to within 0.25 degrees with within 0.1 degrees exemplary. Such a two-axis tracker may use, without limitation, azimuth/altitude tracking, polar-axis tracking or tilt-and-roll tracking.

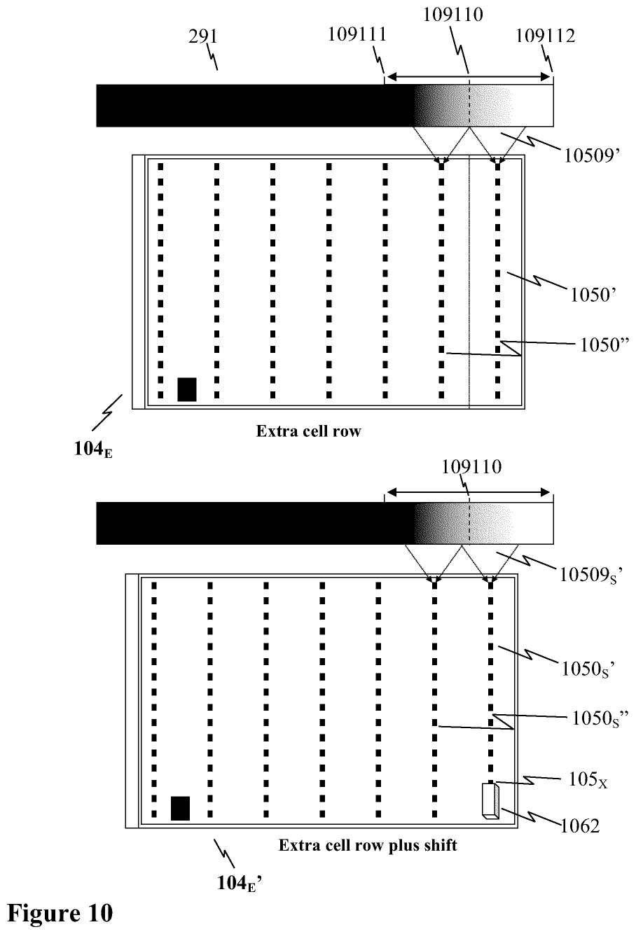

RP-3 mirrors are 1700 mm long, so this makes a preferred module 26 (as seen in FIG. 2) roughly 1700 mm long as well (namely, a module length roughly similar to the primary concentrator length is a preferred module length). With 6 rows per receiver as per an exemplary embodiment, a convenient 32 receivers fit in a module. The lens tile 221 will span the whole length of the module 26, allowing it to serve as a cover glass sealed to a module back 3611. As was seen in FIG. 5A, the receivers 54 are preferably in series along the trough's focus. With 32 six-row receivers, for the lens tile length to match the mirror length the lenses would be 8.854 mm wide. However as shown in FIG. 10, the trough's focus is very even along almost its entire length, but instead of stopping abruptly at the length of the primary concentrator, there is a small ‘spill zone’ at the end of the focus where the intensity tapers off. Largely this is from the sun's diameter, whose image is almost 17 mm in diameter at the trough's focal length. However, the tapering is slightly larger, with the sun's image from the far edge of the trough spreading light by almost exactly 20 millimeters, and imperfections in the mirrors spreading a small fraction of the light by up to another 5 mm. This can be seen in FIG. 10 by the tapering of the primary concentrator's focus 291 in the spill zone starting at 1091111 and ending at 109112; the nominal end of the focus at the length of the primary concentrator, which is at the spill zone's center 109110.

Since the 32 receivers will be in series, the same current must flow through each of them, so a receiver that receives a few percent less light than the others would have to be bypassed to keep from pulling the performance of the whole receiver string down to match, so a receiver extending into the spill zone would normally be bypassed and thus wasted. One solution is to shorten the module by about 12 mm on each end to bring the ends out of the spill zone, forgoing about 1.3% of the light (which is better than 6% of the light hitting bypassed receivers); this has the advantage that it keeps all receivers the same length. A slightly more efficient solution is to lengthen the module slightly and to extend the end-of-module receivers with two more cell rows to capture entire spill zone, but this is slightly more expensive.

However, an end receiver 104_{E} with a single extra cell row 1050′ captures almost enough light. The weaker half of the spill zone contains exactly the light missing from the stronger half, and while the lens's light gathering area 10509′ of the extra cell row 1050′ doesn't reach the end of the spill zone, it only misses the very weakest part and thus gets only slightly less light penultimate row 1050″ is missing. By slightly narrowing all lenses of the lens tile (and thus slightly narrowing the cell-row to cell-row distance and slightly shortening all receivers), the extra cell row 1050′ could be shifted into the more intense part of the spill zone, where it would capture enough light to make up for the reduced light missing from penultimate cell row 1050″. The shift needed would be roughly a half-millimeter on each module end, or only about 8 microns per lens in a lens tile according to the exemplary embodiments (which has almost 200 lenses). Thus, by narrowing the lenses by less than 0.1% (to 8.847 mm in the exemplary embodiments), and adding one cell row to the receiver at each module end, essentially all of the light could be captured at less extra cost than adding two cell rows to each end. However, this can be further improved with a slightly larger shift. The last row would still capture weaker light, so the end cells in that cell row would receive even less light than elsewhere. By narrowing the lenses very slightly further, not only will the lens's light-gathering area 10509s′ of extra row 1050s′ capture slightly more light, but penultimate row 1050s″ will also be missing less light. This spare light for end receiver 104_{E}′ (over the amount needed to match photocurrent with other receivers) can be used to eliminate cells such as 105_{X} from the doubly-weakly-illuminated end-of-last-row cell sites. Not only does this save slightly on cost, but eliminating the TOEs for those cells also provides a convenient for place for connector cage 1062 to fit in a lens indent (as opposed to adding a separate pocket for the connector). It is possibly to gain similar advantages by adding the extra row on a separate 1-row ‘substrate extender’, and connecting its backplane to the end-receiver's backplane and its power plane to the end-receiver's power plane, but this is generally less preferred in volume production because there are more parts to handle. However, if an extra row would push a receiver's size beyond a particular wire-bonding machine's limit, a substrate extender could become preferred. Preferred embodiments of the present invention therefore comprise a module with multiple receivers connected in series along the focus of the primary concentrator (as refocused by the secondary concentrator and TOEs), with the receivers on each end of the module each having one or more extra rows of cells compared to the receivers in the middles of the module, and in exemplary embodiments receives have one extra row of cells and the width of the secondary concentrator elements is such that secondary concentrator for the extra row of cell on each end spans the center of the spill zone from that end of the primary concentrator.

In addition to supporting efficient handling of spill zones, a one-to-one correspondence between modules and primary concentrators allows common support means to support both a primary concentrator and its sealed module, removing issues of aligning multiple mirrors to a module and thus simplifying installation and increasing alignment accuracy.

While placing and bonding tens of Watts of microcells on a single substrate that fits in high-speed assembly and wire-bonding equipment greatly reduces cell handling cost, the receiver still have to be mated to the lens tile, with the cells mated to the cones (namely, to the TOEs), the connection strip electrically connect to the next receiver, and the lens support pressed against the substrate. The critical alignment is the cells to the cone, and these must be optically coupled as well as aligned. While optically coupling can be done with a drop of uncured optical silicone as is normally cone for secondary optical element in Fresnel/Box CPV, a Fresnel SOE is small compared to a receiver, and in the 2-axis-tracked module of the present invention, the lens tile is much bigger than a receiver and is shared by many receivers. The process is therefore preferably reversed, and the receivers are preferably placed on the lens tile. To prevent excess optical coupling silicone from running down the cone [namely, the TOE] (where it would interfere with the total internal reflection), even more preferably the lens tile is held cones-down (namely, TOEs-down) and each receiver is placed upward against the lens tile. This upward placement could still be used when liquid optical coupling is not used; if, for example, a dispense machine or a placement machine worked better in that orientation.

While wires in connector cages could interconnect the receivers as is in Fresnel/box CPV, the present invention eliminates such cages except for the module ends, and interconnects the modules in series as they are placed on the lens tile. Returning to FIG. 5B, more-preferred embodiments of the present invention use a simple copper strip 543 attached to power plane 5B4112 at one end of a receiver 54 [preferably with solder or with conductive adhesive, unless the copper power planes are bonded to the AlSiC (namely, the remain the rest of the substrate) after singulation, in which case that copper (namely, the power-plane copper) can be cut to be long on one end and short on the other—namely, to leave an overhang strip of copper], and expose a narrow band 5B41111 of backplane 5B4111 at the other end of a receiver 54. This narrow band may have a compliant electrically conductive material 5B73, preferably an electrically conductive adhesive, dispensed on it preferably just prior to module assembly. Returning again to FIG. 5A, it can be seen that as the modules are placed side by side along the lens, the adhesive (i.e., 5B73) of module 54″ being placed will contact strip 543 of the previously-placed module 54′, connecting the backplane of 54″ to the power plane of 54′ and thus connecting the modules in series. Alternatively, all copper strips 543 for a module may be adhered to the back of the lens tile before the receivers 54 are placed on (and bonded to) the lens tile, producing the same result.

In addition to the conductive adhesive 5B73 dispensed on its exposed substrate 5B41111 to electrically connect to the previous receiver, a receiver about to be placed on the lens tile has mechanical adhesive 3B74 dispensed between the cell rows, where it will mate to the lens supports 323. In some preferred embodiments the receiver has optical coupling 4721 such as optical silicone dispensed on each cell just before assembly, to a depth that covers the bond wire, but unless this is tightly controlled it can squish to beyond the cell and guide a few percent of the light off the cell. It is therefore preferable to pre-mold a curing optical silicone (or other optical coupling), to at least the depth of the bond wire, on each cell after the cells are wire-bonded. Although for visibility in FIG. 5B this is only shown on one cell; by molding these in one shot with a multi-cavity mold these optical blocks 5B721′ can have well-matched heights, and with the cones 331 on the lenses molded in one shot they will have well-matched heights. Silicone will optically couple to silicone even if both are pre-cured, and silicone cones will be soft enough to adapt to even few tens of microns of height difference, so silicone is especially preferred as a molded optical material for the cones and the coupling. A tiny drop of adhesive optical coupling can still be used, and it can then be small enough to not squish significantly beside the seam (namely, where the TOE meets the cell). In more-preferred embodiment of the present invention, the cells therefore have a transparent material with an index of refraction similar to or higher than the cone molded over each cell to at least the height of the bond wire material before the receivers are placed, and in especially preferred embodiments the receivers have a mechanical adhesive 3B74 tacky enough to hold each receiver in place against gravity after it is placed upward against the lens tile, end in exemplary embodiments electrically conductive adhesive 5B73 is dispensed on the bare end 5B41111 of the backplane 5B4111, so as to also electrically connect the receiver to the previous receiver as the receiver is placed against the lens tile.

Over-molding optical coupling on the cells is only useful when bonds wires are on active area of the cells; when bond wires are on the edges or corners of the cells, this extra molding step is not used preferred because the tail of the bond wire is at most a few tens of microns thick (and, as noted above, the soft silicone will adapt to a few tens of microns of height difference). For clarity this is illustrated in FIG. 5C, where TOE 5C31 is compressed between lens material 3210 and cell 5C5, which can be similar to cell 35 but has bond-wire contact point(s) 5C530 on the cell edge or corner rather than on the cell's active area. The compression is sufficient to press the almost the entirety of TOE egress 5C312 against the cell 5C5 in spite of the intervening end of the bond-wire 5C53, which is at most a few tens of microns thick. Compression should be at least sufficient to tolerate variation in cell thickness and solder thickness, each of which may be on the order of +/−10 microns, so compressed-cone coupling should compress the average TOE by at least 20 microns. If a liquid silicone is not then the TOE should be further compressed to accommodate shrinkage on cold winter days where the silicone may be tens of degrees cooler than the temperature at which the receiver is attached, which is location-dependant but is typically 40 to 100 microns of shrinkage. Thus in especially-preferred embodiments the average TOE may be compressed by 20 to 120 microns when a receiver is adhered to a lens tile, and by 60 to 80 microns in exemplary embodiments. When an adhesive liquid optical coupling is used (even in a very thin layer) then the average TOE should be compressed by roughly 20 microns since the TOEs will stretch on cold winter days and nights.

Once the receivers are placed against the lens tile the module is optically complete, and once the adhesive cures the final electrical connections can be made. Referring again to FIG. 10, the receiver on each end will have not only an array of cells and a diode, but also a connector cage in which a wire can be inserted; the other end of each wire will have a standard solar module connector such as MC-4 or Helios H4. The wire can extend from the side of the module or from the module end; ideally a wire with thin, heat-resistant insulation, such as Exane wire, is preferred.

Returning briefly to FIG. 3A, module back 3611 can be seen surrounding the back and extending onto the sides of lens tile 221, and a cooling fin 2613 can be seen on the module back. FIG. 11A shows the module housing 361 of FIG. 3A (namely, an example of a module housing in keeping with FIG. 3A) in more detail. The module back 3611 may be a strong, weatherproof, low-thermal-expansion, moderately-thermally-conductive material. Titanium, Martensitic stainless steel, and cast iron are examples of strong materials that have high enough thermal conductivity, and CTEs closely enough matched to low-iron glass; of these cast iron has the highest thermal conductivity (but would need to be treated to be weatherproof), titanium the best CTE match, and Martensitic stainless steel, particularly alloy 410, has the best overall blend of properties and cost and so is most preferred (however if titanium cost were to drop several fold it would become even more preferred). For Alloy 410 steel, a suitable thickness is about 1.5 millimeters, and alloy 410 is low enough in cost that the module back can have extra folds added to not needed other bracing in an RP-3-length module, or as shown in FIG. 11B, it can have a flange extension 11B6112 added to the flange 11B6111 on the side of the module farthest from the far edge of the trough (i.e., where a reinforcing member can be positioned to not significantly impede the airflow, and not shade the primary concentrator). Titanium is several times more expensive, so a thickness of around 1 mm is preferred for titanium.

The modules terminal wires could pass through holes in the module back to be installed after the module is sealed, but preferably the module back is notched with notches 116113, as shown in FIG. 11A, for the module terminal wires pass through; this lets the wires be installed and the module tested before the module back is placed and hermetically sealed to the rest of the module. Preferably the wire is covered with a reflective metal shield until it passes behind the module (and is thus shaded); this protects the wire if the tracker is miss-tracked, and preferably the terminal wires do not emerge from opposite sides of the module so that tracking onto sun from one direction does not expose even the wire shields to the trough's focus before the lens tile intercepts the focus.

The module back also provide the heat rejection for the module, and for two-axis tracked modules this can be through simple fins, heat pipes, or pumped coolant. While pumped coolant is preferable when heat is a useful by-product, that is generally better suited for single-axis-tracked versions and so will be discussed in that application. As for whether heat pipe or simple fins are preferred, fins are much simpler but do not scale well to higher heat loads so the preference depends largely on the mirror width. For narrow mirrors simple fins are more preferred, while when mirrors are wider than about two meters fins do not provide sufficient cooling to be optimal for today's cell, which lose ˜0.1% efficiency per ° C. and whose lifetime is shortened dramatically above 100° C. This preference therefore depends on the climate as well as the specific cells; in a hot desert the dividing line shift to roughly the width of an RP-3 inner mirror (namely, the RP-3 mirror's 1582 mm aperture width), and in cold climates it shifts above a 2-meter width. Since both (namely, both types of heat rejection) can be preferable within the scope of the present invention, both are taught herein.

Since aluminum currently offers the highest thermal conduction per dollar of any solid, simple fin cooling normally uses aluminum fins on an aluminum body. However aluminum has a roughly 14 PPM/K (depending on the alloy) higher CTE than low-iron glass, which on thermal cycling from cold winter nights to hot sunny summer data would either put too much stress on the glass lens, or would shift the lens and receivers by up to two millimeters relative to the housing, which would make maintaining a hermetic seal to the lens and maintaining good thermal contact with the receivers difficult. Titanium is a near-perfect thermal expansion match to the low-iron glass lens tile and alloy-410 stainless is within 1.5 PPM/K of the glass, and grey cast iron is within 2.5 PPM/K of the glass, making these materials much more suitable. But aluminum is still far more suitable for the fins, so in preferred embodiments aluminum fins 2613 are bonded to a lower-CTE module back 3611. Aluminum sheet is very inexpensive and is easy to cut and fold, so a module-length ‘accordion’ 116130 of folded aluminum fins 2613 is prepared (only part of the length is shown). As seen in FIG. 11B, to keep the folds from interfering with the air flow, material 116130X′ is removed from adjacent to fold zones 1161301′ and 1161301″ A larger region 116130X″ is removed where the material would shade the primary concentrator (as careful look at FIG. 2 will show that the module is off slightly to the side of the primary concentrator in preferred embodiments such as a single RP3 inner mirror, and this region 116130X″ would project out enough to shade the mirror). This removal of material this also helps make folding easier, and other features to ensure sharp folds, as known in the art of folding metal, may also be included. Alternatively, instead of a long accordion-folded sheet, folded fin-pairs can be stamped, producing more but easier-to-handle parts that each has a fold zone serving the same function as fold-zone 1161301″ of the accordion-folded part.

Aluminum can be brazed to titanium by placing a thin copper foil between them and heating them while pressing them together; the copper forms a eutectic melt with the aluminum that wets the titanium and cools to a strong bond (either the titanium or the aluminum could also be coated with copper, but a foil is typically less expensive). Titanium is much more expensive that alloy 410, and while titanium is affordable enough to be a preferred material, lower cost is even more preferable. Aluminum brazed directly to steel or cast iron forms weak iron/aluminum intermetallics, but steel or cast iron can be coated with titanium first and the aluminum then brazed to the titanium coating with copper foil or copper coating. Alloy 410 stainless steel and titanium are far more weather resistant that cast iron, making them more preferred.

Either titanium sheet is used, or alloy 410 steel sheet is coated with titanium where the brazing will occur; this can be done on large sheets that are then cut and folded into multiple module backs 3611. The module back and the aluminum accordion (or, alternatively, numerous folded fin-pairs) are placed in a clamp with copper foil between the titanium coating and the aluminum bottom fold zone 1161301″, and the clamp has a non-magnetic (e.g., 304 stainless steel) tooth to press each fold against the titanium coating. Alloy 410 in magnetic, and therefore suitable for induction heating; a rapidly alternating current in the steel teeth with therefore quickly heat the module back and braze the aluminum fins to the titanium coating through the copper foil forming a eutectic melt with the surface of the aluminum. The fins will quickly conduct the heat away leaving a strong bond with low thermal resistance. Being non-ferromagnetic, titanium is harder to induction-heat directly, so if titanium sheet is used for the module back the clamp teeth can have magnetic steel tips so that the tooth tips provide the heat rather than the module back itself, but the overall process is similar.

Embodiments of the present invention preferably have module housing 3611 with a CTE within 2.5 PPM/K of the lens tile's CTE, and more preferably within 1.5 PPM/K, even more preferably with aluminum fins attached, still more preferably folded aluminum fins with areas that would block airflow removed before folding, yet more preferably attached through brazing, and in exemplary embodiments attached through brazing to titanium sheet or coating through an aluminum/copper eutectic. For good cooling through natural convection the aggregate fin surface area is preferably between 1 and 3 times the primary concentrator's aperture area for a primary concentrator up to 2 meters wide, and is more preferably between 1.5 and 2.5 times the primary concentrator's aperture area.

Alternatively, the fins can be formed as part of the module back. As shown in FIG. 11C, a profile similar to a standard heat-sink profile can be formed from aluminum (or from another other low-cost, highly-thermally conductive material such as magnesium; copper would offer higher performance but currently is too expensive to be preferred, however it would become preferred if its cost were to fall enough to offer comparable thermal conductivity per dollar to aluminum).

Extrusion is a preferred way of forming the profile because the fins can easily be tapered to be thicker near the extrusion base 11C6110, which will become the module back, and thus the fins can be thicker in regions that will have higher heat flow. While extrusion eliminates bonding the fins to the module back since they are formed as a unit, extrusion is currently limited in width to at most roughly 650 mm, and many extruders have limits in the 200 mm to 300 mm range. In one preferred embodiment that uses extruded fins, the module is simply made shorter than the extrusion width so that a single extrusion width can be used to form a back for the module. But at current extruder widths this provides shorter module than optimal due to more modules (on a per kilowatt basis) to handle, along with more weather-proof connectors needed to interconnect the increased number of modules.

In more-preferred embodiments the module length may be wider than the current extrusion limit. With extruded fins, multiple short module backs can be used side by side to cover the longer module. However even more preferable multiple extruded profiles may be joined together placed side-by-side and joined together (such as by brazing, laser-welding, or other means known in the art of joining aluminum) into a wider profile (of roughly 1750 mm in the preferred modules that use 1700-mm-long RP-3 mirrors, providing sufficient extra material to form the module ends). Extruded profiles can be several meters long, so as few as two (or five to eight with 200 mm to 300 mm extrusion widths) long, straight welds can produce a large sheet from which many module housings can be formed.

To provide sufficient fin area to sufficiently cool today's cells when an RP-3 mirror is used as a primary concentrator, fins are preferably between 60 mm and 100 mm tall and 120 mm to 160 long, with fins between 70 mm and 75 mm tall by 140 mm long being exemplary. As shown in FIG. 11D, which is a cross-section, across the primary concentrator's focus, of an example of a preferred embodiment, the several-meter length may be cut every 140 mm at a slant to the extrusion base 11C6110. The slant of the cut is substantially the same as the primary concentrator's rim angle, minimizing shading of the mirror by the fins, and the housing 11D611 is formed so that the fins are offset away from the far edge of the primary concentrator; since a single RP-3 inner mirror is an off-axis mirror, this puts the vast bulk of the fin material where is will not shade the primary concentrator. Just as with the spill zone from the mirrors ends, there is a roughly 20 mm-wide partial shading zone, and the asymmetry is reduced (to shorten the average distance that heat is conducted in the fins) by having the fins intrude roughly half-way into this partial-shading zone; since the fins are substantially parallel to the incoming rays they block only a small fraction of the light, and in this zone they will block it from only part of the sun, so very little light is lost and cooling is noticeably improved. The fin corners can be left sharp, but are preferably rounded for safety during handling.

Referring briefly back to FIG. 11C, the extrusion base 11C6110 extends for the whole length (not seen in this cross-section) of the extruded profile as well as the whole width (as can be seen in this cross-section). If left intact this would be problematic because (as can be seen in returning to FIG. 11D), base material 11D6110_{X} beyond the width of the lens tile would reduce air-flow through the heat-sink by partially blocking the gaps between the fins. This material could simply be removed to improve the air-flow (as was done with material 116130_{X}′ near the fold zones in the accordion-folded fins). However rather than simply remove this material, in further-preferred embodiments the air-blocking parts of the extrusion-base are cut free from the fins and are then folded to produce the flanges 11D6111′ and 11D6111″ of the module back. Mounting flange 11D6111″ preferable then gets holes (for mounting bolts) formed (such as by drilling, cutting, or punching). To prevent force from wind load or snow and ice load from having leverage to pry the housing from the lens tile, a gusset is preferable installed near each such bolt hole to transfer force from the fins to the mounting bolts (it is envisioned that modules may be bolted to a low-cost galvanized-steel ‘angle iron’ for mounting and/or reinforcement).

This arrangement provides excellent cooling from a minimum of aluminum by conducting heat with low thermal resistance from the back of receiver 11D4 into fins 11D613, while only slightly shading the primary concentrator. A very similar fin profile can also be produced with skived fins, so skiving is also a preferred method of producing the heat-sink profile. Skiving does not have width restrictions, so it eliminates the welding step. Skiving does requires a thicker base (roughly 5 mm), but this can be machined thinner before cutting the excess base free and folding the flanges (the few mm of excess aluminum is much less material than the fins, an aluminum is highly recyclable). Skiving is currently more expensive than extrusion, but a lower-cost skiving would be possible in high volume, potentially making skiving even more preferred than extrusion.

Multiple steps are taken to deal with aluminum having much higher thermal expansion than glass. The fins put very little longitudinal stress on the glass, so preferred embodiments keep the heat-sink base thin (or thin it in the case of skived fins) to keep the forces on the glass small. Glass is also very strong under compressive force, so the aluminum housing is preferably bonded to the glass at roughly the highest temperature that the heat-sink will see in operation, so that the aluminum shrinks onto the glass at lower temperatures and thus compresses the glass. The housing is bonded to the glass with a strong adhesive (such as epoxy) so that the two are mechanically coupled and expand and contract together with their weighted-average CTE. With the 19-mm-thick lens glass of many of the preferred embodiments, a roughly 1 mm base thickness produces an overall longitudinal CTE of about 12 ppm/K, which is a close match to a galvanised-A36-steel angle iron to which the module of the present invention may be bolted, minimizing mismatch stress at that interface. With a roughly 3-mm-thick base the overall longitudinal CTE is about 16 ppm/K, a close match to copper, which is ideal for copper-based receivers (and for a thin, flat material copper is lower cost than AlSiC as well as being more thermally- and electrically-conductive). A roughly 2-mm-thick base produces a CTE of about 14 ppm/K about halfway between A36 steel and copper, and provides a quite good match to both, making a roughly 2 mm-thick base formed into a flanged module housing exemplary when attached to the lens tile at a temperature that keeps stress on the glass compressive.

While simple fins are suitable for current tandem cells and single-RP-3-inner-mirror troughs, there can be cases where more fin area is needed. For example, future cells might be much more sensitive to heat but be enough higher in efficiency or lower in cost to be worth adapting to, or wider mirrors might become lower-cost per area than RP-3. If cooler cells are needed, the thermal resistance from cell to the module back is small compared to the resistance in the fins and their heat transfer to the air, so increasing the fin area per module length would meet the need. If using wider mirrors is desired, the lens tile of the present invention could scale to much wider mirrors simply by cutting wider lens tiles from a lens sheet; receivers up to three times wider would still fit in high-speed placement equipment and in many high-speed wire-bonder, and a receiver could have multiple substrates beyond that size, so again increasing the fin area per module length would meet the remaining need. But simple fins do not scale well to large sizes; larger fins need more airflow, but the air has farther to travel and thus meets more resistance unless the fins are farther apart, which reduces conduction into the air; heat must also flow farther in the fins themselves, requiring thicker fin material for the same performance. Fins that are both thicker and larger in area for a given cooling performance quickly become prohibitively expensive.

An alternative cooling means therefore incorporates the module back into a heat pipe that carries the heat to multiple finned members that can each have smaller (and thus more efficient) fins while providing a large aggregate fin area. As shown in FIG. 12A, a cover 126141 is hermetically sealed to the module back 12613 to form an evaporation chamber. One or more common coolant pipes 126142 are attached to said evaporation chamber, with the coolant pipe interior(s) in communication with the evaporation chamber; each common coolant pipe 126142 has one or more cooling tubes 126143 attached to it, with the cooling tube interior(s) in communication with the evaporation chamber via the common coolant tubes. The tube(s) have fins 126144 on their exterior(s) for increased surface area for heat rejection to the air; such ‘fin-tube’ is readily available in a variety of configuration, including with aluminum fins 126144 wrapped around a steel tube, which is a preferred configuration.

As is known in the art of heat pipes, the evaporation chamber is at least partially filled with a liquid coolant 126146, and enough air is evacuated from the chamber that the remaining air has a partial pressure low (typically less than 10% and more typically less than 1% of the vapor pressure of the coolant at typical operating temperatures) so that the liquid coolant boils readily upon absorbing heat in the evaporation chamber. The coolant vapor thus produced travels into the fin tube(s) where it gives up its latent heat to the tube walls and condenses to liquid coolant, this liquid returns to the evaporation chamber to complete the cycle. Heat pipes have extremely high effective thermal conductivity, so the number of fin tubes can be increase as need to provide very large aggregate fin area and thus high heat transfer with very low thermal resistance.

Most heat pipes are small enough that a wick can be used for coolant return without of even against gravity, but even for an RP-3 inner mirror the distances involved are too large. Gravity return is also well known in ‘thermosiphon’ heat pipes, but the orientation of the module to be cooled changes as the module is tracked to follow the sun. The prior art of cooling HCPV modules includes numerous examples of thermosiphons where fin-tube is oriented so that its tube's axis points directly at the sun when the HCPV module is in operation. While this orientation minimizes the shadow from the fins, the fins are then largely horizontal when the sun is highest and the demand for cooling is thus likely to be greatest, and heat transfer from natural convection is much lower from closely-spaced horizontal fins the closely-spaced vertical fins, so much more fin area is needed to avoid overheating the cells being cooled.

The fin-tube set of preferred embodiments of the present invention overcomes this by orienting a heat-pipe's condensation so that it does not shade the light-gathering area of its module, while still obtaining gravity-assist for the coolant return, and while ensuring a near-vertical orientation for the fins. As shown in FIG. 12A, the present invention mounts multiple fin tubes 126143 on a common coolant pipe 126412. The common coolant pipe 126412 is slanted relative to the module back 12613 (which may be the same as module back 3611, but may also be modified by the addition of wick 126145 on the surface opposite where it will mate to the receivers) so that even when as module is tracked to follow the sun to dawn or dusk gravity still brings condensed coolant 126145 back through the common coolant pipe to the evaporation chamber of heat pipe 12614. Within the evaporator wick 126145, as is well known in the art, can wick coolant up the short distance from the pool level 1261460 to the highest cell; this works for a module up to about twice the width needed for a single RP-3 inner-mirror trough. The pool can also be deep enough to always cover the module back to the level of the highest cells (on one end of the cell rows), which scales to any module width needed; with the exemplary RP-3 mirror this would move the common coolant pipe to where the fin tube would significantly shade the mirror, but this would only be needed for a wider mirror which could be made more off-axis to avoid mirror in the shaded area. Even when a wick is not needed to lift the coolant, a wick such as sintered copper grains provides increased surface area for evaporation, reducing overheat in the coolant and thus running the cells a few degrees cooler.

As seen in FIG. 12B, to improve airflow through the fins the present invention orients the fin tubes' tubes largely parallel to the altitude tracking axis. But the fin tubes are slanted slightly relative to the altitude tracking axis, and each fin tube 126143 is closest to the module back 12613 where that fin tube joins the common coolant pipe 126142. This allows gravity always to always assist the coolant return in the fin tubes as well as in the common coolant pipe that enters the evaporator. Preferentially the trough mirror's focus is also substantially parallel to the altitude tracking axis so that the fin tube is close to parallel to the module, allowing the mirrors and their modules to be packed closer together without the fin tube of one module shading the mirror of the next module.

When the fin area needed for heat rejection exceeds that where simple fins become inefficient, preferred embodiments of the present invention provide heat-pipe/fin-tube cooling where the module back comprises an evaporator for a sealed heat pipe. Without aluminum directly on the module back a low-CTE steel alloy such as stainless 410 is more preferred for both module back 12613 and evaporator cover 126141, and can easily be welded for a strong hermetic joint. Even more preferably the heat pipe has a plurality of fin-tube heat rejection members 126143 in communication with the evaporator through a common coolant pipe 126142, and that are closer to parallel than perpendicular to long axis of the module, and are closest to the evaporator where they join the coolant pipe to return condensed coolant to the evaporator, and in exemplary embodiments the fin tubes comprise aluminum fins spiral-wound around a steel tube.

The final assembly of the 2-axis-tracked module of the present invention is joining the lens tile to the module back. This procedure is similar for both the heat-pipe and simple-fin module backs described previously. As mentioned before, an at-least-moderately thermally conductive electrical insulator such as ventec's VT-542 prepreg provides isolation between the receivers and the module back; this isolation can be on the backs of the individual receivers (it can be bonded to the receiver substrate material as a large sheet before the substrates are cut), or it can be bonded to the backs of all receivers at once after they are bonded to the lens tile, or it can be bonded inside the module back. Returning again to FIG. 11B, in either case either the lens tile assembly of the module back may have a thermally-conductive gap filler 11B75 applied, which may be a grease, a curing adhesive, a cementitious grout, or a pad, as are known in the art of thermally coupling heat-producing component to heat-sinks. If the prepreg (or other isolation) is applied to the module back then this gap-filler must be electrically isolating; if the prepreg (or other isolation) is applied as a sheet to all receiver backs after bonding them to the lens tile then this gap filler may be either electrically isolating or conductive, and if the prepreg (or other isolation) is on the individual receiver backs then an electrically isolating gap filler is needed unless the gaps between the receivers are filled after bonding them to the lens tile.

Preferred module backs have flanges 11B6111 along their lengths the extend parallel to the sides of the lens tile. If the thermally conductive gap filler 11B75 is a strong, weatherproof adhesive, it can be extended to serve to mechanically seal the lens tile to the module back, but such adhesive are currently expensive so it is currently preferred to use a separate weatherproof adhesive 11B76 such as epoxy or silicone to seal the lens tile to the module back. This can be applied to the sides of the lens tile or to the module back's flanges before joining these parts, but to lower the risk of entrapping air-filled voids in the thermally-conductive gap filler, it is more preferably applied to the flange/tile seam after joining, and in exemplary embodiments is injected or worked into the seam between the module back and the lens tile to ensure a water-tight seal.

With all sensitive components hermetically sealed between a thick glass lens and a titanium or stainless steel sheet (or, in the case of a higher-CTE module, aluminum), and the cells and bypass diodes well cooled and on a well-CTE-matched substrate, the HCPV modules of the present invention should be very durable as well as being very low cost to manufacture and very high in efficiency, thus meeting all of the most important criteria for producing solar energy at very low cost.

Many of the above aspects of the present invention also have uses outside of solar energy, particularly in the field of arrays of high-brightness LEDs (HB-LEDs) for architectural lighting or for horticulture. HB-LEDs are typically in the size range of the cells of the preferred embodiments of the photovoltaic embodiments of the present invention, and have current requirements within the range that the conductors taught above can handle, so by replacing the photovoltaic cells by HB-LEDs and reversing the current flow, the substrates and electrical connectivity taught for photovoltaic cells in the present invention are highly suitable for arrays of HB-LEDs, reducing the cost of such arrays. The bypass diodes may be replaced with ‘LED Shunts’, (also known as “LED Open Protectors), allowing the aspects of arrays-of-parallel-semiconductors connected in series as taught above to be used with LEDs. While there is no need to match the module length taught above, the receiver size range taught for photovoltaic cells will also create luminaires a meter or two long (including standard 4-foot and six-foot lengths) that run at reasonable voltages (similar voltages to current luminaires), so preferred embodiments of the present invention use two-dimension arrays of LEDs-in-parallel that fit in 50 mm×50 mm regions, and connect multiple such arrays, more preferably at least 10 such arrays and even more preferably at most 100 such arrays, in series.

Furthermore, ray optics are largely reversible, so the lens tile of the present invention, with its low-cost/high-efficiency coupling to arrays of optic-electronic semiconductors, is suitable for use as a collimator to direct light over an angular range roughly equal to the preferred trough rim angles as taught herein. Preferred embodiments of the present invention may therefore mount multiple LED arrays on an integral lens tile comprising multiple linear lenses, and more preferably those arrays connect in series during the mounting process, and in exemplary embodiments, each linear lens is optically coupled each of multiple LEDs through a transparent conical light guide of material that has a refractive index at least as high as the linear lens.

LEDs also need cooling, and the module cooling means taught in the two-axis-tracked-primary-concentrator embodiments above are highly suitable, providing excellent cooling at low cost. In particular the integral-fin heat sinks with the base folded to form flanges are preferred, and are exemplary when bonded to a lens tile at a temperature at least as high as it will reach in normal use as a luminaire.

Since LEDs produce broadly similar ratios of visible light to heat as the tandem photovoltaic cells produce electricity to heat, such a luminaire can produce light of intensity broadly comparable to sunlight at distances of the same rough magnitude as the focal length of the primary concentrators of the photovoltaic aspects of the present invention, and 1700 mm above the plants is in a range highly suitable for greenhouses. Vertical farms generally use luminaires closer to plants to allow denser vertical packing, but from the forgoing it will become obvious to one skilled in the art that luminaires of lower optical output can be produced by many means, including without limitation lower voltage, lower current per LED, narrower arrays with fewer LEDs, or sparser arrays with fewer LEDs, and that the cooling can be scaled down appropriately.

Upon reading the above, numerous variations will suggest themselves to those familiar with the relevant arts, and the above examples and embodiments of the present invention are meant to be illustrative rather than limiting. In general, when a combination of features taught herein complement each other in an unexpected way, the combination is discussed, but combinations that merely complement each other as would be expected from understanding the individual feature are generally not discussed unless they provide the foundation for understanding other improvements.

The physical details presented herein are also meant to be illustrative rather than limiting. For example, in the various preferred embodiments described in detail the concentration could be higher or lower and the cells could have one junction or many; the trough could be wider or narrower, the mirrors longer or shorter, a module could span multiple mirrors or multiple modules could span each mirror's focus, the primary concentrator can be an off-axis or on-axis trough, and parabolic, cylindrical or other shape, or even another linear concentrator such as compact linear Fresnel Reflectors, the mirrors can be metal-on-glass, or metal, or dielectric reflectors, and may be self-supporting or thinner with back supports; two-axis trackers may be altitude/azimuth or polar and may be pole mounted or carousel or any other combination that tracks the sun on two axes, and one-axis trackers may have axes, N/S, E/W, at-latitude, on-slope, vertical, or any other arrangement that tracks the sun on one axis; then lens and cones may be the same material or different materials, and may be a commodity glass, and instrument-grade glass, a hard polymer such as acrylic or polycarbonate or a soft polymers such as silicone, or may be another transparent material such as sapphire or diamond if such materials become affordable in the future; the substrate could be any material of high thermal conductivity, reasonable CTE match to the lens and the cells (or of the overall CTE of the lens bound to the heat sink), and electrical conductivity at least on its surface, including not just AlSiC but other metal-matrix composites such as molybdenum/copper, graphite/copper and diamond/copper, pure metals such as molybdenum (or copper), or laminates such as DBC/AlN; the power-plane could be a different electrically conductive material such as aluminum, the cooling could be passive, semi-passive or active; etc. The examples given are preferred or exemplary based on current materials availability, cost and familiarity to the solar industry in general and HCPV in particular. For example an aluminum power plane would cost very slightly less than a copper power plane and could use aluminum bond-wire that costs less than the gold bond wire, but current commercially available tandem cells have top contact metallization that is compatible with gold rather than aluminum so to use aluminum today would create brittle intermetallics, therefore copper and gold are used in the examples, but it would be well within the scope of the present application to switch to aluminum should compatible cells become available, and such a variation is not discussed (other than in this example of things that are not discussed) because the principles and details involved would be obvious to one familiar with the relevant arts and would not impact the inventive features disclosed in the present application.

Even these examples of the generality are meant to be illustrative rather than limiting, and numerous minor variations, especially in trading generality for features for specific purposes, will suggest themselves to those familiar with the relevant art upon reading the above descriptions of the preferred embodiments.

1. A system for providing electrical power from sunlight, the system comprising:
a primary concentrator that focuses sunlight, on at least a primary concentration axis, onto a plurality of secondary concentrators,
each one of said secondary concentrators concentrates light at least on a second concentration axis that is substantially orthogonal to said primary concentration axis, and wherein each of said plurality of secondary concentrators produces a focus that does not overlap foci of the other secondary concentrators of said plurality of secondary concentrators,
moveable mounting means for adjusting the orientation of said primary concentrator to follow the sun on at least said primary concentration axis,
moveable mounting means for adjusting the orientation of said secondary concentrator to follow the sun on at least said secondary concentration axis,
multiple receivers, with each of said multiple receivers comprising a plurality of photovoltaic cells that are individually connected electrically in parallel with each other and arranged to receive light from a corresponding plurality of said non-overlapping foci, with multiple ones of said receivers electrically connected in series.

2. A system for providing electrical power from sunlight as claimed in claim 1, wherein said primary concentrator is an off-axis parabolic trough mirror with a rim angle between 20° and 30°.

3. A system for providing electrical power from sunlight as claimed in any one of claims 1 through 2, wherein each of said receivers comprises a 2-dimensional array of photovoltaic cells, wherein all cells of said array are mounted on a contiguous substrate.

4. A system for providing electrical power from sunlight as claimed in any one of claims 1 through 3, wherein each of said photovoltaic cells has a total photoreceptive area that is at most 2 square millimeters.

5. A system for providing electrical power from sunlight as claimed in any one of claims 1 through 4, further where each of said receivers can produce at least 10 Watts of electrical power when said primary and secondary concentrators are aligned to the sun on their respective concentration axes and the sunlight has 1000 W/m² Direct Normal Insolation.

6. A system for providing electrical power from sunlight as claimed in any one of claims 1 through 5, wherein each of said receivers comprises a power plane that is a contiguous metal sheet, and each of said photovoltaic cells of said receiver has at least one front electrical contact that is wire-bonded to said power-plane, and all wire bonds on a given receiver are within a region that is at most 50 mm by 50 mm.

7. A system for providing electrical power from sunlight as claimed in any one of claims 1 through 6, wherein each of said receivers comprises a power plane that is a contiguous metal sheet, each of said receivers further comprises a backplane that is a contiguous metal sheet, and each of said photovoltaic cells of said receiver has at least one back electrical contact that is soldered to said backplane, and said power-plane has a hole to accommodate each of said photovoltaic cells.

8. A system for providing electrical power from sunlight as claimed in any one of claims 1 through 7, wherein multiple ones of said plurality of secondary concentrators are formed as an integral part.

9. A system for providing electrical power from sunlight as claimed in any one of claims 1 through 8, wherein said moveable mounting means for adjusting the orientation of said primary concentrator to follow the sun adjust said orientation of said primary concentrator only on said primary concentration axis, and said moveable mounting means for adjusting the orientation of said secondary concentrator to follow the sun adjust said orientation of said secondary concentrator only on said secondary concentration axis.

10. A system for providing electrical power from sunlight, the system comprising:
a primary concentrator that focuses sunlight, on at least a primary concentration axis, onto a plurality of secondary concentrators,
each one of said secondary concentrators uses refraction to concentrate light at least on a second concentration axis that is substantially orthogonal to said primary concentration axis, and wherein each of said plurality of secondary concentrators produces a focus that does not overlap foci of the other secondary concentrators of said plurality of secondary concentrators,
moveable mounting means for adjusting the orientation of said primary concentrator to follow the sun on at least said primary concentration axis,
moveable mounting means for adjusting the orientation of said secondary concentrator to follow the sun on at least said secondary concentration axis,
multiple receivers, with each of said multiple receivers comprising at least one photovoltaic cell, with multiple ones of said receivers electrically connected in series,
where multiple ones of said plurality of secondary concentrators are formed as an integral part, and said multiple secondary concentrators are optically coupled to said photovoltaic cells without passing through any region that has a refractive index lower than 0.25 below the refractive index of said secondary concentrators.

11. A system for providing electrical power from sunlight as claimed in claim 10, wherein a plurality of tertiary optical elements further concentrates the light each of said multiple secondary concentrators.

12. A system for providing electrical power from sunlight as claimed in claim 11, wherein said tertiary optical elements are formed on said integral part.

13. A system for providing electrical power from sunlight as claimed in claim 12, wherein said integral part comprises glass and said tertiary optical elements comprise silicone.

14. A system for providing electrical power from sunlight as claimed in any one of claims 10 through 13, wherein said primary concentrator is tracked to follow the sun on both said primary concentration axis and said secondary concentration axis.

15. A system for providing electrical power from sunlight as claimed in claim 14, wherein said integral part has multiple ones of said receivers mounted on it.

16. A system for providing electrical power from sunlight as claimed in claim 14 or 15, wherein said integral part extends for at least 500 mm along the primary concentrator's focus.

17. A system for providing electrical power from sunlight as claimed in any one of claims 14 through 16, wherein said primary concentrator comprises a plurality of integral segments and there is a one-to-one correspondence between said integral segments and said integral parts.

18. A system for providing electrical power from sunlight as claimed in any one of claims 14 through 17, wherein said system further comprises a module back that is sealed to said integral part, wherein said module back had a higher coefficient of thermal expansion than said integral part, and said module back is bonded to said integral part at a temperature of at least 80° C.

19. A system for providing electrical power from sunlight as claimed in any one of claims 14 through 17, wherein said system further comprises a module back that comprises flanges that are sealed to said integral part, wherein said module back further comprises fins

20. A system for providing electrical power from sunlight as claimed in any one of claim 19, wherein said flanges and fins are formed as an integral unit.

21. A method of manufacturing a system for providing electrical power from sunlight, the method comprising:
mounting multiple receivers, each one of said multiple receivers comprising one or more photovoltaic cells connected in parallel, on an integral part that comprises multiple secondary concentrators that each concentrates light on a secondary concentration axis, and
mounting said integral part in the focus of a primary concentrator that is tracked to follow the sun on two axes.

22. A method of manufacturing a system for providing electrical power from sunlight as claimed in claim 21, wherein mounting said multiple receivers on said integral part electrically interconnects said receivers in series.

23. A method of manufacturing a system for providing electrical power from sunlight as claimed in any one of claims 21 through 22, wherein each of said secondary concentrators is optically coupled to a plurality of said cell through a plurality of tertiary optical elements the comprise a flexible transparent material, and where said tertiary optical elements are compressed against said cells by mounting said receivers on said electrical parts.

24. A method of manufacturing a system for providing electrical power from sunlight as claimed in any one of claims 21 through 23, wherein a module back comprising fins and flanges and having a higher overall coefficient of thermal expansion than said integral part is bonded to said integral part at a temperature of at least 80° C.

25. A method of manufacturing a system for providing electrical power from sunlight as claimed in any one of claims 21 through 24, wherein a module back comprising fins and flanges is formed as an integral part by forming said fins with an integral base, cutting part of the width of that base from said fins with said base remaining integral with said fins through the remainder of the width of said base, and then folding that base to form said flanges.

26. A system for producing light from electrical power, the system comprising:
multiple LED arrays that each comprise a plurality of light-emitting diodes that are individually connected electrically in parallel with each other,
wherein all light-emitting diodes of each one of said LED arrays are mounted on a corresponding one of a corresponding plurality of backplanes, each one of said backplanes comprising a contiguous metal sheet and each of said light-emitting diodes has at least one back electrical contact that is soldered to said corresponding one of said backplanes, and
wherein bonded to each one of said backplanes is a power plane that is a contiguous metal sheet, and each of said light-emitting diodes of said array has at least one front electrical contact that is electrically connected to said power-plane, and said power-plane has a hole to accommodate each of said light-emitting diodes.

27. A system for directing light from arrays of LEDS, comprising:
a plurality of LED arrays that each comprise a plurality of light-emitting diodes that are individually connected electrically in parallel with each other,
a plurality directors that use refraction to direct light at on at least one axis, wherein multiple ones of said plurality of directors are formed as an integral part, and said multiple directors are optically coupled to said light-emitting diodes without passing through any region that has a refractive index lower than 0.25 below the refractive index of said directors,
with multiple ones of said LED arrays mounted on said integral part and electrically connected in series.

28. A solar energy collector substantially as described herein and exemplified with reference to the accompanying figures.
